(19) United States
(12) Patent Application Publication
(10) Pub. No.: US 2024/0170555 A1
(43) Pub. Date: May 23, 2024

(54) SEMICONDUCTOR DEVICE AND METHOD FOR MANUFACTURING SEMICONDUCTOR DEVICE

(71) Applicant: SEMICONDUCTOR ENERGY LABORATORY CO., LTD., Atsugi-shi, Kanagawa-ken (JP)

(72) Inventors: Yukinori SHIMA, Tatebayashi, Gunma (JP); Takuya HANDA, Mooka, Tochigi (JP)

(21) Appl. No.: 18/284,681

(22) PCT Filed: Apr. 4, 2022
(86) PCT No.: PCT/IB2022/053094

§ 371 Date: Sep. 28, 2023

(30) Foreign Application Priority Data
Apr. 16, 2021 (JP) 2021-069533
Aug. 6, 2021 (JP) 2021-129504

(51) Int. Cl. H01L 29/49; H01L 29/786

(52) U.S. Cl. CPC H01L 29/4908; H01L 29/7869

(57) ABSTRACT

A semiconductor device with favorable electrical characteristics is to be provided. A semiconductor device with high reliability is to be provided. The semiconductor device includes a first transistor and a second transistor. The first transistor includes a first semiconductor layer, a first insulating layer, a second insulating layer, and a first gate electrode that are stacked in this order. The first gate electrode includes a region overlapping with the first semiconductor layer. The second transistor includes a second semiconductor layer, a second insulating layer, and a second gate electrode that are stacked in this order. The second gate electrode includes a region overlapping with the second semiconductor layer.

### TECHNICAL FIELD

One embodiment of the present invention relates to a semiconductor device. One embodiment of the present invention relates to a method for manufacturing a semiconductor device. Note that one embodiment of the present invention is not limited to the above technical field. Examples of a technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a fabricating method thereof. A semiconductor device refers to any device that can function by utilizing semiconductor characteristics.

### BACKGROUND ART

As a semiconductor material applicable to a transistor, an oxide semiconductor using a metal oxide has attracted attention. For example, Patent Document 1 discloses a semiconductor device in which the field-effect mobility (simply referred to as mobility or μFE in some cases) is increased by stacking a plurality of oxide semiconductor layers, containing indium and gallium in an oxide semiconductor layer serving as a channel in the plurality of oxide semiconductor layers, and making the proportion of indium higher than the proportion of gallium.

A metal oxide can be formed by a sputtering method or the like, and thus can be used for a semiconductor layer of a transistor in a large display device. In addition, capital investment can be reduced because part of production equipment for a transistor using polycrystalline silicon or amorphous silicon can be retrofitted and utilized. Furthermore, a transistor using a metal oxide has high field-effect mobility compared to the case of using amorphous silicon; therefore, a high-performance display device provided with a gate circuit can be achieved.

### REFERENCE

### Patent Document

[Patent Document 1] Japanese Published Patent Application No. 2014-7399

### SUMMARY OF THE INVENTION

### Problems to be Solved by the Invention

An object of one embodiment of the present invention is to provide a semiconductor device with favorable electrical characteristics. Another object of one embodiment of the present invention is to provide a highly reliable semiconductor device. Another object of one embodiment of the present invention is to provide a semiconductor device with stable electrical characteristics. Another object of one embodiment of the present invention is to provide a semiconductor device including different transistors over one substrate. Another of one embodiment of the present invention is to provide a novel semiconductor device.

Note that the description of these objects does not preclude the presence of other objects. Note that one embodiment of the present invention does not have to achieve all the objects. Note that objects other than these can be derived from the descriptions of the specification, the drawings, the claims, and the like.

### Means for Solving the Problems

One embodiment of the present invention is a semiconductor device including a first transistor and a second transistor. The first transistor includes a first semiconductor layer, a first insulating layer, a second insulating layer, and a first gate electrode that are stacked in this order. The first gate electrode includes a region overlapping with the first semiconductor layer. The second transistor includes a second semiconductor layer, a second insulating layer, and a second gate electrode that are stacked in this order. The second gate electrode includes a region overlapping with the second semiconductor layer.

In the above semiconductor device, the first insulating layer preferably includes a region in contact with a top surface of the first semiconductor layer. The first insulating layer preferably includes a region in contact with a bottom surface of the second semiconductor layer.

In the above semiconductor device, each of the first semiconductor layer and the second semiconductor layer preferably contains indium. The atomic ratio of indium to metal elements contained in the second semiconductor layer is preferably higher than that in the first semiconductor layer.

In the above semiconductor device, the atomic ratio of indium to metal elements contained in the second semiconductor layer is preferably higher than or equal to 30 atomic % and lower than or equal to 100 atomic %.

In the above semiconductor device, each of the first semiconductor layer and the second semiconductor layer preferably contains indium. The atomic ratio of indium to metal elements contained in the first semiconductor layer is preferably higher than that in the second semiconductor layer.

In the above semiconductor device, the atomic ratio of indium to metal elements contained in the first semiconductor layer is preferably higher than or equal to 30 atomic % and lower than or equal to 100 atomic %.

In the above semiconductor device, the second semiconductor layer preferably contains an element M, and the element M is preferably one or more kinds selected from gallium, aluminum, yttrium, and tin. The atomic ratio of the element M to metal elements contained in the second semiconductor layer is preferably higher than that in the first semiconductor layer.

In the above semiconductor device, the atomic ratio of the element M to metal elements contained in the second semiconductor layer is preferably higher than or equal to 20 atomic % and lower than or equal to 60 atomic %.

In the above semiconductor device, the first semiconductor layer preferably contains an element M, and the element M is preferably one or more kinds selected from gallium, aluminum, yttrium, and tin. The atomic ratio of the element M to metal elements contained in the first semiconductor layer is preferably higher than that in the second semiconductor layer.

In the above semiconductor device, the atomic ratio of the element M to metal elements contained in the first semiconductor layer is preferably higher than or equal to 20 atomic % and lower than or equal to 60 atomic %.

In the above semiconductor device, the first transistor preferably includes a third insulating layer and a third gate electrode. The third gate electrode preferably includes a region overlapping with the first gate electrode with the first semiconductor layer therebetween. The third gate electrode preferably includes a region overlapping with the first semiconductor layer with the third insulating layer therebetween.

In the above semiconductor device, the second transistor preferably includes the first insulating layer, the third insulating layer, and a fourth gate electrode. The fourth gate electrode preferably includes a region overlapping with the second gate electrode with the second semiconductor layer therebetween. The fourth gate electrode preferably includes a region overlapping with the second semiconductor layer with the first insulating layer and the third insulating layer therebetween.

Another embodiment of the present invention is a method for manufacturing a semiconductor device including steps of forming an island-shaped first semiconductor layer over a substrate, forming a first insulating layer over the substrate and the first semiconductor layer, forming an island-shaped second semiconductor layer over the first insulating layer, forming a second insulating layer over the first insulating layer and the second semiconductor layer, and forming a first gate electrode and a second gate electrode over the second insulating layer. The first gate electrode includes a region overlapping with the first semiconductor layer with the first insulating layer and the second insulating layer therebetween. The second gate electrode includes a region overlapping with the second semiconductor layer with the second insulating layer therebetween.

### Effect of the Invention

According to one embodiment of the present invention, a semiconductor device with favorable electrical characteristics can be provided. Alternatively, a highly reliable semiconductor device can be provided. Alternatively, a semiconductor device with stable electrical characteristics can be provided. Alternatively, a semiconductor device including different transistors over one substrate can be provided. Alternatively, a novel semiconductor device can be provided.

Note that the description of these effects does not preclude the presence of other effects. Note that one embodiment of the present invention does not necessarily have all of these effects. Note that effects other than these can be derived from the descriptions of the specification, the drawings, the claims, and the like.

### BRIEF DESCRIPTION OF THE DRAWINGS

FIG. 1A and FIG. 1B are diagrams illustrating a structure example of a semiconductor device.

FIG. 2A to FIG. 2D are diagrams illustrating a structure example of a semiconductor device.

FIG. 3A to FIG. 3D are diagrams illustrating a structure example of a semiconductor device.

FIG. 4A to FIG. 4D are diagrams illustrating a structure example of a semiconductor device.

FIG. 5A to FIG. 5D are diagrams illustrating a structure example of a semiconductor device.

FIG. 6A and FIG. 6B are diagram illustrating a structure example of a semiconductor device.

FIG. 7A and FIG. 7B are diagrams illustrating a structure example of a semiconductor device.

FIG. 8A and FIG. 8B are diagrams illustrating a structure example of a semiconductor device.

FIG. 9A and FIG. 9B are diagrams illustrating a structure example of a semiconductor device.

FIG. 10A to FIG. 10D are diagrams illustrating a structure example of a semiconductor device.

FIG. 11A and FIG. 11B are diagrams illustrating a structure example of a semiconductor device.

FIG. 12A to FIG. 12D are diagrams illustrating a structure example of a semiconductor device.

FIG. 13A and FIG. 13B are diagrams illustrating a structure example of a semiconductor device.

FIG. 14A to FIG. 14D are diagrams illustrating a structure example of a semiconductor device.

FIG. 15A and FIG. 15B are diagrams illustrating a structure example of a semiconductor device.

FIGS. 16A and 16B are diagrams illustrating a structure example of a semiconductor device.

FIG. 17A and FIG. 17B are diagrams illustrating a structure example of a semiconductor device.

FIG. 18A and FIG. 18B are diagrams illustrating a structure example of a semiconductor device.

FIG. 19A and FIG. 19B are diagrams illustrating a structure example of a semiconductor device.

FIG. 20A to FIG. 20C are diagrams each illustrating a structure example of a semiconductor device.

FIG. 21A to FIG. 21C are diagrams illustrating a method for manufacturing a semiconductor device.

FIG. 22A to FIG. 22C are diagrams illustrating a method for manufacturing a semiconductor device.

FIG. 23A to FIG. 23C are diagrams illustrating a method for manufacturing a semiconductor device.

FIG. 24A to FIG. 24C are diagrams illustrating a method for manufacturing a semiconductor device.

FIG. 25A to FIG. 25C are diagrams illustrating a method for manufacturing a semiconductor device.

FIG. 26A and FIG. 26B are diagrams illustrating a method for manufacturing a semiconductor device.

FIG. 27A and FIG. 27B are diagrams illustrating a method for manufacturing a semiconductor device.

FIG. 28A and FIG. 28B are diagrams illustrating a method for manufacturing a semiconductor device.

FIG. 29A and FIG. 29B are diagrams illustrating a method for manufacturing a semiconductor device.

FIG. 30A to FIG. 30C are diagrams illustrating a method for manufacturing a semiconductor device.

FIG. 31A and FIG. 31B are diagrams illustrating a method for manufacturing a semiconductor device.

FIG. 32 is a diagram illustrating a structure example of a display device.

FIG. 33A and FIG. 33B are diagrams illustrating structure examples of a display device.

FIG. 34 is a diagram illustrating a structure example of a display device.

FIG. 35A to FIG. 35D are diagrams illustrating an example of pixel arrangement.

FIG. 36A is a top view illustrating an example of a display device. FIG. 36B is a cross-sectional view illustrating an example of the display device.

FIG. 37A to FIG. 37C are cross-sectional views each illustrating an example of a display device.

FIG. 38A and FIG. 38B are cross-sectional views each illustrating an example of a display device.

FIG. 39A to FIG. 39C are cross-sectional views each illustrating an example of a display device.

FIG. 40A to FIG. 40F are cross-sectional views each illustrating an example of a display device.

FIG. 41 is a perspective view illustrating an example of a display device.

FIG. 42 is a cross-sectional view illustrating an example of a display device.

FIG. 43A to FIG. 43F are diagrams each illustrating a structure example of a light-emitting device.

FIG. 44A and FIG. 44B are diagrams illustrating an example of an electronic device.

FIG. 45A to FIG. 45D are diagrams illustrating examples of electronic devices.

FIG. 46A to FIG. 46F are diagrams illustrating examples of electronic devices.

FIG. 47 shows measurement results of Id-Vg characteristics.

FIG. 48 shows measurement results of reliability.

FIG. 49A and FIG. 49 B show measurement results of reliability.

FIG. 50A and FIG. 50B show measurement results of Id-Vg characteristics.

### MODE FOR CARRYING OUT THE INVENTION

Hereinafter, embodiments will be described with reference to the drawings. Note that the embodiments can be implemented with many different modes, and it will be readily understood by those skilled in the art that modes and details thereof can be changed in various ways without departing from the spirit and scope thereof. Thus, the present invention should not be interpreted as being limited to the following description of the embodiments.

Note that in structures of the present invention described below, the same reference numerals are commonly used for the same portions or portions having similar functions in different drawings, and a repeated description thereof is omitted. Furthermore, the same hatch pattern is used for the portions having similar functions, and the portions are not especially denoted by reference numerals in some cases.

In each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first,” “second,” and the like are used in order to avoid confusion among components and do not limit the number.

A transistor is a kind of semiconductor element and can achieve a function of amplifying a current or a voltage, a switching operation for controlling conduction or non-conduction, and the like. An IGFET (Insulated Gate Field Effect Transistor) and a thin film transistor (TFT) are in the category of a transistor in this specification and the like.

Functions of a “source” and a “drain” are sometimes replaced with each other when a transistor of opposite polarity is used or when the direction of current is changed in circuit operation, for example. Therefore, the terms “source” and “drain” can be switched in this specification.

In this specification and the like, one of a source and a drain of a transistor is referred to as a “first electrode” and the other of the source and the drain is referred to as a “second electrode” in some cases. Note that a gate is also referred to as a “gate” or a “gate electrode”.

In this specification and the like, “electrically connected” includes the case where connection is made through an “object having any electric function”. Here, there is no particular limitation on the “object having any electric function” as long as electric signals can be transmitted and received between components that are connected through the object. Examples of the “object having any electric function” include a switching element such as a transistor, a resistor, a coil, a capacitor, and other elements with a variety of functions as well as an electrode and a wiring.

In this specification and the like, the term “film” and the term “layer” can be interchanged with each other. For example, in some cases, the term “conductive layer” and the term “insulating layer” can be interchanged with the term “conductive film” and the term “insulating film”, respectively.

Note that in this specification and the like, an EL layer means a layer containing at least a light-emitting substance (also referred to as a light-emitting layer) or a stacked-layer body including the light-emitting layer provided between a pair of electrodes of a light-emitting device (also referred to as a light-emitting element).

In this specification and the like, a display panel that is one embodiment of a display device has a function of displaying (outputting) an image or the like on (to) a display surface. Thus, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module, a display module, or simply a display panel or the like in some cases.

### Embodiment 1

In this embodiment, a semiconductor device of one embodiment of the present invention and a manufacturing method thereof will be described.

A semiconductor device of one embodiment of the present invention includes at least two types of transistors (a first transistor and a second transistor) over a substrate. The first transistor includes a channel formation region in a first semiconductor layer, and the second transistor includes a channel formation region in a second semiconductor layer. Each of the first semiconductor layer and the second semiconductor layer can be formed using a metal oxide. For each of the first semiconductor layer and the second semiconductor layer, a metal oxide containing indium can be favorably used.

The first semiconductor layer and the second semiconductor layer preferably include metal oxides that are different in at least one of the composition, thickness, crystallinity, carrier concentration and film quality. In particular, the first semiconductor layer and the second semiconductor layer preferably include metal oxides with different compositions. The compositions of the first semiconductor layer and the second semiconductor layer greatly affect electrical characteristics and reliability of the first transistor and the second transistor.

For example, the atomic ratio of indium to metal elements contained in the second semiconductor layer is preferably higher than that in the first semiconductor layer. With such a structure, the second transistor can have higher operation speed and higher on-state current than the first transistor. When the semiconductor device of one embodiment of the present invention is used for a display device, the second transistor is applicable to a source driver (also referred to as a source line driver circuit or a signal line driver circuit) or a demultiplexer circuit requiring high-speed switching operation.

Meanwhile, a pixel circuit and a gate driver (also referred to as a gate line driver circuit or a scan line driver circuit) in the display device are not required to achieve switching operation speed as high as that achieved by a source driver or a demultiplexer circuit. In the case where the pixel circuit and the gate driver are formed with the second transistors, an increase in transistor size (for example, an increase in a channel length) is necessary for obtaining appropriate electrical characteristics, resulting in an increase in area occupied by such circuits. Thus, the pixel circuit and the gate driver are formed with the first transistors with lower on-state current than the second transistors, whereby the area occupied by the pixel circuit and the gate driver can be made small. Consequently, the area occupied by the pixel circuit can be reduced, so that a high-resolution display device can be achieved. In addition, the smaller area occupied by the gate driver will achieve a display device with a narrow bezel. Hence, a display device what is called on-panel, where a pixel circuit and a driver circuit including a plurality of types of transistors are formed over one substrate as described, can be achieved.

More specific examples are described below with reference to drawings.

### <Structure Example 1>

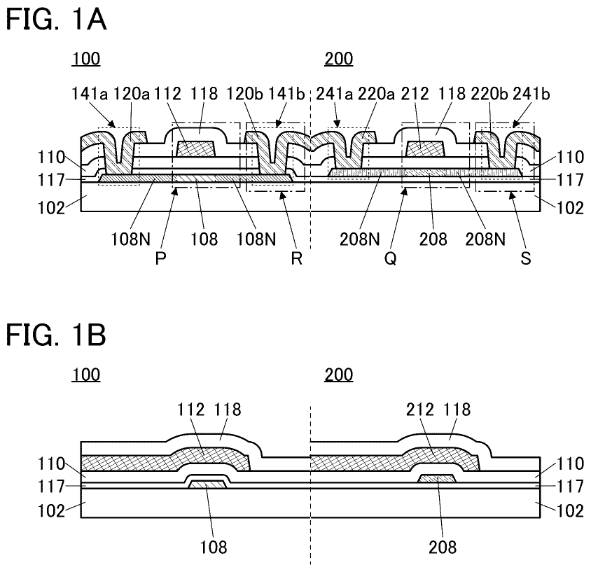

Transistors that can be used in the semiconductor device of one embodiment of the present invention are described. FIG. 1A and FIG. 1B are schematic cross-sectional views of a transistor 100 and a transistor 200. The schematic cross-sectional view of FIG. 1A shows the transistor 100 and the transistor 200, which are provided over a substrate 102, in the channel length direction, and the schematic cross-sectional view of FIG. 1B shows the transistor 100 and the transistor 200 in the channel width direction.

The transistor 100 includes a semiconductor layer 108, an insulating layer 117, an insulating layer 110, and a conductive layer 112 that are stacked in this order. Parts of the insulating layer 117 and the insulating layer 110 function as a gate insulating layer of the transistor 100. The conductive layer 112 functions as the gate electrode of the transistor 100. The transistor 100 is what is called a top-gate transistor, in which the gate electrode is provided over the semiconductor layer 108.

The transistor 200 includes a semiconductor layer 208, the insulating layer 110, and a conductive layer 212 that are stacked in this order. Part of the insulating layer 110 functions as a gate insulating layer of the transistor 200. The conductive layer 212 functions as a gate electrode of the transistor 200. The transistor 200 is what is called a top-gate transistor, in which the gate electrode is provided over the semiconductor layer 208. The transistor 200 is different from the transistor 100 in a surface where the semiconductor layer is formed. Furthermore, the transistor 200 is different from the transistor 100 in the structure of the gate insulating layer.

The components of the transistor 100 and the transistor 200 other than their semiconductor layers can be formed in the same steps. This can inhibit an increase in the number of steps even when two types of transistors are incorporated.

The semiconductor layer 108 is provided over and in contact with the substrate 102. The insulating layer 117 is provided in contact with a top surface of the substrate 102 and top and side surfaces of the semiconductor layer 108. The semiconductor layer 208 is provided over and in contact with the insulating layer 117. In other words, the semiconductor layer 208 is provided on a plane different from that where the semiconductor layer 108 is provided. The insulating layer 117 serves as a base film in the transistor 200. The insulating layer 110 is provided in contact with a top surface of the insulating layer 117 and top and side surfaces of the semiconductor layer 208. The conductive layer 112 and the conductive layer 212 are provided over and in contact with the insulating layer 110. The conductive layer 112 includes a region overlapping with the semiconductor layer 108 with the insulating layer 117 and the insulating layer 110 therebetween. The conductive layer 212 includes a region overlapping with the semiconductor layer 208 with the insulating layer 110 therebetween.

As illustrated in FIG. 1A, it is preferable that the transistor 100 and the transistor 200 further include an insulating layer 118. The insulating layer 118 is provided to cover the insulating layer 110, the conductive layer 112, and the conductive layer 212 and functions as a protective layer for protecting the transistor 100 and the transistor 200.

The transistor 100 may include a conductive layer 120a and a conductive layer 120b over the insulating layer 118. The conductive layer 120a functions as one of a source electrode and a drain electrode of the transistor 100, and the conductive layer 120b functions as the other of the source electrode and the drain electrode of the transistor 100. The conductive layer 120a and the conductive layer 120b are electrically connected to low-resistance regions 108N in the semiconductor layer 108 through an opening portion 141a and an opening portion 141b which are provided in the insulating layer 118, the insulating layer 110, and the insulating layer 117.

The transistor 200 may include a conductive layer 220a and a conductive layer 220b over the insulating layer 118. The conductive layer 220a functions as one of a source electrode and a drain electrode of the transistor 200, and the conductive layer 220b functions as the other of the source electrode and the drain electrode of the transistor 200. The conductive layer 220a and the conductive layer 220b are electrically connected to low-resistance regions 208N in the semiconductor layer 208 through an opening portion 241a and an opening portion 241b provided in the insulating layer 118 and the insulating layer 110.

It is preferable to contain a metal oxide (also referred to as an oxide semiconductor) in each of the semiconductor layer 108 in the transistor 100 and the semiconductor layer 208 in the transistor 200. In other words, it is preferable to use a transistor including a metal oxide in a channel formation region (hereinafter, also referred to as an OS transistor) for each of the transistor 100 and the transistor 200. Alternatively, each of the semiconductor layer 108 and the semiconductor layer 208 may contain silicon. Examples of silicon include amorphous silicon and crystalline silicon (e.g., low-temperature polysilicon or single crystal silicon). The material used for the semiconductor layer 108 may be different from the material used for the semiconductor layer 208.

The band gap of a metal oxide included in each of the semiconductor layer 108 and the semiconductor layer 208 is preferably 2.0 eV or more, further preferably 2.5 eV or more. The use of a metal oxide having a wide bandgap makes the off-state current of an OS transistor extremely low. For example, such a low off-state current enables long-term retention of charge accumulated in a capacitor that is connected in series with the OS transistor. Furthermore, a semiconductor device using an OS transistor enables low power consumption.

A change in electrical characteristics of an OS transistor due to irradiation with radiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include X-rays and a neutron beam.

Here, the compositions of metal oxides applicable to the semiconductor layer 108 and the semiconductor layer 208 are described. Note that the composition of the metal oxide may be replaced with the composition of the semiconductor layer in some cases.

The metal oxide preferably contains at least indium or zinc. Note that the metal oxide further preferably contains indium and zinc. A metal oxide preferably contains indium, an element M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Examples of the applicable metal oxide include indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide), and indium gallium aluminum zinc oxide (In—Ga—Al—Zn oxide, also referred to as IGAZO or IAGZO). Alternatively, indium tin oxide containing silicon, or the like can also be used.

In particular, the element M is preferably one or more kinds selected from gallium, aluminum, yttrium, and tin, and the element M is further preferably gallium. In this specification and the like, a metal oxide containing indium, the element M, and zinc is referred to as In-M-Zn oxide in some cases.

The compositions of the semiconductor layer 108 and the semiconductor layer 208 greatly affect the electrical characteristics and reliability of the transistor 100 and the transistor 200.

For example, higher content of indium in the semiconductor layer enables the transistor to have a high on-state current.

As an In—Zn oxide used for the semiconductor layer, a metal oxide in which the atomic proportion of indium is higher than or equal to that of zinc is preferably used. For example, it is possible to use a metal oxide in which the atomic ratio of metal elements is In:Zn=1:1, In:Zn=2:1, In:Zn=3:1, In:Zn=4:1, In:Zn=5:1, In:Zn=7:1, or In:Zn=10:1, or in the neighborhood thereof.

In the case where an In—Sn oxide is used for the semiconductor layer, a metal oxide in which the atomic proportion of indium is higher than or equal to that of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or in the neighborhood thereof.

In the case where an In—Sn—Zn oxide is used for the semiconductor layer, it is possible to use a metal oxide in which the atomic proportion of indium is higher than that of tin. It is further preferable to use a metal oxide in which the atomic proportion of zinc higher than that of tin. For example, it is possible to use a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the neighborhood thereof.

In the case where an In—Al—Zn oxide is used for the semiconductor layer, it is possible to use a metal oxide in which the atomic proportion of indium is higher than that of aluminum. It is further preferable to use a metal oxide in which the atomic proportion of zinc is higher than that of aluminum. For example, it is possible to use a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the neighborhood thereof.

In the case where an In—Ga—Zn oxide is used for the semiconductor layer, it is possible to use a metal oxide in which the atomic proportion of indium is higher than that of gallium. It is further preferable to use a metal oxide film in which the atomic ratio of zinc is higher than gallium. For example, a metal oxide having any of the following atomic ratios of metal elements can be used as the semiconductor layer: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and a neighborhood thereof.

In the case where an In-M-Zn oxide is used for the semiconductor layer, it is possible to use a metal oxide in which the atomic proportion of indium is higher than that of the element M. It is further preferable to use a metal oxide film in which the atomic ratio of zinc is higher than the element M. For example, a metal oxide having any of the following atomic ratios of metal elements can be used as the semiconductor layer: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, or a neighborhood thereof.

In the case where a plurality of metal elements are contained as the element M, the atomic proportion of the sum of the metal elements can be the atomic proportion of the element M. In In—Ga—Al—Zn oxide where gallium and aluminum are contained as the element M, for example, the atomic proportion of the sum of gallium and aluminum can be the atomic proportion of the element M. The atomic ratio of indium to the element M to zinc is preferably within the ranges given above.

It is preferable to use a metal oxide in which the atomic ratio of indium the metal elements contained in the semiconductor layer is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, further preferably higher than or equal to 35 atomic % and lower than or equal to 90 atomic %, further preferably higher than or equal to 40 atomic % and lower than or equal to 90 atomic %, further preferably higher than or equal to 45 atomic % and lower than or equal to 90 atomic %, further preferably higher than or equal to 50 atomic % and lower than or equal to 80 atomic %, further preferably higher than or equal to 60 atomic % and lower than or equal to 80 atomic %, further preferably higher than or equal to 70 atomic % and lower than or equal to 80 atomic %. For example, when an In—Ga—Zn oxide is used for the semiconductor layer, the atomic ratio of indium to gallium to zinc is preferably within the ranges given above.

In this specification and the like, the atomic ratio of indium to the metal elements contained is sometimes referred to as indium content. The same applies to other metal elements.

Higher indium content in the semiconductor layer enables the transistor to have a high on-state current. By using such a transistor as a transistor required to have a high on-state current, a semiconductor device having excellent electrical characteristics can be provided.

As an analysis method of the composition of a metal oxide, for example, energy dispersive X-ray spectroscopy (EDX), X-ray photoelectron spectrometry (XPS), inductively coupled plasma-mass spectrometry (ICP-MS), or inductively coupled plasma-atomic emission spectrometry (ICP-AES), can be used. Alternatively, such kinds of analysis methods may be performed in combination. Note that as for an element whose content is low, the actual content may be different from the content obtained by analysis because of the influence of the analysis accuracy. In the case where the content of the element M is low, for example, the content of the element M obtained by analysis may be lower than the actual content.

Note that a composition in the neighborhood in this specification and the like includes the range of ±30% of an intended atomic ratio. For example, when the atomic ratio is described as In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. When the atomic ratio is described as In:M:Zn=5:1:6 or a composition in the neighborhood thereof, the case is included where the atomic ratio of the element M is greater than 0.1 and less than or equal to 2 and the atomic ratio of zinc is greater than or equal to 5 and less than or equal to 7 with the atomic ratio of indium being 5. When the atomic ratio is described as In:M:Zn=1:1:1 or a composition in the neighborhood thereof, the case is included where the atomic ratio of the element M is greater than 0.1 and less than or equal to 2 and the atomic ratio of zinc is greater than 0.1 and less than or equal to 2 with the atomic ratio of indium being 1.

Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately 40% to 90% of the atomic ratio of zinc contained in the target.

Here, the reliability of a transistor is described.

One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation is performed are respectively referred to as a PBTIS (Positive Bias Temperature Illumination Stress) test and an NBTIS (Negative Bias Temperature Illumination Stress) test.

In particular, in an n-channel transistor, a positive potential is applied to a gate in putting the transistor in an on state (a state where current flows); thus, the amount of change in threshold voltage in the PBTS test is one important item to be focused on as an indicator of the reliability of the transistor.

With use of a metal oxide that does not contain gallium or has low gallium content in the semiconductor layer, the transistor can be highly reliable against positive bias application. In other words, the amount of change in the threshold voltage of the transistor in the PBTS test can be small. Meanwhile, with use of a metal oxide that contains gallium, the gallium content is preferably lower than the indium content so that the transistor can be highly reliable. Thus, a highly reliable transistor can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content in a region of the semiconductor layer that is in contact with the gate insulating layer.

The following can be given as the reason why the amount of change in the threshold voltage in the PBTS test can be reduced when a metal oxide that does not contain gallium or has low gallium content is used for the semiconductor layer. Gallium contained in the semiconductor layer has a property of attracting oxygen more easily than another metal element (e.g., indium or zinc) does. Thus, when, at the interface between a metal oxide film containing a large amount of gallium and the gate insulating layer, gallium is bonded to excess oxygen in the gate insulating layer, trap sites of carriers (here, electrons) are probably generated easily. This might cause the change in the threshold voltage when a positive potential is applied to a gate and carriers are trapped at the interface between the semiconductor layer and the gate insulating layer.

Specifically, in the case where an In—Ga—Zn oxide is used for the semiconductor layer, a metal oxide film in which the atomic proportion of indium is higher than that of gallium can be used as the semiconductor layer. It is further preferable to use a metal oxide film in which the atomic proportion of zinc is higher than that of gallium. In other words, a metal oxide film in which the atomic proportions of metal elements satisfy In >Ga and Zn>Ga is preferably used as the semiconductor layer.

For example, a metal oxide film having any of the following atomic ratios of metal elements can be used as the semiconductor layer: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and a neighborhood thereof.

The semiconductor layer is preferably formed using a metal oxide having the following compositions; the atomic ratio of gallium to the metal elements contained in the metal oxide is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, further preferably higher than or equal to 0.1 atomic % and lower than or equal to 30 atomic %, further preferably higher than or equal to 0.1 atomic % and lower than or equal to 25 atomic %, further preferably higher than or equal to 0.1 atomic % and lower than or equal to 20 atomic %, further preferably higher than or equal to 0.1 atomic % and lower than or equal to 15 atomic %, further preferably higher than or equal to 0.1 atomic % and lower than or equal to 10 atomic %. The reduction in the gallium content in the semiconductor layer enables the transistor to be highly resistant to the PBTS test. Note that oxygen vacancies (Vo) are less likely to be generated in the metal oxide when the semiconductor layer contains gallium.

A metal oxide film not containing gallium may be used as the semiconductor layer. For example, an In—Zn oxide can be used for the semiconductor layer. In this case, when the atomic ratio of indium to metal elements contained in the metal oxide film is increased, the field-effect mobility of the transistor can be increased. By contrast, when the atomic ratio of zinc to metal elements contained in the metal oxide is increased, the metal oxide film has high crystallinity; thus, a change in the electrical characteristics of the transistor can be inhibited and the reliability can be increased. Alternatively, a metal oxide film that contains neither gallium nor zinc, such as indium oxide, can be used as the semiconductor layer. The use of a metal oxide film not containing gallium at all can make a change in the threshold voltage particularly in the PBTS test extremely small.

For example, an oxide containing indium and zinc can be used for the semiconductor layer. In that case, for example, a metal oxide film where the atomic ratio of metal elements of In:Zn=2:3, In:Zn=4:1, or a neighborhood thereof can be used.

Although the case of using gallium is described as an example, the same applies to the case where the element M is used instead of gallium. In particular, a metal oxide film in which the atomic proportion of indium is higher than the atomic proportion of the element M is preferably used as the semiconductor layer. Furthermore, a metal oxide film in which the atomic proportion of zinc is higher than the atomic proportion of the element M is preferably used.

Low content of the element M in the semiconductor layer enables the transistor to be highly reliable against positive bias application. With use of the transistor as a transistor that is required to have high reliability against positive bias application, a highly reliable semiconductor device can be provided.

Next, the reliability of a transistor against light is described.

Light irradiation on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in a NBTIS test, for example.

The high content of the element M in the semiconductor layer enables the transistor to be highly reliable against light. In other words, the amount of change in the threshold voltage of the transistor in the NBTIS test can be small. Specifically, in a metal oxide in which the atomic proportion of the element M is higher than or equal to that of indium, the band gap is increased and accordingly the amount of change in the threshold voltage of the transistor in the NBTIS test can be reduced. The band gap of the metal oxide in the semiconductor layer is preferably greater than or equal to 2.0 eV, further preferably greater than or equal to 2.5 eV, further preferably greater than or equal to 3.0 eV, further preferably greater than or equal to 3.2 eV, further preferably greater than or equal to 3.3 eV, further preferably greater than or equal to 3.4 eV, further preferably greater than or equal to 3.5 eV.

For example, the semiconductor layer can include a metal oxide film having any of the following atomic ratios: In:M:Zn=1:1:1, In:M:Zn=1:3:1.2, In:M:Zn=1:3:2, In:M:Zn=1:3:3, In:M:Zn=1:3:4, and a neighborhood thereof.

For the semiconductor layer, in particular, it is preferable to use a metal oxide in which the atomic ratio of the element M to the metal elements contained in the semiconductor layer is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, further preferably higher than or equal to 40 atomic % and lower than or equal to 60 atomic %, further preferably higher than or equal to 50 atomic % and lower than or equal to 60 atomic %.

In the case where an In—Ga—Zn oxide is used for the semiconductor layer, a metal oxide in which the atomic proportion of indium is less than or equal to that of gallium can be used. For example, it is possible to use a metal oxide having any of the following atomic ratios: In:Ga:Zn=1:1:1, In:Ga:Zn=1:1:1.2, In:Ga:Zn=1:3:2, In:Ga:Zn=1:3:3, In:Ga:Zn=1:3:4, and a neighborhood thereof.

For the semiconductor layer, in particular, it is preferable to use a metal oxide in which the atomic ratio of gallium to the metal elements contained in the semiconductor layer is higher than or equal to 20 atomic % and lower than or equal to 60 atomic %, preferably higher than or equal to 20 atomic % and lower than or equal to 50 atomic %, further preferably higher than or equal to 30 atomic % and lower than or equal to 50 atomic %, further preferably higher than or equal to 40 atomic % and lower than or equal to 60 atomic %, further preferably higher than or equal to 50 atomic % and lower than or equal to 60 atomic %.

The high content of the element M in the semiconductor layer enables the transistor to be highly reliable against light. With use of the transistor as a transistor that is required to have high reliability against light, a highly reliable semiconductor device can be provided.

Here, the semiconductor layer 108 preferably contains a metal oxide whose composition is different from that of a metal oxide contained in the semiconductor layer 208. The semiconductor layer 108 and the semiconductor layer 208 can be formed by processing metal oxides with different compositions. In the semiconductor device of one embodiment of the present invention, a plurality of transistors whose semiconductor layers are different in their compositions are provided over one substrate, and components other than the semiconductor layers can be formed in the same steps.

As described above, electrical characteristics and reliability of a transistor depend on the composition of the metal oxide used for the semiconductor layer. Therefore, by determining the composition of the metal oxide in accordance with the electrical characteristics and reliability required for the transistor, the semiconductor device can have both good electrical characteristics and high reliability.

An example where the transistor 200 is used as a transistor requiring a high on-state current is described. In the case where an In—Ga—Zn oxide is used for both the semiconductor layer 108 and the semiconductor layer 208, a metal oxide used in the semiconductor layer 208 can have a higher atomic ratio of indium to metal elements contained in the metal oxide than a metal oxide used in the semiconductor layer 108, for example.

Also in the case where an In—Ga—Zn oxide is used for the semiconductor layer 108 and a metal oxide containing indium, other than the In—Ga—Zn oxide, is used for the semiconductor layer 208, the metal oxide used in the semiconductor layer 208 can have a higher atomic ratio of indium atoms to metal elements contained in the metal oxide than a metal oxide used in the semiconductor layer 108.

A metal oxide containing indium, other than the In—Ga—Zn oxide, can be used for the semiconductor layer 108. Also in that case, a metal oxide used in the semiconductor layer 208 can have a higher atomic ratio of indium to metal elements contained in the metal oxide than a metal oxide used in the semiconductor layer 108.

Alternatively, the semiconductor layer 108 may be formed using a metal oxide that has a higher atomic ratio of indium to metal elements contained in the metal oxide than a metal oxide used in the semiconductor layer 208.

An example where the transistor 200 is used as a transistor requiring high reliability against positive bias application is described. In the case where an In—Ga—Zn oxide is used for both the semiconductor layer 108 and the semiconductor layer 208, for example, the semiconductor layer 208 can be formed using a metal oxide that has a lower atomic ratio of gallium to metal elements contained in a metal oxide than a metal oxide film used in the semiconductor layer 108. For example, an In—Ga—Zn oxide may be used for the semiconductor layer 108, and a metal oxide not containing gallium may be used for the semiconductor layer 208.

The semiconductor layer 208 may be formed using a metal oxide in which with respect to contained metal elements, the atomic ratio of indium is high and the atomic ratio of the element M is low, as compared to a metal oxide used in the semiconductor layer 108. With such a structure, the transistor 200 enables the on-state current and reliability against positive bias application to be increased.

Alternatively, the semiconductor layer 108 may be formed using a metal oxide in which the atomic ratio of the element M to contained metal elements is lower than a metal oxide used in the semiconductor layer 208. Furthermore, the semiconductor layer 108 may be formed using a metal oxide in which, with respect to contained metal elements, the atomic ratio of indium is high and the atomic ratio of the element M is low, as compared to a metal oxide used in the semiconductor layer 208.

An example where the transistor 200 is used as a transistor requiring high reliability against light is described. The semiconductor layer 208 can be formed using a metal oxide in which the atomic ratio of the element M to contained metal elements is higher than a metal oxide used in the semiconductor layer 108. For example, an In—Ga—Zn oxide may be used for the semiconductor layer 208, and a metal oxide not containing gallium may be used for the semiconductor layer 108.

Alternatively, the semiconductor layer 108 may be formed using a metal oxide in which the atomic ratio of the element M to contained metal elements is higher than a metal oxide used in the semiconductor layer 208.

An example where the transistor 100 is used as a transistor requiring high reliability against light and the transistor 200 is used as a transistor requiring high on-state current is described. The semiconductor layer 108 can be formed using a metal oxide in which the atomic ratio of the element M to contained metal elements is higher than a metal oxide used in the semiconductor layer 208. The semiconductor layer 208 can be formed using a metal oxide in which the atomic ratio of indium to contained metal elements is higher than a metal oxide used in the semiconductor layer 108.

Metal oxides that can be used for the semiconductor layer 108 and the semiconductor layer 208 are different in at least one of the thickness, crystallinity, carrier concentration, and film quality as well as the composition. For example, in addition to the composition difference, the thickness or the deposition condition of the metal oxides may be varied between the semiconductor layer 108 and the semiconductor layer 208 so that the on-state current of the transistor 200 is higher than the on-state current of the transistor 100.

The semiconductor layer 108 includes a region overlapping with the conductive layer 112 and a pair of low-resistance regions 108N between which the region is sandwiched. A region of the semiconductor layer 108 that overlaps with the conductive layer 112 functions as a channel formation region of the transistor 100. The pair of low-resistance regions 108N function as a source region and a drain region of the transistor 100. The semiconductor layer 208 similarly includes a channel formation region overlapping with the conductive layer 212 and a pair of low-resistance regions 208N between which the region is sandwiched.

In the transistor 100, the low-resistance region 108N can be regarded as a region having lower resistance than the channel formation region of the transistor 100, a region having a higher carrier concentration than the channel formation region, a region having a higher density of oxygen vacancy than the channel formation region, a region having a higher impurity concentration than the channel formation region, or an n-type region. Also in the transistor 200, the low-resistance region 208N can be regarded as a region having lower resistance than the channel formation region of the transistor 200, a region having a higher carrier concentration than the channel formation region, a region having a higher density of oxygen vacancy than the channel formation region, a region having a higher impurity concentration than the channel formation region, or an n-type region.

Each of the low-resistance region 108N and the low-resistance region 208N is a region including an impurity element. Examples of the impurity element are hydrogen, boron, carbon, nitrogen, fluorine, phosphorus, sulfur, arsenic, aluminum, and a noble gas. Note that typical examples of a noble gas include helium, neon, argon, krypton, and xenon. In particular, the low-resistance region 108N and the low-resistance region 208N preferably include boron or phosphorus. The low-resistance region 108N and the low-resistance region 208N may include two or more elements mentioned above. The low-resistance region 108N and the low-resistance region 208N may include different impurity elements.

The low-resistance region 108N and the low-resistance region 208N can be formed by adding impurities through the insulating layer 110 with use of the conductive layer 112 and the conductive layer 212 as masks, for example.

Each of the e low-resistance region 108N and the low-resistance region 208N preferably includes a region where the impurity concentration is higher than or equal to 1×10¹⁹ atoms/cm³ and lower than or equal to 1×10²³ atoms/cm³, preferably higher than or equal to 5×10¹⁹ atoms/cm³ and lower than or equal to 5×10²² atoms/cm³, further preferably higher than or equal to 1×10²⁰ atoms/cm³ and lower than or equal to 1×10²² atoms/cm³.

The concentrations of the impurities included in the low-resistance region 108N and the low-resistance region 208N can be analyzed by an analysis method such as secondary ion mass spectrometry (SIMS) or X-ray photoelectron spectroscopy (XPS). In the case of using XPS analysis, ion sputtering from the front surface side or the back surface side is combined with XPS analysis, whereby the concentration distribution in the depth direction can be found.

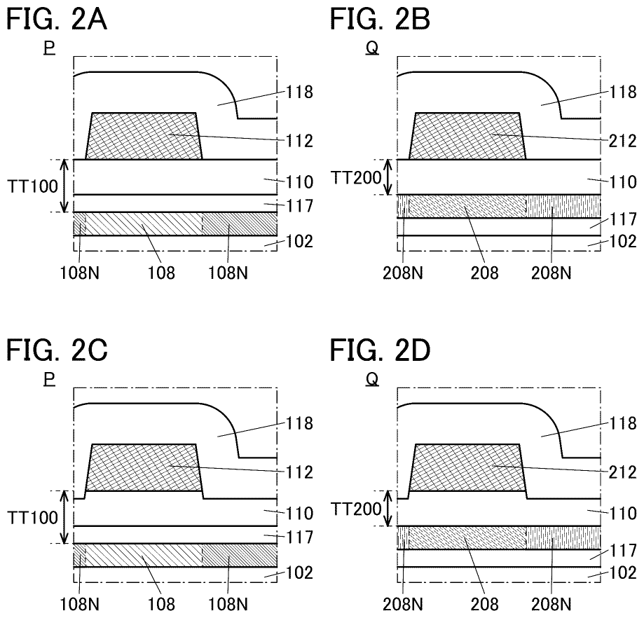

FIG. 2A shows an enlarged view of a region P indicated by the dashed-dotted line in FIG. 1A. FIG. 2B shows an enlarged view of a region Q indicated by the dashed-dotted line in FIG. 1A.

Each of the insulating layer 110 and the insulating layer 117 in contact with semiconductor layer 108 or the semiconductor layer 208 preferably includes an oxide or an oxynitride. Each of the insulating layer 110 and the insulating layer 117 may include a region containing oxygen in excess of that in the stoichiometric composition. In other words, each of the insulating layer 110 and the insulating layer 117 may include an insulating film capable of releasing oxygen. It is also possible to supply oxygen into the insulating layer by forming an insulating layer in an oxygen atmosphere, performing heat treatment in an oxygen atmosphere after the formation of the insulating layer, performing plasma treatment or the like in an oxygen atmosphere after the formation of the insulating layer, or depositing an oxide film or an oxynitride film over the insulating layer in an oxygen atmosphere, for example. Note that an oxidizing gas (e.g., one or more of dinitrogen monoxide and ozone) may be used instead of oxygen or in addition to oxygen in each of the above treatments for supplying oxygen.

Note that in this specification and the like, oxynitride refers to a material that contains more oxygen than nitrogen, and nitride oxide refers to a material that contains more nitrogen than oxygen. For example, in the case where silicon oxynitride is described, it refers to a material that contains more oxygen than nitrogen in its composition. In the case where silicon nitride oxide is described, it refers to a material that contains more nitrogen than oxygen in its composition. Each of the insulating layer 110 and the insulating layer 117, for example, can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD) method and a thermal CVD method. An example of the thermal CVD method is a metal organic chemical vapor deposition (MOCVD: Metal Organic CVD) method. In particular, the insulating layer 110 is preferably formed by a PECVD (plasma CVD) method.

For each of the insulating layer 110 and the insulating layer 117, for example, an insulating layer including one or more kinds of a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, and a neodymium oxide film can be used. Note that the insulating layer 110 may have a stacked-layer structure of two layers or a stacked-layer structure of three or more layers. Similarly, the insulating layer 117 may have a stacked-layer structure of two layers or a stacked-layer structure of three or more layers. Alternatively, different materials may be used between the insulating layer 110 and the insulating layer 117.

Each of the insulating layer 110 and the insulating layer 117 can be formed using a material having a higher dielectric constant than silicon oxide and silicon oxynitride. As a material having a high dielectric constant, hafnium oxide can be used, for example. In that case, the insulating layer 110 and the insulating layer 117 can be thick, and a leakage current due to a tunnel current can be inhibited. In particular, hafnium oxide having crystallinity is preferable because it has a higher dielectric constant than amorphous hafnium oxide.

As illustrated in FIG. 2A, a thickness TT100 of the gate insulating layer in the transistor 100 is the sum of the thickness of the insulating layer 110 and the thickness of the insulating layer 117. As illustrated in FIG. 2B, a thickness TT200 of the gate insulating layer in the transistor 200 is the thickness of the insulating layer 110. In other words, the thickness TT100 of the gate insulating layer in the transistor 100 is larger than the thickness TT200 of the gate insulating layer in the transistor 200. It can be said that the thickness TT200 of the gate insulating layer in the transistor 200 is smaller than the thickness TT100 of the gate insulating layer in the transistor 100.

The thickness of the gate insulating layer is increased here, whereby the gate breakdown voltage of the transistor can be increased. On the other hand, the thickness of the gate insulating layer is reduced, whereby the on-state current and the operation speed of the transistor can be increased. In other words, the transistor 100 with high gate breakdown voltage and the transistor 200 with high on-state current and high operation speed can be formed over one substrate. For example, when the transistor 100 is used as a transistor to which high voltages are applied and the transistor 200 is used as a transistor requiring high speed operation, a semiconductor device achieving both high speed operation and high reliability can be provided.

The thickness TT200 of the gate insulating layer in the transistor 200 is preferably greater than or equal to 50% and less than 100%, further preferably greater than or equal to 60% and less than 100%, still further preferably greater than or equal to 60% and less than or equal to 95%, yet still further preferably greater than or equal to 70% and less than or equal to 95%, yet still further preferably greater than or equal to 80% and less than or equal to 95%, and yet still further preferably greater than or equal to 80% and less than or equal to 90% of the thickness TT100 of the gate insulating layer in the transistor 100.

As described above, the composition of the semiconductor layer greatly affect the electrical characteristics and reliability of the transistor 100 or the transistor 200. For example, a metal oxide with higher indium content is used for the semiconductor layer 208 in the transistor 200 whose gate insulating layer has a small thickness, in which case the on-state current of the transistor 200 can be further increased. Furthermore, the indium content in the metal oxide used for the semiconductor layer 208 is preferably higher than that for the semiconductor layer 108. In this manner, with the combination of the composition of the semiconductor layer and the thickness of the gate insulating layer, the electrical characteristics and reliability of the transistor can be further increased, resulting in manufacture of a semiconductor device with excellent electrical characteristics and high reliability.

Alternatively, a metal oxide with higher indium content is used for the semiconductor layer 108 in the transistor 100 whose gate insulating layer has a large thickness, in which case a transistor with high gate breakdown voltage and high on-state current can be provided. Furthermore, the indium content in the metal oxide used for the semiconductor layer 108 is preferably higher than that for the semiconductor layer 208.

For example, a metal oxide with lower content of the element M is used for the semiconductor layer 208 in the transistor 200 whose gate insulating layer has a small thickness, in which case a transistor with high on-state current and high reliability against positive bias application can be provided. Furthermore, the content of the element M in the metal oxide used for the semiconductor layer 208 is preferably lower than that for the semiconductor layer 108.

Alternatively, a metal oxide with lower content of the element M is used for the semiconductor layer 108 in the transistor 100 whose gate insulating layer has a large thickness, in which case a transistor with high gate breakdown voltage and high reliability against positive bias application can be provided. Furthermore, the content of the element M in the metal oxide used for the semiconductor layer 108 is preferably lower than that for the semiconductor layer 208.

For example, a metal oxide with higher content of the element M is used for the semiconductor layer 208 in the transistor 200 whose gate insulating layer has a small thickness, in which case a transistor with high on-state current and high reliability against light can be provided. Furthermore, the content of the element M in the metal oxide used for the semiconductor layer 208 is preferably higher than that for the semiconductor layer 108.

Alternatively, a metal oxide with higher content of the element M is used for the semiconductor layer 108 in the transistor 100 whose gate insulating layer has a large thickness, in which case a transistor with high gate breakdown voltage and high reliability against light can be provided. Furthermore, the content of the element M in the metal oxide used for the semiconductor layer 108 is preferably higher than that for the semiconductor layer 208.

When the thickness of the insulating layer 117 is increased, the difference between the thickness TT100 of the gate insulating layer in the transistor 100 and the thickness TT200 of the gate insulating layer in the transistor 200 can be made large. By contrast, when the thickness of the insulating layer 117 is reduced, the difference between the thickness TT100 of the gate insulating layer in the transistor 100 and the thickness TT200 of the gate insulating layer in the transistor 200 can be made small. In this manner, the thicknesses of the gate insulating layers in the transistor 100 and the transistor 200 can be easily adjusted, depending on characteristics required in the transistor 100 and the transistor 200, without a significant increase in steps.

The thicknesses of the gate insulating layers in the transistor 100 and the transistor 200 can also be adjusted by the thickness of the insulating layer 110. The thickness of the insulating layer 110 is reduced, whereby the difference between the thickness TT100 of the gate insulating layer in the transistor 100 and the thickness TT200 of the gate insulating layer in the transistor 200 can be made large. By contrast, the thickness of the insulating layer 110 is reduced, whereby the difference between the thickness TT100 of the gate insulating layer in the transistor 100 and the thickness TT200 of the gate insulating layer in the transistor 200 can be made small.

The semiconductor layer 108 and the semiconductor layer 208 may be formed using metal oxides with the same compositions. As described above, electrical characteristics (e.g., on-state current) and reliability (e.g., gate breakdown voltage) are varied depending on the thickness of the gate insulating layer. Thus, the thickness of the gate insulating layer is varied between the transistor 100 and the transistor 200 depending on required electrical characteristics and reliability, so that a semiconductor device with excellent electrical characteristics and high reliability can be provided.

Note that as illustrated in FIG. 2C and FIG. 2D, the thickness of the insulating layer 110 in a region not overlapping with the conductive layer 112 may be smaller than the thickness of the insulating layer 110 in a region overlapping with the conductive layer 112. For example, when the conductive layer 112 is formed, a surface of the insulating layer 110 in the region not overlapping with the conductive layer 112 is removed, in which case the thickness of the insulating layer 110 in the region may be made small. Similarly, the thickness of the insulating layer 110 in a region not overlapping with the conductive layer 212 may be smaller than the thickness of the insulating layer 110 in a region overlapping with the conductive layer 212. For example, when the conductive layer 212 is formed, a surface of the insulating layer 110 in the region not overlapping with the semiconductor layer 208 is removed, in which case the thickness of the insulating layer 110 in the region may be made small.

In this specification and the like, the thickness of the gate insulating layer refers to the thickness of a region overlapping with the gate electrode. For example, the thickness TT100 of the gate insulating layer in the transistor 100 refers to the thickness of the gate insulating layer in a region overlapping with the conductive layer 112, that is, the sum of the thickness of the insulating layer 110 in a region overlapping with the conductive layer 112 and the thickness of the insulating layer 117. The thickness TT200 of the gate insulating layer in the transistor 200 refers to the thickness of the gate insulating layer in a region overlapping with the conductive layer 212, that is, the thickness of the insulating layer 110 in a region overlapping with the conductive layer 212.

The insulating layer 117 can serve as an etching stopper for preventing the semiconductor layer 108 from disappearing when the semiconductor layer 208 is formed. The insulating layer 117 preferably has such a thickness as to serve as an etching stopper, that is, such a thickness as not to disappear when the semiconductor layer 208 is formed. The thickness of the insulating layer 117 is preferably larger than or equal to 2 nm and smaller than or equal to 200 nm, further preferably larger than or equal to 2 nm and smaller than or equal to 150 nm, further preferably larger than or equal to 2 nm and smaller than or equal to 100 nm, further preferably larger than or equal to 5 nm and smaller than or equal to 100 nm, further preferably larger than or equal to 5 nm and smaller than or equal to 50 nm, further preferably larger than or equal to 5 nm and smaller than or equal to 30 nm, further preferably larger than or equal to 5 nm and smaller than or equal to 20 nm, further preferably larger than or equal to 5 nm and smaller than or equal to 15 nm, further preferably larger than or equal to 7 nm and smaller than or equal to 15 nm, further preferably larger than or equal to 7 nm and smaller than or equal to 10 nm. Note that in this specification and the like, the thickness of the insulating layer 117 refers to the thickness of a region overlapping with the conductive layer 112.

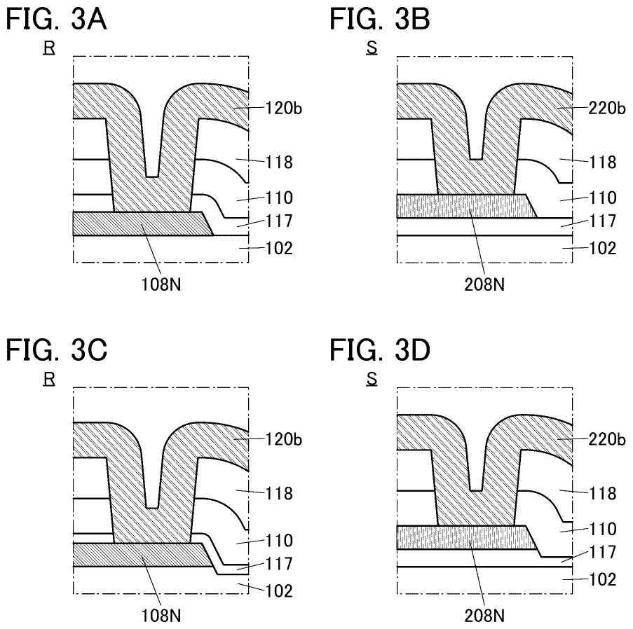

FIG. 3A illustrates an enlarged view of a region R indicated by the dashed-dotted line in FIG. 1A. FIG. 3B illustrates an enlarged view of a region S indicated by the dashed-dotted line in FIG. 1A.

As illustrated in FIG. 3A and FIG. 3B, the insulating layer 117 includes a region in contact with a top surface and a side surface of the semiconductor layer 108. The insulating layer 117 is formed over the semiconductor layer 108, and thus is preferably a film formed under conditions where the semiconductor layer 108 is damaged as little as possible. The insulating layer 110 includes a region in contact with a top surface and a side surface of the semiconductor layer 208. The insulating layer 110 is formed over the semiconductor layer 208, and thus is preferably a film formed under conditions where the semiconductor layer 208 is damaged as little as possible.

Each of the insulating layer 117 and the insulating layer 110 can be formed under a condition of sufficiently low film-formation speed (also referred to as deposition rate). The insulating layer 117 is formed under the conditions where the semiconductor layer 108 is not damaged, so that the density of defect states at the interface between the semiconductor layer 108 and the insulating layer 117 is reduced and the transistor 100 can have high reliability. The insulating layer 110 is formed under the conditions where the semiconductor layer 208 is not damaged, so that the density of defect states at the interface between the semiconductor layer 208 and the insulating layer 110 is reduced and the transistor 200 can have high reliability. Furthermore, damage to the semiconductor layer 108 through the insulating layer 117 can be suppressed.

For example, when the insulating layer 117 and the insulating layer 110 are formed by a plasma CVD method under a low-power condition, damage to the semiconductor layer 108 and the semiconductor layer 208 can be extremely small. When the proportion of the flow rate of the deposition gas in the total flow rate of the film formation gas (hereinafter also simply referred to as a flow rate ratio) is low, the film formation speed can be made low, which allows formation of a dense film with few defects. The insulating layer 117 can be formed under the same conditions as for the insulating layer 110. Note that the insulating layer 117 may be formed under conditions different from those for the insulating layer 110.

As illustrated in FIG. 3C, the thickness of the substrate 102 in a region not overlapping with the semiconductor layer 108 may be smaller than the substrate 102 in a region overlapping with the semiconductor layer 108. For example, in formation of the semiconductor layer 108, a surface of the substrate 102 in the region not overlapping with the semiconductor layer 108 is removed, whereby the thickness of the substrate 102 in the region is reduced in some cases. As illustrated in FIG. 3D, the thickness of the insulating layer 117 in a region not overlapping with the semiconductor layer 208 may be smaller than the thickness of the insulating layer 117 in a region overlapping with the semiconductor layer 208. For example, in formation of the semiconductor layer 208, a surface of the insulating layer 117 in a region not overlapping with the semiconductor layer 208 is removed, whereby the thickness of the insulating layer 117 in the region is reduced in some cases.

Note FIG. 1A and the like illustrate an example in which the thickness of the semiconductor layer 108 in the opening portion 141a is equal to the thickness of the semiconductor layer 108 in a region not overlapping with the opening portion 141a, that is, an example in which the thickness of the semiconductor layer 108 in a region in contact with the conductive layer 120a is equal to the thickness of the semiconductor layer 108 in a region not in contact with the conductive layer 120a. However, one embodiment of the present invention is not limited to such a structure. The thickness of the semiconductor layer 108 in the opening portion 141a may be smaller than the thickness of the semiconductor layer 108 in the region not overlapping with the opening portion 141a; that is, the thickness of the semiconductor layer 108 in the region in contact with the conductive layer 120a may be smaller than the thickness of the semiconductor layer 108 in the region not in contact with the conductive layer 120a. The same applies to the thickness of the semiconductor layer 108 in the opening portion 141b.

The thickness of the semiconductor layer 208 in the opening portion 241a may be smaller than the thickness of the semiconductor layer 208 in a region not overlapping with the opening portion 241a; that is, the thickness of the semiconductor layer 208 in a region in contact with the conductive layer 220a may be smaller than the thickness of the semiconductor layer 208 in a region not in contact with the conductive layer 220a. The same applies to the thickness of the semiconductor layer 208 in the opening portion 241b.

Each of the conductive layer 112 and the conductive layer 212 functioning as the gate electrode is preferably formed using a low-resistance material. When the gate electrode is formed using a low-resistance material, the parasitic resistance can be reduced, and thus a transistor with high on-state current can be obtained. For example, the conductive layer 112 and the conductive layer 212 are preferably formed using a conductive film containing a metal or an alloy, in which case electric resistance can be reduced. Note that a conductive film containing an oxide may be used as the conductive layer 112 and the conductive layer 212. For example, in the case where the semiconductor device of one embodiment of the present invention is used for a large-sized display device or a high-definition display device, a reduction in wiring resistance inhibits signal delay and enables high-speed operation.

For each of the conductive layer 112 and the conductive layer 212, one or more selected from chromium, copper, aluminum, gold, silver, zinc, niobium, molybdenum, tantalum, titanium, tungsten, manganese, nickel, iron, and cobalt can be used. An alloy containing any of the above-described metal elements, an alloy containing the above-described metal elements in combination, or the like may be used for the conductive layer 112 and the conductive layer 212. Copper is particularly preferable because of its low resistance and high mass productivity.

The conductive layer 112 and the conductive layer 212 may each have a stacked-layer structure. In the case where the conductive layer 112 and the conductive layer 212 each have a stacked-layer structure, a second conductive layer is provided over and/or under a first conductive layer having low resistance. For the second conductive layer, a conductive material that is less likely to be oxidized (that has higher oxidation resistance) than the first conductive layer is preferably used. For the second conductive layer, a material that inhibits diffusion of components of the first conductive layer is preferably used. For the second conductive layer, for example, a metal oxide such as indium oxide, indium zinc oxide, indium tin oxide (ITO), indium tin oxide containing silicon (ITSO), or zinc oxide, or a metal nitride such as titanium nitride, tantalum nitride, molybdenum nitride, or tungsten nitride can be suitably used.

An oxide conductor or a metal oxide film such as an In—Sn oxide, an In—W oxide, an In—W—Zn oxide, an In—Ti oxide, an In—Ti—Sn oxide, an In—Zn oxide, an In—Sn—Si oxide, or an In—Ga—Zn oxide can also be used for the conductive layer 112 and the conductive layer 212.

Here, an oxide conductor (OC) is described. For example, when oxygen vacancies are formed in a metal oxide having semiconductor characteristics and hydrogen is supplied to the oxygen vacancies, a donor level is formed in the vicinity of the conduction band. As a result, the conductivity of the metal oxide is increased, so that the metal oxide becomes a conductor. The metal oxide having become a conductor can be referred to as an oxide conductor.

In addition, each of the conductive layer 112 and the conductive layer 212 may have a stacked-layer structure of a conductive film containing the oxide conductor (the metal oxide) and a conductive film containing a metal or an alloy. The use of the conductive film containing a metal or an alloy can reduce the wiring resistance. At this time, a conductive film containing an oxide conductor is preferably used as the conductive film on the side in contact with the insulating layer functioning as a gate insulating film.

For the conductive layer 112, the same material as the conductive layer 212 can be used. The conductive layer 112 and the conductive layer 212 can each be formed by processing a conductive film formed over the insulating layer 110. In other words, the conductive layer 112 can be formed through the same steps as the conductive layer 212. Note that the conductive layer 112 may be formed using a material different from that of the conductive layer 212. The conductive layer 112 may be formed through steps different from those for the conductive layer 212.

A material that can be used for the conductive layer 112 or the conductive layer 212 can be used for each of the conductive layer 120a, the conductive layer 120b, the conductive layer 220a, and the conductive layer 220b functioning as a source electrode or a drain electrode. One or more selected from titanium, tungsten, tantalum, niobium, and molybdenum can also be suitably used for the conductive layer 120a, the conductive layer 120b, the conductive layer 220a, and the conductive layer 220b. In particular, a tantalum nitride film can be favorably used for the conductive layer 120a, the conductive layer 120b, the conductive layer 220a, and the conductive layer 220b. Since a tantalum nitride film has conductivity and a high barrier property against copper, oxygen, or hydrogen and releases little hydrogen from itself, it can be suitably used as the conductive film in contact with the semiconductor layer 108 or the semiconductor layer 208 or a conductive film in the vicinity of the semiconductor layer 108 or the semiconductor layer 208.

The same material as for the conductive layer 220a and the conductive layer 220b can be used for the conductive layer 120a and the conductive layer 120b. The conductive layer 120a, the conductive layer 120b, the conductive layer 220a, and the conductive layer 220b can be formed by processing a conductive film formed over the insulating layer 118. In other words, the conductive layer 120a and the conductive layer 120b can be formed in the same steps as the conductive layer 220a and the conductive layer 220b. Note that the conductive layer 120a and the conductive layer 120b may be formed using a material different from that for the conductive layer 220a and the conductive layer 220b. The conductive layer 120a and the conductive layer 120b may be formed through steps different from those for the conductive layer 220a and the conductive layer 220b.

The insulating layer 118 functioning as a protective layer can be formed using one or both of an inorganic material and an organic material. As an inorganic material, for example, one or more of silicon oxide, silicon oxynitride, silicon nitride, silicon nitride oxide, aluminum oxide, aluminum oxynitride, aluminum nitride, hafnium oxide, and hafnium aluminate can be used. As an organic material, for example, one or both of an acrylic resin and a polyimide resin can be used. As an organic material, a photosensitive material may be used.

With the insulating layer 118, diffusion of impurities from the outside of the transistor 100 and the transistor 200 into the transistor 100 and the transistor 200 can be prevented. Examples of the impurities include water and hydrogen. In particular, an inorganic insulating material such as an oxide, an oxynitride, a nitride oxide, or a nitride can be used for the insulating layer 118.

### <Structure Example 2>

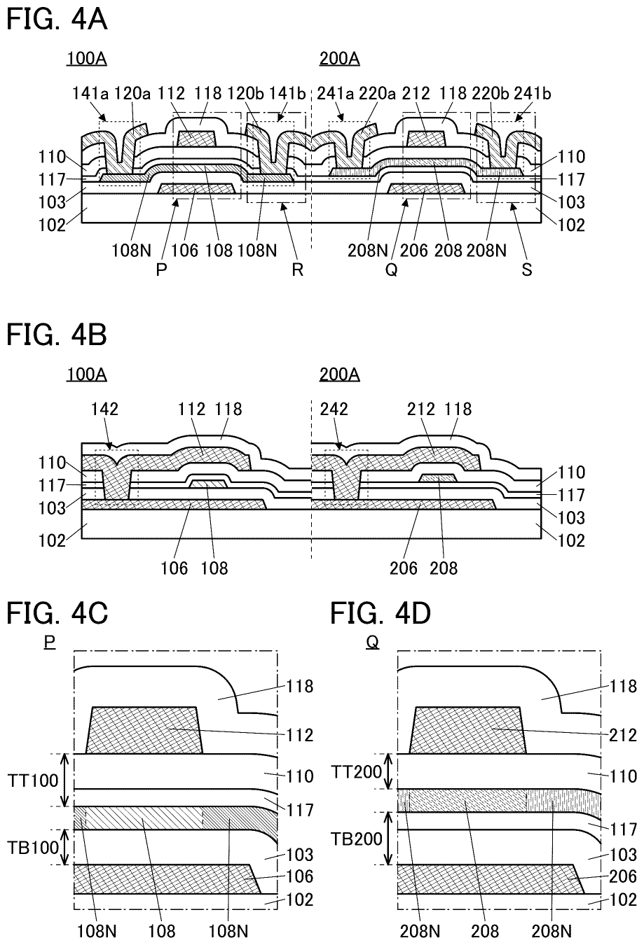

A structure example different from that of the transistor 100 and the transistor 200 is illustrated in FIG. 4A and FIG. 4B. FIG. 4A is a cross-sectional view of a transistor 100A and a transistor 200A in the channel length direction, and FIG. 4B is a cross-sectional view of the transistors in the channel width direction.

The transistor 100A is different from the transistor 100 mainly in including a conductive layer 106 and an insulating layer 103 between the substrate 102 and the semiconductor layer 108. Similarly, the transistor 200A is different from the transistor 200 mainly in including a conductive layer 206, an insulating layer 103, and the insulating layer 117 between the substrate 102 and the semiconductor layer 208. The conductive layer 106 includes a region overlapping with the semiconductor layer 108 with the insulating layer 103 therebetween and a region overlapping with the conductive layer 112 with the semiconductor layer 108 therebetween. The conductive layer 206 includes a region overlapping with the semiconductor layer 208 with the insulating layer 103 and the insulating layer 117 therebetween and a region overlapping with the conductive layer 212 with the semiconductor layer 208 therebetween.

In the transistor 100A, the conductive layer 112 has a function of a first gate electrode (also referred to as a top gate electrode), and the conductive layer 106 has a function of a second gate electrode (also referred to as a bottom gate electrode). In the transistor 100A, part of each of the insulating layer 117 and the insulating layer 110 functions as a first gate insulating layer, and part of the insulating layer 103 functions as a second gate insulating layer. For the insulating layer 103, a material that can be used for the insulating layer 110 or the insulating layer 117 can be used. The insulating layer 117 is provided in contact with a top surface of the insulating layer 103 and a top surface and a side surface of the semiconductor layer 108.

In the transistor 200A, the conductive layer 212 has a function of a first gate electrode (also referred to as a top gate electrode), and the conductive layer 206 has a function of a second gate electrode (also referred to as a bottom gate electrode). Here, in the transistor 200A, part of the insulating layer 110 functions as a first gate insulating layer, and part of each of the insulating layer 117 and the insulating layer 103 functions as a second gate insulating layer.

A portion of the semiconductor layer 108 that overlaps with at least one of the conductive layer 112 and the conductive layer 106 functions as a channel formation region of the transistor 100A. Note that for easy explanation, a portion of the semiconductor layer 108 that overlaps with the conductive layer 112 is sometimes referred to as a channel formation region; however, a channel can also be actually formed in a portion not overlapping with the conductive layer 112 and overlapping with the conductive layer 106 (a portion including the low-resistance region 108N). The same applies to the semiconductor layer 208 of the transistor 200A.

As illustrated in FIG. 4B, in the transistor 100A, the conductive layer 106 may be electrically connected to the conductive layer 112 through an opening portion 142 provided in the insulating layer 110, the insulating layer 117, and the insulating layer 103. In that case, the same potential can be applied to the conductive layer 106 and the conductive layer 112. Similarly, in the transistor 200A, the conductive layer 206 may be electrically connected to the conductive layer 212 through an opening portion 242 provided in the insulating layer 110, the insulating layer 117, and the insulating layer 103.

The conductive layer 106 and the conductive layer 206 can be formed using a material similar to that used for the conductive layer 112, the conductive layer 212, the conductive layer 120a, the conductive layer 120b, the conductive layer 220a, or the conductive layer 220b. In particular, a material containing copper is preferably used for the conductive layer 106 and the conductive layer 206, in which case wiring resistance can be reduced. The conductive layer 106 and the conductive layer 206 can be formed using the same material. The conductive layer 106 can be formed by processing a conductive film which is the same as that for the conductive layer 206. Note that the conductive layer 106 and the conductive layer 206 may be formed using different materials.

As illustrated in FIG. 4B, the conductive layer 112 and the conductive layer 106 preferably extend beyond an end portion of the semiconductor layer 108 in the channel width direction of the transistor 100A. In that case, as illustrated in FIG. 4B, the semiconductor layer 108 in the channel width direction is entirely covered with the conductive layer 112 and the conductive layer 106 with the insulating layer 110 and the insulating layer 103 therebetween. Similarly, the semiconductor layer 208 included in the transistor 200A is covered with the conductive layer 212 and the conductive layer 206. Note that a transistor structure in which a channel formation region is electrically surrounded by electric fields of a first gate electrode and a second gate electrode can be referred to as a surrounded channel (S-channel) structure.

With an S-channel structure, a semiconductor layer can be electrically surrounded by electric fields generated by a pair of gate electrodes. At this time, it is particularly preferable that the pair of gate electrodes be supplied with the same potential. In that case, electric fields for inducing a channel can be effectively applied to the semiconductor layer, so that the on-state current of each of the transistor 100A and the transistor 200A can be increased. Thus, the transistor 100A and the transistor 200A can also be miniaturized. Furthermore, resistance to a short-channel effect can be enhanced, that is, a transistor in which a short-channel effect is less likely to occur can be provided.

Note that the pair of gate electrodes are not necessarily connected to each other. In that case, a constant potential may be applied to one of the pair of gate electrodes, and a signal for driving the transistor 100A or the transistor 200A may be applied to the other. In that case, the potential supplied to one of the gate electrodes enables control of the threshold voltage at the time of driving the transistor 100A or the transistor 200A with the other gate electrode.

FIG. 4C shows an enlarged view of a region P indicated by the dashed-dotted line in FIG. 4A. FIG. 4D is an enlarged view of a region Q indicated by a dashed-dotted line in FIG. 4A. As illustrated in FIG. 4C, in the transistor 100A, the thickness TT100 of the first gate insulating layer is the sum of the thickness of the insulating layer 110 and the thickness of the insulating layer 117. The thickness TB100 of the second gate insulating layer is the thickness of the insulating layer 103. As illustrated in FIG. 4D, in the transistor 200A, the thickness TT200 of the first gate insulating layer is the thickness of the insulating layer 110. The thickness TB200 of the second gate insulating layer is the sum of the thickness of the insulating layer 103 and the thickness of the insulating layer 117.

The thickness TT100 of the first gate insulating layer in the transistor 100A is larger than thickness TT200 of the first gate insulating layer in the transistor 200A. On the other hand, the thickness TB100 of the second gate insulating layer in the transistor 100A is smaller than the thickness TB200 of the second gate insulating layer in the transistor 200A.

The thickness TB100 of the second gate insulating layer in the transistor 100A is preferably greater than or equal to 50% and less than 100%, further preferably greater than or equal to 60% and less than 100%, still further preferably greater than or equal to 60% and less than or equal to 95%, yet still further preferably greater than or equal to 70% and less than or equal to 95%, yet still further preferably greater than or equal to 80% and less than or equal to 95%, and yet still further preferably greater than or equal to 80% and less than or equal to 90% of the thickness TB200 of the second gate insulating layer in the transistor 200A.

An increase in the thickness of the insulating layer 117 can enlarge the thickness difference between the thickness TT100 of the first gate insulating layer in the transistor 100A and the thickness TT200 of the first gate insulating layer in the transistor 200A. Moreover, an increase in the thickness of the insulating layer 117 can enlarge the thickness difference between the thickness TB100 of the second gate insulating layer in the transistor 100A and the thickness TB200 of the second gate insulating layer in the transistor 200A.

Meanwhile, a reduction in the thickness of the insulating layer 117 can decrease the thickness difference between the thickness TT100 of the first gate insulating layer in the transistor 100A and the thickness TT200 of the first gate insulating layer in the transistor 200A. Moreover, a reduction in the thickness of the insulating layer 117 can decrease the thickness difference between the thickness TB100 of the second gate insulating layer in the transistor 100A and the thickness TB200 of the second gate insulating layer in the transistor 200A. In this manner, the thicknesses of the first gate insulating layer and the second gate insulating layer in each of the transistor 100A and the transistor 200A can be adjusted easily depending on characteristics required in the transistor 100A and the transistor 200A, without a significant increase in steps.

The thicknesses of the second gate insulating layers in the transistor 100A and the transistor 200A can also be adjusted by the thickness of the insulating layer 103. The thickness of the insulating layer 103 is reduced, whereby the difference between the thickness TB100 of the second gate insulating layer in the transistor 100 and the thickness TB200 of the second gate insulating layer in the transistor 200 can be made large. In contrast, the thickness of the insulating layer 103 is reduced, whereby the difference between the thickness TB100 of the second gate insulating layer in the transistor 100 and the thickness TB200 of the second gate insulating layer in the transistor 200 can be made small.

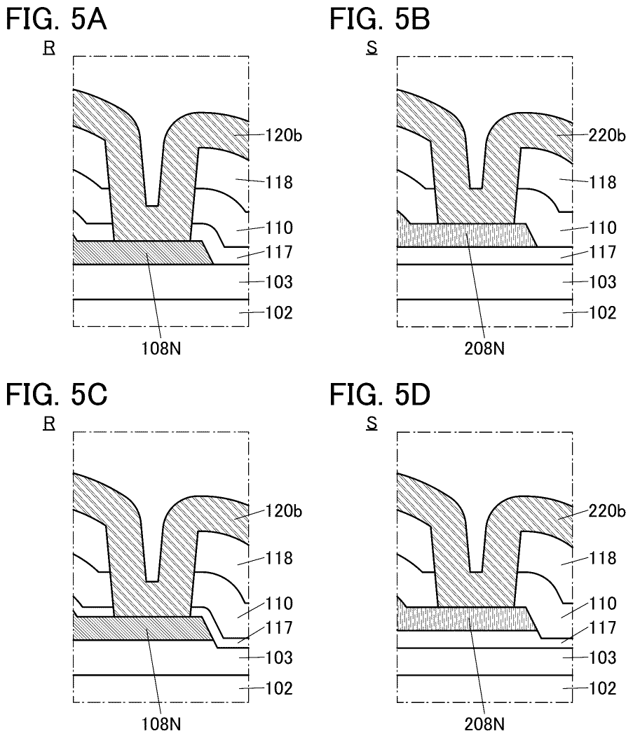

FIG. 5A shows an enlarged view of a region R indicated by the dashed-dotted line in FIG. 4A. FIG. 5B shows an enlarged view of a region S indicated by the dashed-dotted line in FIG. 4A. As illustrated in FIG. 5A and FIG. 5B, the insulating layer 117 includes a region in contact with a top surface and a side surface of the semiconductor layer 108, a bottom surface of the semiconductor layer 208, a bottom surface of the insulating layer 110, or a top surface of the insulating layer 103.

As illustrated in FIG. 5C and FIG. 5D, the thickness of the insulating layer 103 in the region not overlapping with the semiconductor layer 108 may be smaller than the thickness of the insulating layer 103 in the region overlapping with the semiconductor layer 108. For example, in formation of the semiconductor layer 108, a surface of the insulating layer 103 in the region not overlapping with the semiconductor layer 108 is removed, whereby the thickness of the insulating layer 103 in the region is reduced in some cases. Furthermore, the thickness of the insulating layer 117 in the region not overlapping with the semiconductor layer 208 may be smaller than the thickness of the insulating layer 117 in the region overlapping with the semiconductor layer 208.

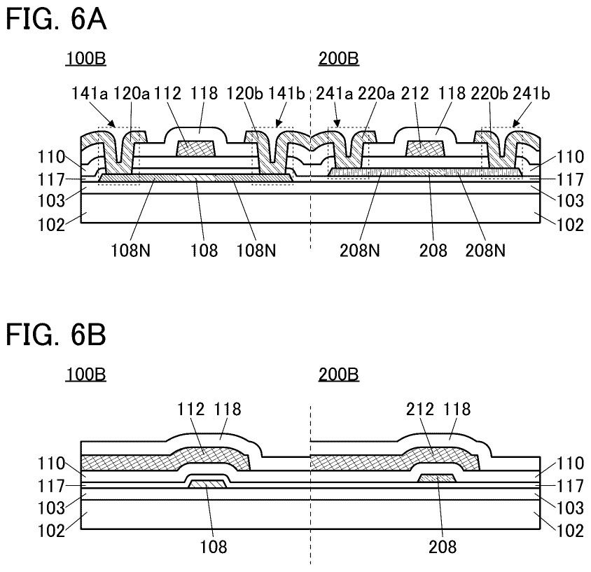

In the manufacturing process of the transistor 100A and the transistor 200A, a transistor not including the conductive layer 106 and a transistor not including the conductive layer 206 can be concurrently formed over one substrate. FIG. 6A is a cross-sectional view of a transistor 100B not including the conductive layer 106 of the transistor 100A and a transistor 200B not including the conductive layer 206 of the transistor 200A in the channel length direction, and FIG. 6B is a cross-sectional view of the transistors in the channel width direction.

A semiconductor device of one embodiment of the present invention allows achieving of a semiconductor device incorporating four types of transistors, the transistor 100A, the transistor 100B, the transistor 200A, and the transistor 200B. It is also possible to achieve a semiconductor device in which either or both of the transistor 100A and the transistor 100B and either or both of the transistor 200A and the transistor 200B are incorporated.

### Structure Example 3

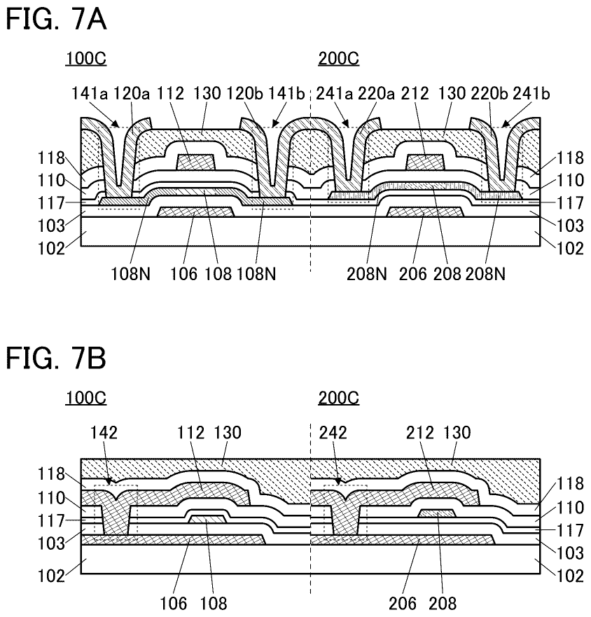

A structure example different from that of the transistor 100A and the transistor 200A is illustrated in FIG. 7A and FIG. 7B. FIG. 7A is a cross-sectional view of a transistor 100C and a transistor 200C in the channel length direction, and FIG. 7B is a cross-sectional view of the transistors in the channel width direction.

The transistor 100C and the transistor 200C are respectively different from the transistor 100A and the transistor 200A mainly in including an insulating layer 130 over the insulating layer 118.

The insulating layer 130 functions as a planarization film. An organic material can be suitably used for the insulating layer 130. One or both of an acrylic resin and a polyimide resin, which are organic materials, can be used for the insulating layer 130. As an organic material, a photosensitive material may be used.

When the insulating layer 130 functioning as a planarization film is provided, the step coverage of layers formed (for example, the conductive layer 120a, the conductive layer 120b, the conductive layer 220a, and the conductive layer 220b) over the insulating layer 130 is improved, so that generation of defects such as disconnection or voids in the layers can be suppressed.

The conductive layer 120a and the conductive layer 120b are electrically connected to the low-resistance region 108N in the semiconductor layer 108 through the opening portion 141a or the opening portion 141b provided in the insulating layer 130, the insulating layer 118, the insulating layer 110, and the insulating layer 117.

The conductive layer 220a and the conductive layer 220b are electrically connected to the low-resistance region 208N in the semiconductor layer 208 through the opening portion 241a or the opening portion 241b provided in the insulating layer 130, the insulating layer 118, and the insulating layer 110.

### <Structure Example 4>

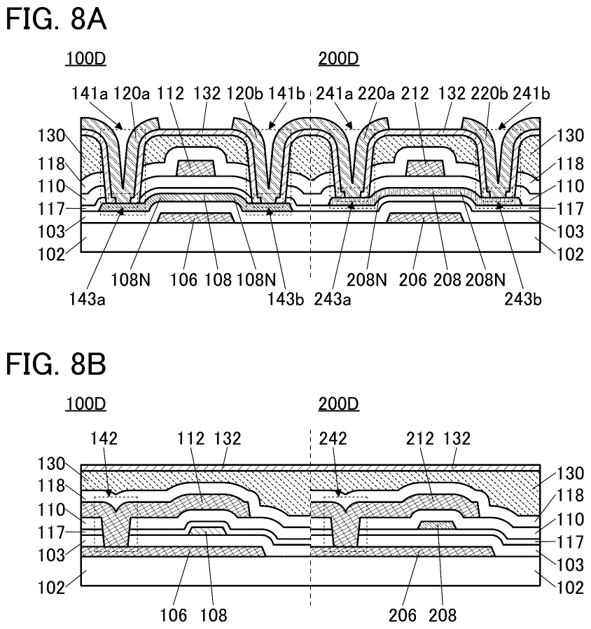

A structure example different from that of the transistor 100C and the transistor 200C is illustrated in FIG. 8A and FIG. 8B. FIG. 8A is a cross-sectional view of a transistor 100D and a transistor 200D in the channel length direction, and FIG. 8B is a cross-sectional view of the transistors in the channel width direction.

The transistor 100D and the transistor 200D are respectively different from the transistor 100C and the transistor 200C mainly in including an insulating layer 132 over the insulating layer 130.

The insulating layer 132 is provided to cover a top surface and a side surface of the insulating layer 130. The insulating layer 132 has an opening portion 143a on an inner side of the opening portion 141a, an opening portion 143b on an inner side of the opening portion 141b, an opening portion 243a on an inner side of the opening portion 241a, and an opening portion 243b on an inner side of the opening portion 241b. Furthermore, the insulating layer 132 may include a region in contact with the top surface of the semiconductor layer 108 and the top surface of the semiconductor layer 208.

The conductive layer 120a and the conductive layer 120b are electrically connected to the low-resistance regions 108N in the semiconductor layer 108 through the opening portion 143a and the opening portion 143b, respectively, which are provided in the insulating layer 132.

The conductive layer 220a and the conductive layer 220b are electrically connected to the low-resistance region 208N included in the semiconductor layer 208 through the opening portion 243a or the opening portion 243b provided in the insulating layer 132.

For the insulating layer 132, a material that can be used for the insulating layer 118 can be used. The insulating layer 132 is provided between the insulating layer 130 and the conductive layer 120a, the conductive layer 120b, the conductive layer 220a, and the conductive layer 220b; each of the conductive layer 120a, the conductive layer 120b, the conductive layer 220a, and the conductive layer 220b is in contact with the insulating layer 132. Such a structure enables adhesion to the conductive layer 120a, the conductive layer 120b, the conductive layer 220a, and the conductive layer 220b to be increased.

### <Structure Example 5>

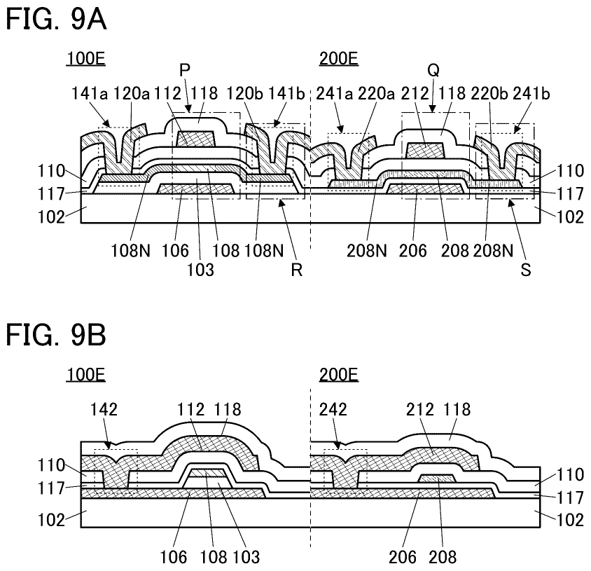

A structure example different from that of the transistor 100A and the transistor 200A is illustrated in FIG. 9A and FIG. 9B. FIG. 9A is a cross-sectional view of a transistor 100E and a transistor 200E in the channel length direction, and FIG. 9B is a cross-sectional view of the transistors in the channel width direction.

The transistor 100E is different from the transistor 100A mainly in the shape of the insulating layer 103 functioning as the second gate insulating layer. The transistor 200E is different from the transistor 200A mainly in the structure of an insulating layer functioning as the second gate insulating layer.

The insulating layer 103 includes a region overlapping with the semiconductor layer 108, and an end portion of the insulating layer 103 is aligned or substantially aligned with an end portion of the semiconductor layer 108. In other words, a top surface shape of the insulating layer 103 is aligned or substantially aligned with a top surface shape of the semiconductor layer 108. For example, an insulating film to be the insulating layer 103 is formed and a region of the insulating film that does not overlap with the semiconductor layer 108 is removed, so that an island-shaped insulating layer 103 whose top surface is aligned or substantially aligned with the top surface shape of the semiconductor layer 108 can be formed. The insulating layer 103 can be formed with use of a resist mask for processing the semiconductor layer 108, for example.

Note that in this specification and the like, the expression “top surface shapes are aligned or substantially aligned with each other” means that at least outlines of stacked layers partly overlap with each other. For example, the case of processing the upper layer and the lower layer with use of the same mask pattern or mask patterns that are partly the same is included. However, in some cases, the outlines do not completely overlap with each other and the upper layer is positioned on an inner side of the lower layer or the upper layer is positioned on an outer side of the lower layer; such a case is also represented by the expression “top surface shapes are aligned or substantially aligned with each other”.

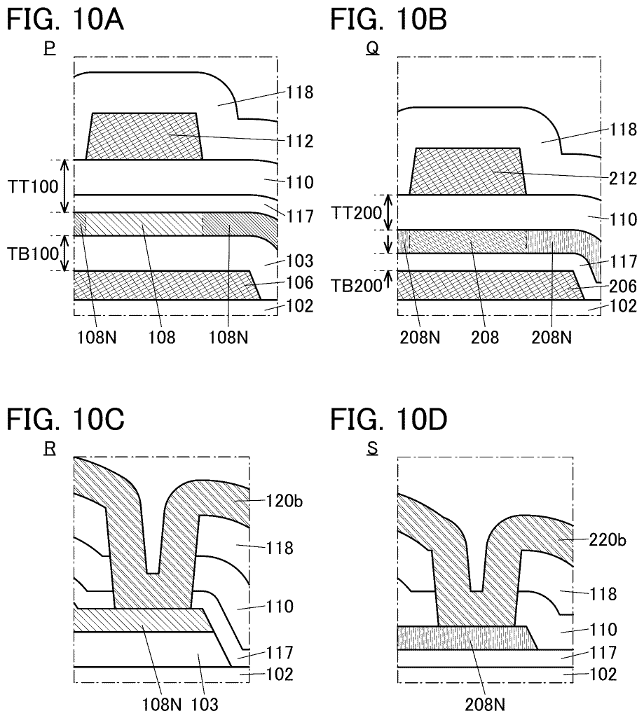

FIG. 10A shows an enlarged view of a region P indicated by the dashed-dotted line in FIG. 9A. FIG. 10B shows an enlarged view of a region Q indicated by the dashed-dotted line in FIG. 9A. In the transistor 100E, part of each of the insulating layer 110 and the insulating layer 117 functions as a first gate insulating layer, and part of the insulating layer 103 functions as a second gate insulating layer. In the transistor 200E, part of the insulating layer 110 functions as a first gate insulating layer, and part of the insulating layer 117 functions as a second gate insulating layer.

As illustrated in FIG. 10A, in the transistor 100E, the thickness TT100 of the first gate insulating layer is the sum of the thickness of the insulating layer 110 and the thickness of the insulating layer 117. The thickness TB100 of the second gate insulating layer is the thickness of the insulating layer 103. As illustrated in FIG. 10B, in the transistor 200E, the thickness TT200 of the first gate insulating layer is the thickness of the insulating layer 110. The thickness TB200 of the second gate insulating layer is the thickness of the insulating layer 117. Thus, the thickness TT100 of the first gate insulating layer in the transistor 100E is larger than the thickness TT200 of the first gate insulating layer in the transistor 200E. Meanwhile, the thickness TB100 of the second gate insulating layer in the transistor 100E and the thickness TB200 of the second gate insulating layer in the transistor 200E can be adjusted depending on the thickness of the insulating layer 103 and the thickness of the insulating layer 117.

FIG. 10C shows an enlarged view of a region R indicated by the dashed-dotted line in FIG. 9A. FIG. 10D shows an enlarged view of a region S indicated by the dashed-dotted line in FIG. 9A. As illustrated in FIG. 10C and FIG. 10D, the insulating layer 117 includes a region in contact with a top surface and a side surface of the semiconductor layer 108, a bottom surface of the semiconductor layer 208, a bottom surface of the insulating layer 110, a side surface of the insulating layer 103, or a top surface of the substrate 102.

### <Structure Example 6>

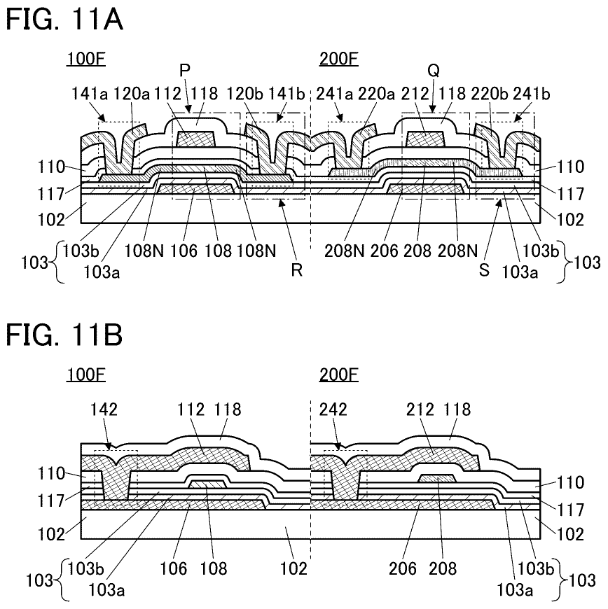

A structure example different from that of the transistor 100A and the transistor 200A is illustrated in FIG. 11A and FIG. 11B. FIG. 11A is a cross-sectional view of a transistor 100F and a transistor 200F in the channel length direction, and FIG. 11B is a cross-sectional view of the transistors in the channel width direction.

The transistor 100F and the transistor 200F are different from the transistor 100A and the transistor 200A mainly in that the insulating layer 103 has a stacked-layer structure.

The insulating layer 103 preferably has a stacked-layer structure of an insulating layer 103a and an insulating layer 103b over the insulating layer 103a.

The insulating layer 103a located on the side of the conductive layer 106 and the conductive layer 206 preferably serves as a barrier film that inhibits diffusion of components of the conductive layer 106 and the conductive layer 206 to the side of the semiconductor layer 108 and the semiconductor layer 208. As the insulating layer 103a, an insulating film containing nitrogen can be suitably used. As the insulating layer 103a, an insulating layer containing one or more of a silicon nitride film, a silicon nitride oxide film, an aluminum nitride film, and a hafnium nitride film, can be used, for example.

On the other hand, an insulating film containing oxygen is preferably used as the insulating layer 103b located on the side of the semiconductor layer 108 and the semiconductor layer 208. As the insulating layer 103b, an insulating film containing oxygen is preferably used. For the insulating layer 103b, a material that can be used for the insulating layer 110 or the insulating layer 117 can be used.

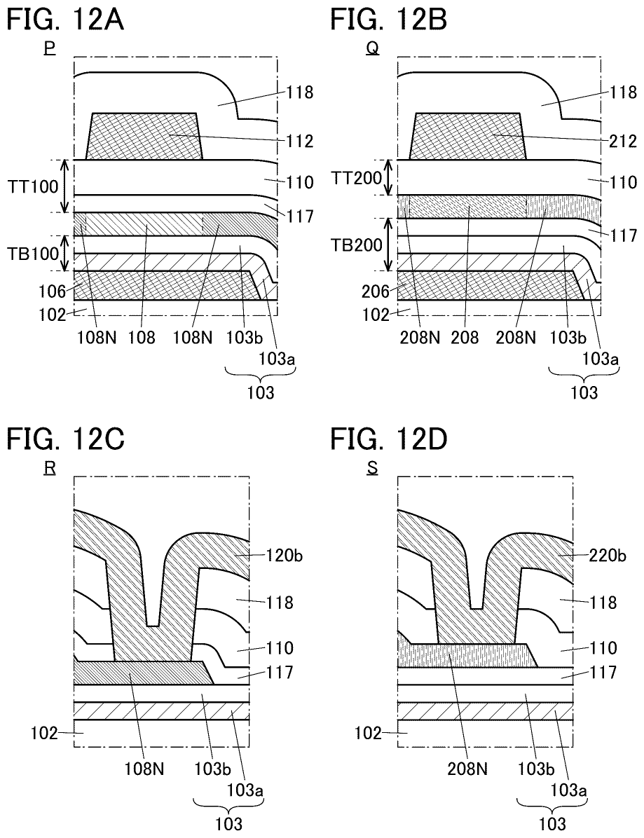

FIG. 12A shows an enlarged view of a region P indicated by the dashed-dotted line in FIG. 11A. FIG. 12B shows an enlarged view of a region Q indicated by the dashed-dotted line in FIG. 11A.

As illustrated in FIG. 12A, in the transistor 100F, the thickness TT100 of the first gate insulating layer is the sum of the thickness of the insulating layer 110 and the thickness of the insulating layer 117. The thickness TB100 of the second gate insulating layer is the sum of the thickness of the insulating layer 103a and the thickness of the insulating layer 103b. As illustrated in FIG. 12B, in the transistor 200F, the thickness TT200 of the first gate insulating layer is the thickness of the insulating layer 110. The thickness TB200 of the second gate insulating layer is the sum of the thickness of the insulating layer 117, the thickness of the insulating layer 103a, and the thickness of the insulating layer 103b.

FIG. 12C shows an enlarged view of a region R indicated by the dashed-dotted line in FIG. 11A. FIG. 12D shows an enlarged view of a region S indicated by the dashed-dotted line in FIG. 11A. As illustrated in FIG. 12C and FIG. 12D, the insulating layer 117 includes a region in contact with the a top surface and a side surface of the semiconductor layer 108, a bottom surface of the semiconductor layer 208, a bottom surface of the insulating layer 110, or a top surface of the insulating layer 103b. The insulating layer 103a includes a region in contact with a bottom surface of the insulating layer 103b. The insulating layer 103b includes a region in contact with a bottom surface of the semiconductor layer 108 and a bottom surface of the insulating layer 117.

The thickness of the insulating layer 103b in the region not overlapping with the semiconductor layer 108 may be smaller than the thickness of the insulating layer 103b in the region overlapping with the semiconductor layer 108. For example, in formation of the semiconductor layer 108, a surface of the insulating layer 103b in a region that does not overlap with the semiconductor layer 108 is removed, so that the thickness of the insulating layer 103b in the region is reduced in some cases.

### <Structure Example 7>

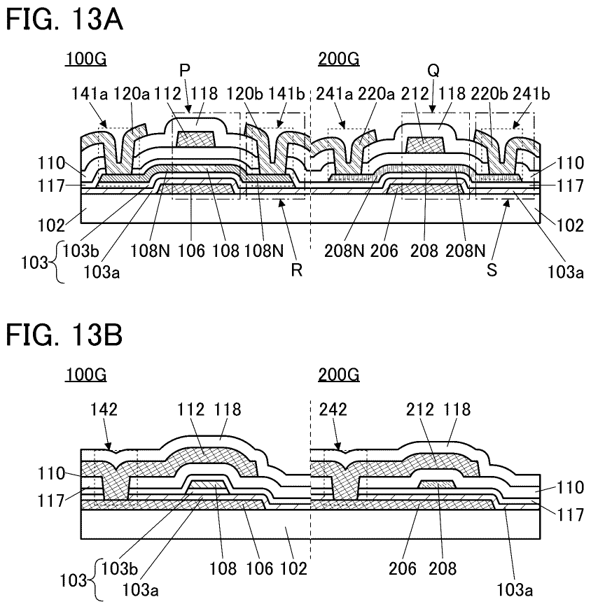

A structure example different from the transistor 100F and the transistor 200F is illustrated in FIG. 13A and FIG. 13B. FIG. 13A is a cross-sectional view of a transistor 100G and a transistor 200G tin the channel length direction, and FIG. 13B is a cross-sectional view of the transistors in the channel width direction.

The transistor 100G is different from the transistor 100F mainly in the shape of the insulating layer 103b. The transistor 200G is different from the transistor 200F mainly in the structure of the second gate insulating layer.

The insulating layer 103b includes a region overlapping with the semiconductor layer 108, and an end portion of the insulating layer 103b is aligned or substantially aligned with an end portion of the semiconductor layer 108. In other words, a top surface shape of the insulating layer 103b is aligned or substantially aligned with a top surface shape of the semiconductor layer 108. For example, an insulating film to be the insulating layer 103b is formed and a region of the insulating film that does not overlap with the semiconductor layer 108 is removed, so that an island-shaped insulating layer 103b whose top surface is aligned or substantially aligned with the top surface shape of the semiconductor layer 108 can be formed. The insulating layer 103b can be formed with use of a resist mask for processing the semiconductor layer 108, for example.

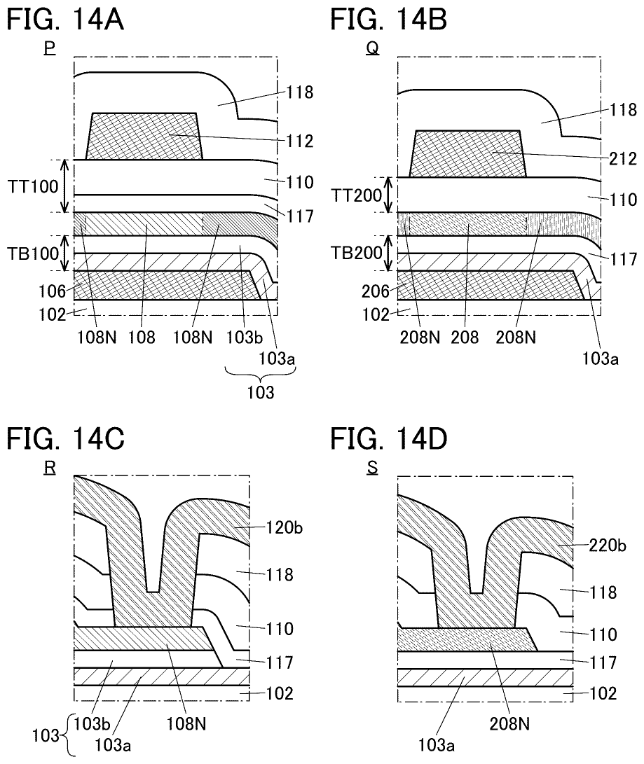

FIG. 14A shows an enlarged view of a region P indicated by the dashed-dotted line in FIG. 13A. FIG. 14B shows an enlarged view of a region Q indicated by the dashed-dotted line in FIG. 13A. In the transistor 100G, part of each of the insulating layer 110 and the insulating layer 117 functions as a first gate insulating layer, and part of each of the insulating layer 103a and the insulating layer 103b functions as a second gate insulating layer. In the transistor 200G, part of the insulating layer 110 functions as a first gate insulating layer, and part of each of each of the insulating layer 117 and the insulating layer 103a functions as a second gate insulating layer.

As illustrated in FIG. 14A, the thickness TT100 of the first gate insulating layer in the transistor 100G is the sum of the thickness of the insulating layer 110 and the thickness of the insulating layer 117. The thickness TB100 the second gate insulating layer is the sum of the thickness of the insulating layer 103a and the thickness of the insulating layer 103b. As illustrated in FIG. 14B, in the transistor 200G, the thickness TT200 of the first gate insulating layer is the thickness of the insulating layer 110. The thickness TB200 of the second gate insulating layer is the sum of the thickness of the insulating layer 117 and the thickness of the insulating layer 103a.

The thickness TT100 of the first gate insulating layer in the transistor 100G is larger than the thickness TT200 of the first gate insulating layer in the transistor 200G. Meanwhile, the thickness TB100 of the second gate insulating layer in the transistor 100G and the thickness TB200 of the second gate insulating layer in the transistor 200G can be adjusted depending on the thickness of the insulating layer 103a, the thickness of the insulating layer 103b, and the thickness of the insulating layer 117.

FIG. 14C shows an enlarged view of a region R indicated by the dashed-dotted line in FIG. 13A. FIG. 14D shows an enlarged view of a region S indicated by the dashed-dotted line in FIG. 13A. As illustrated in FIG. 14C and FIG. 14D, the insulating layer 117 includes a region in contact with a top surface and a side surface of the semiconductor layer 108, a bottom surface of the semiconductor layer 208, a bottom surface of the insulating layer 110, a side surface of the insulating layer 103b, or a top surface of the insulating layer 103a. The insulating layer 103a includes a region in contact with a bottom surface of the insulating layer 103b and a region in contact with a bottom surface of the insulating layer 117. The insulating layer 103b includes a region in contact with a bottom surface of the semiconductor layer 108. The insulating layer 103b may include a region in contact with a bottom surface of the insulating layer 117.

### <Structure Example 8>

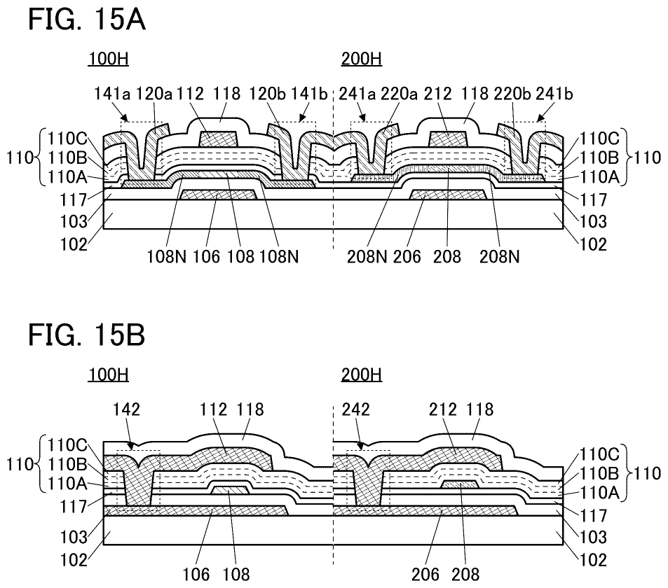

A structure example different from that of the transistor 100A and the transistor 200A is illustrated in FIG. 15A and FIG. 15B. FIG. 15A is a cross-sectional view of a transistor 100H and a transistor 200H in the channel length direction, and FIG. 15B is a cross-sectional view of the transistors in the channel width direction.

The transistor 100H and the transistor 200H are respectively different from the transistor 100A and the transistor 200A mainly in that the insulating layer 110 has a stacked-layer structure.

FIG. 15A and FIG. 15B illustrate an example in which the insulating layer 110 has a three-layer structure in which an insulating layer 110A, an insulating layer 110B, and an insulating layer 110C are stacked in this order from the side of the semiconductor layer 108 and the semiconductor layer 208.

A first gate insulating layer of the transistor 100H has a stacked-layer structure of the insulating layer 117, the insulating layer 110A, the insulating layer 110B, and the insulating layer 110C. A first gate insulating layer of the transistor 200H has a stacked-layer structure of the insulating layer 110A, the insulating layer 110B, and the insulating layer 110C.

For each of the insulating layer 110A, the insulating layer 110B, and the insulating layer 110C, the material that can be used for the insulating layer 110 can be used. The insulating layer 110A, the insulating layer 110B, and the insulating layer 110C can be formed in a manner similar to that for formation of the insulating layer 110.

It is preferable that the insulating layer 110A, the insulating layer 110B, and the insulating layer 110C be successively formed without exposure to the air with the same deposition apparatus. The successive formation can suppress attachment of impurities such as water to the interfaces between the insulating layer 110A, the insulating layer 110B, and the insulating layer 110C. Plasma CVD method can be favorably used for formation of the insulating layer 110A, the insulating layer 110B, and the insulating layer 110C.

The insulating layer 110A is formed over the semiconductor layer 208, and thus is preferably a film formed under conditions where the semiconductor layer 208 is damaged as little as possible. For example, the insulating layer 110A can be deposited under conditions where the deposition rate is sufficiently low. The insulating layer 110A is formed under the conditions where the semiconductor layer 208 is not damaged, so that the density of defect states at the interface between the semiconductor layer 208 and the insulating layer 110 is reduced and the transistor 200H can have high reliability. Similarly, damage given to the semiconductor layer 108 through the insulating layer 117 can be suppressed, whereby the transistor 100H can have high reliability.

For example, when the insulating layer 110A is formed by a plasma CVD method under a low-power condition, damage to the semiconductor layer 108 and the semiconductor layer 208 can be extremely small. When the proportion of the flow rate of the deposition gas in the total flow rate of the film formation gas (hereinafter also simply referred to as a flow rate ratio) is low, the film formation speed can be made low, which allows formation of a dense film with few defects.

It is preferable that the insulating layer 117 in contact with the semiconductor layer 108 is a film, like the insulating layer 110A, formed under conditions where the semiconductor layer 108 is damaged as little as possible. For example, the conditions that can be used for formation of the insulating layer 110A can be used for formation of the insulating layer 117.

The insulating layer 110B is preferably a film formed at a higher deposition rate than the insulating layer 110A. Thus, the productivity can be improved.

For example, the insulating layer 110B can be formed at an increased deposition rate by setting the flow rate ratio of the deposition gas to be higher than that for the insulating layer 110A.

The insulating layer 110C is preferably an extremely dense film that has reduced defects on the surface and is less likely to adsorb impurities contained in the air, such as water. For example, like the insulating layer 110A, the insulating layer 110C can be formed at a sufficiently low deposition rate.

Since the insulating layer 110C is formed over the insulating layer 110B, the formation of the insulating layer 110C affects the semiconductor layer 108 and the semiconductor layer 208 less than the formation of the insulating layer 110A. Thus, the insulating layer 110C can be formed under conditions where the power is higher than that for the insulating layer 110A. The reduced flow rate ratio of the deposition gas and the relatively high-power film formation enable formation of a dense film in which defects on its surface are reduced.

That is, as the insulating layer 110, a stacked-layer film formed under conditions where the deposition rate of the insulating layer 110B is the highest, that of the insulating layer 110A is the second highest, and that of the insulating layer 110C is the lowest can be used. In the insulating layer 110, the etching rate of the insulating layer 110B is the highest, that of the insulating layer 110A is the second highest, and that of the insulating layer 110C is the lowest when wet etching or dry etching is performed under the same condition.

The insulating layer 110B is preferably formed to be thicker than the insulating layer 110A and the insulating layer 110C. The time taken to form the insulating layer 110 can be shortened by forming the insulating layer 110B, which is formed at the highest deposition rate, to be thick.

Note that insulating films formed of the same kind of material can be used as the insulating layer 110A, the insulating layer 110B, and the insulating layer 110C; thus, the boundary between the insulating layer 110A and the insulating layer 110B and the boundary between the insulating layer 110B and the insulating layer 110C cannot be clearly observed in some cases. Thus, the boundaries are denoted by dashed lines in FIG. 15A and the like. Since the insulating layer 110A and the insulating layer 110B have different film densities, the boundary therebetween can sometimes be observed as a difference in contrast in a transmission electron microscopy (TEM) image or the like of the cross section of the insulating layer 110. Similarly, the boundary between the insulating layer 110B and the insulating layer 110C can be observed as a difference in contrast in some cases.

### <Structure Example 9>

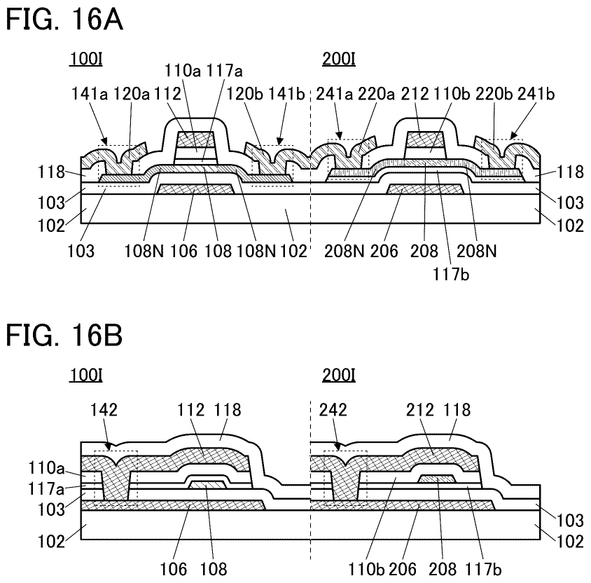

A structure example different from that of the transistor 100A and the transistor 200A is illustrated in FIG. 16A and FIG. 16B. FIG. 16A is a cross-sectional view of a transistor 100I and a transistor 200I in the channel length direction, and FIG. 16B is a cross-sectional view of the transistors in the channel width direction.

The transistor 100I and the transistor 200I are different from the transistor 100A and the transistor 200A mainly in shapes of the insulating layer 117 and the insulating layer 110.

The transistor 100I has a stacked-layer structure of an insulating layer 117a and an insulating layer 110a over the insulating layer 117a as a first gate insulating layer. End portions of the insulating layer 117a and the insulating layer 110a are aligned or substantially aligned with an end portion of the conductive layer 112. In other words, top surface shapes of the insulating layer 117a and the insulating layer 110a are aligned or substantially aligned with a top surface shape of the conductive layer 112. The insulating layer 117a and the insulating layer 110a can be formed with use of a resist mask for processing the conductive layer 112, for example. The transistor 100I includes the insulating layer 103 as a second gate insulating layer.

The transistor 200I includes an insulating layer 110b as the first gate insulating layer. An end portion of the insulating layer 110b is aligned or substantially aligned with an end portion of the conductive layer 212. In other words, a top surface shape of the insulating layer 110b is aligned or substantially aligned with a top surface shape of the conductive layer 212. The insulating layer 110b can be formed with use of a resist mask for processing the conductive layer 212, for example. The transistor 200I includes the insulating layer 103 and an insulating layer 117b as the second gate insulating layer.

The insulating layer 117a and the insulating layer 117b can be formed by processing a first insulating film provided over the semiconductor layer 108 and the insulating layer 103. The insulating layer 110a and the insulating layer 110b can be formed by processing a second insulating film provided over the semiconductor layer 208 and the first insulating film.

In the transistor 100I, the insulating layer 118 is provided in contact with the top surface and the side surface of the semiconductor layer 108 which are not covered with the conductive layer 112, insulating layer 110a, and the insulating layer 117a. In the transistor 200I, the insulating layer 118 is provided in contact with the top surface and the side surface of the semiconductor layer 208 which are not covered with the conductive layer 212 and the insulating layer 110b. The insulating layer 118 is provided to cover a top surface of the insulating layer 103, a side surface of the insulating layer 117a, a side surface of the insulating layer 110a, a top surface and a side surface of the conductive layer 112, a side surface of the insulating layer 117b, a side surface of the insulating layer 110b, and a top surface and a side surface of the conductive layer 212.

The insulating layer 118 has a function of reducing the resistance of the low-resistance region 108N and the low-resistance region 208N. The insulating layer 118 can be formed using an insulating film which can supply impurities to the low-resistance region 108N and the low-resistance region 208N by being heated at the time of or after the deposition of the insulating layer 118. Alternatively, the insulating layer 118 can be formed using an insulating film that can cause generation of oxygen vacancies (Vo) in the low-resistance region 108N and the low-resistance region 208N by being heated at the time of or after the deposition of the insulating layer 118.

For example, as the insulating layer 118, an insulating film functioning as a supply source that supplies impurities to the low-resistance region 108N and the low-resistance region 208N can be used. In that case, the insulating layer 118 is preferably a film from which hydrogen is released by heating. When the insulating layer 118 is formed in contact with the semiconductor layer 108 and the semiconductor layer 208, impurities such as hydrogen can be supplied to the low-resistance region 108N and the low-resistance region 208N, so that the resistance of the low-resistance region 108N and the low-resistance region 208N can be lowered.

The insulating layer 118 is preferably a film deposited using a gas containing an impurity element such as a hydrogen element as a deposition gas used for the deposition.

For the insulating layer 118, for example, a nitride oxide or a nitride such as silicon nitride, silicon nitride oxide, silicon oxynitride, aluminum nitride, or aluminum nitride oxide can be favorably used. In particular, because of having a blocking property against hydrogen and oxygen, silicon nitride can prevent both a diffusion of hydrogen from the outside into the semiconductor layer and a release of oxygen from the semiconductor layer to the outside, and thus a highly reliable transistor can be achieved.

The insulating layer 118 can also be formed using an oxide or an oxynitride such as silicon oxide, silicon oxynitride, aluminum oxide, or hafnium oxide.

### <Structure Example 10>

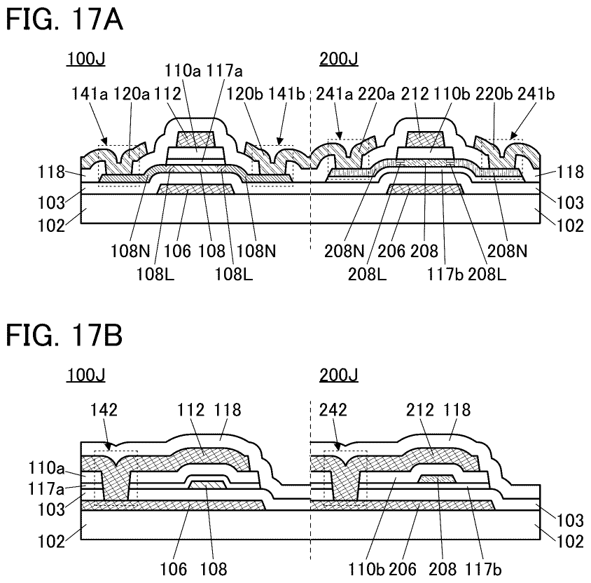

A structure example different from that of the transistor 100I and the transistor 200I is illustrated in FIG. 17A and FIG. 17B. FIG. 17A is a cross-sectional view of a transistor 100J and a transistor 200J in the channel length direction, and FIG. 17B is a cross-sectional view of the transistors in the channel width direction.

The transistor 100J and the transistor 200J are respectively different from the transistor 100I and the transistor 200I mainly in the shape of an insulating layer functioning as a first gate insulating layer.

In the transistor 100J, an end portion of the conductive layer 112 is positioned more inwardly than an end portion of the insulating layer 110a and an end portion of the insulating layer 117a. In other words, the insulating layer 110 and the insulating layer 117 each include a portion extending beyond the end portion of the conductive layer 112 over at least the semiconductor layer 108.

The semiconductor layer 108 includes a pair of regions 108L between which the channel formation region is sandwiched to be sandwiched between a pair of low-resistance regions 108N. The regions 108L are each a region of the semiconductor layer 108 that overlaps with the insulating layer 110a and the insulating layer 117a and does not overlap with the conductive layer 112.

In the transistor 200J, an end portion of the conductive layer 212 is positioned more inwardly than an end portion of the insulating layer 110b. In other words, the insulating layer 110b includes a portion extending beyond the end portion of the conductive layer 212 over at least the semiconductor layer 208.

The semiconductor layer 208 includes a pair of regions 208L between which a channel formation region is sandwiched to be sandwiched between a pair of low-resistance regions 208N. The regions 208L are each a region of the semiconductor layer 208 that overlaps with the insulating layer 110b and does not overlap with the conductive layer 212.

The regions 108L and the regions 208L each have a function of a buffer region that relieves a drain electric field. The region 108L and the region 208L are each a region not overlapping with the conductive layer 112 or the conductive layer 212 and thus is a region where a channel is hardly formed by application of gate voltage to the conductive layer 112 or the conductive layer 212. The region 108L and the region 208L preferably have a higher carrier concentration than the channel formation region. Thus, the region 108L and the region 208L can function as an LDD (Lightly Doped Drain) region.

The region 108L can be referred to as a region whose resistance is substantially equal to or lower than that of the channel formation region in the transistor 100J, a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region.

Similarly, the region 208L can be referred to as a region whose resistance is substantially equal to or lower than that of the channel formation region in the transistor 200J, a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region.

The region 108L can be referred to as a region whose resistance is substantially equal to or higher than that of the low-resistance region 108N, a region whose carrier concentration is substantially equal to or lower than that of the low-resistance region 108N, a region whose oxygen vacancy density is substantially equal to or lower than that of the low-resistance region 108N, or a region whose impurity concentration is substantially equal to or lower than that of the low-resistance region 108N.

Similarly, the region 208L can be referred to as a region whose resistance is substantially equal to or higher than that of the low-resistance region 208N, a region whose carrier concentration is substantially equal to or lower than that of the low-resistance region 208N, a region whose oxygen vacancy density is substantially equal to or lower than that of the low-resistance region 208N, or a region whose impurity concentration is substantially equal to or lower than that of the low-resistance region 208N.

In this manner, the region 108L or the region 208L functioning as the LDD region is provided between the channel formation region and the low-resistance region 108N or the low-resistance region 208N functioning as a source region or a drain region, whereby a highly reliable transistor having both a high drain breakdown voltage and a high on-state current can be provided.

The low-resistance region 108N functions as the source region or the drain region and has the lowest resistance in the other regions of the semiconductor layer 108. Alternatively, the low-resistance region 108N can be referred to as a region having the highest carrier concentration, a region having the highest oxygen vacancy density, or a region having the highest impurity concentration in the regions of the semiconductor layer 108.

Similarly, the low-resistance region 208N functions as the source region or the drain region and has the lowest resistance in the other regions of the semiconductor layer 208. Alternatively, the low-resistance region 208N can be referred to as a region having the highest carrier concentration, a region having the highest oxygen vacancy density, or a region having the highest impurity concentration in the regions of the semiconductor layer 208.

The electric resistivity of the low-resistance region 108N and the low-resistance region 208N is preferably as low as possible. For example, the sheet resistance of each of the low-resistance region 108N and the low-resistance region 208N is preferably higher than or equal to 1 Ω/square and lower than 1×10³ Ω/square, further preferably higher than or equal to 1 Ω/square and lower than or equal to 8×10² Ω/square.

The electric resistance of the channel formation region in a state where the channel is not formed is preferably as high as possible. For example, the sheet resistance of the channel formation region is preferably higher than or equal to 1×10⁹ Ω/square, further preferably higher than or equal to 5×10⁹ Ω/square, still further preferably higher than or equal to 1×10¹⁰ Ω/square.

Since the electric resistance of the channel formation region in a state where the channel is not formed is preferably as high as possible, it is not necessary to set its upper limit. If the upper limit is set, the sheet resistance of the channel formation region is preferably higher than or equal to 1×10⁹ Ω/square and lower than or equal to 1×10¹² Ω/square, further preferably higher than or equal to 5×10⁹ Ω/square and lower than or equal to 1×10¹² Ω/square, still further preferably higher than or equal to 1×10¹⁰ Ω/square and lower than or equal to 1×10¹² Ω/square, for example.

The sheet resistance of each of the region 108L and the region 208L can be, for example, higher than or equal to 1×10³ Ω/square and lower than or equal to 1×10⁹ Ω/square, preferably higher than or equal to 1×10³ Ω/square and lower than or equal to 1×10⁸ Ω/square, further preferably higher than or equal to 1×10³ Ω/square and lower than or equal to 1×10⁷ Ω/square. When the resistance is within the above range, a transistor that has favorable electrical characteristics and high reliability can be provided. Note that the sheet resistance can be calculated from a resistance value. The region 108L is provided between the channel formation region and the low-resistance region 108N, and the region 208L is provided between the channel formation region and the low-resistance region 208N, whereby source-drain breakdown voltages of the transistor 100J and the transistor 200J can be increased.

In the transistor 100J, the electric resistance of the channel formation region in a state where the channel is not formed can be more than or equal to 1×10⁶ times and less than or equal to 1×10¹² times that of the low-resistance region 108N, preferably more than or equal to 1×10⁶ times and less than or equal to 1×10¹¹ times that of the low-resistance region 108N, further preferably more than or equal to 1×10⁶ times and less than or equal to 1×10¹⁰ times that of the low-resistance region 108N.

In the transistor 100J, the electric resistance of the channel formation region in a state where the channel is not formed can be more than or equal to 1×10⁰ times and less than or equal to 1×10⁹ times that of the region 108L, preferably more than or equal to 1×10¹ times and less than or equal to 1×10⁸ times that of the region 108L, further preferably more than or equal to 1×10² times and less than or equal to 1×10⁷ times that of the region 108L.

The electric resistance of the region 108L can be more than or equal to 1×10⁰ times and less than or equal to 1×10⁹ times that of the low-resistance region 108N, preferably more than or equal to 1×10¹ times and less than or equal to 1×10⁸ times that of the low-resistance region 108N, further preferably more than or equal to 1×10¹ times and less than or equal to 1×10⁷ times that of the low-resistance region 108N.

Similarly, in the transistor 200J, the electric resistance of the channel formation region in a state where the channel is not formed can be more than or equal to 1×10⁶ times and less than or equal to 1×10¹² times that of the low-resistance region 208N, preferably more than or equal to 1×10⁶ times and less than or equal to 1×10¹¹ times that of the low-resistance region 208N, further preferably more than or equal to 1×10⁶ times and less than or equal to 1×10¹⁰ times that of the low-resistance region 208N.

In the transistor 200J, the electric resistance of the channel formation region in a state where the channel is not formed can be more than or equal to 1×10⁰ times and less than or equal to 1×10⁹ times that of the region 208L, preferably more than or equal to 1×10¹ times and less than or equal to 1×10⁸ times that of the region 208L, further preferably more than or equal to 1×10² times and less than or equal to 1×10⁷ times that of the region 208L. The electric resistance of the region 208L can be more than or equal to 1×10⁰ times and less than or equal to 1×10⁹ times that of the low-resistance region 208N, preferably more than or equal to 1×10¹ times and less than or equal to 1×10⁸ times that of the low-resistance region 208N, further preferably more than or equal to 1×10¹ times and less than or equal to 1×10⁷ times that of the low-resistance region 208N.

The carrier concentration in the semiconductor layer 108 preferably has a distribution such that the concentration is the lowest in the channel formation region and increases in the order of the region 108L and the low-resistance region 108N. Providing the region 108L between the channel formation region and the low-resistance region 108N can keep the carrier concentration of the channel formation region extremely low even when impurities such as hydrogen diffuse from the low-resistance region 108N during the manufacturing process, for example. The carrier concentration in the semiconductor layer 208 preferably has a distribution such that the concentration is the lowest in the channel formation region and increases in the order of the region 208L and the low-resistance region 208N.

The carrier concentration in the channel formation region is preferably as low as possible and is preferably lower than or equal to 1×10¹⁸ cm⁻³, further preferably lower than or equal to 1×10¹⁷ cm⁻³, still further preferably lower than or equal to 1×10¹⁶ cm⁻³, yet further preferably lower than or equal to 1×10¹³ cm⁻³, yet still further preferably lower than or equal to 1×10¹² cm⁻³. Note that the lower limit of the carrier concentration of the channel formation region is not particularly limited and can be, for example, 1×10⁻⁹ cm⁻³.

Meanwhile, the carrier concentration of each of the low-resistance region 108N and the low-resistance region 208N can be higher than or equal to 5×10¹⁸ cm⁻³, preferably higher than or equal to 1×10¹⁹ cm⁻³, further preferably higher than or equal to 5×10¹⁹ cm⁻³, for example. The upper limit of the carrier concentration of each of the low-resistance region 108N and the low-resistance region 208N is not particularly limited and can be, for example, 5×10²¹ cm⁻³ or 1×10²² cm⁻³.

The carrier concentration of the region 108L can be a value between that of the channel formation region and that of the low-resistance region 108N in the transistor 100J. The carrier concentration of the region 208L can be a value between that of the channel formation region and that of the low-resistance region 208N in the transistor 200J. The carrier concentration of each of the region 108L and the region 208L may have a value in the range higher than or equal to 1×10¹⁴ cm⁻³ and lower than 1×10²⁰ cm⁻³, for example.

Note that the carrier concentration is not necessarily uniform in the region 108L; in some cases, the carrier concentration has a falling gradient from the low-resistance region 108N side toward the channel formation region. For example, one or both of the hydrogen concentration and the oxygen vacancy concentration in the region 108L may have a falling gradient from the low-resistance region 108N side to the channel formation region side. The same applies to the region 208L.

### <Structure Example 11>

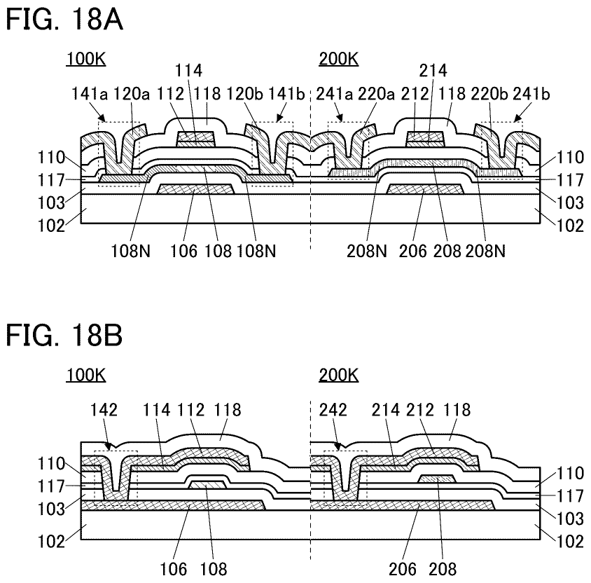

A structure example different from that of the transistor 100A and the transistor 200A is illustrated in FIG. 18A and FIG. 18B. FIG. 18A is a cross-sectional view of a transistor 100K and a transistor 200K in the channel length direction, and FIG. 18B is the cross-sectional view of the transistors in the channel width direction.

The transistor 100K is different from the transistor 100A mainly in including a metal oxide layer 114 between the insulating layer 110 and the conductive layer 112. The transistor 200K is different from the transistor 200A mainly in including a metal oxide layer 214 between the insulating layer 110 and the conductive layer 212.

An end portion of the metal oxide layer 114 is aligned or substantially aligned with an end portion of the conductive layer 112. In other words, a top surface shape of the metal oxide layer 114 is aligned or substantially aligned with a top surface shape of the conductive layer 112. Similarly, an end portion of the metal oxide layer 214 is aligned or substantially aligned with an end portion of the conductive layer 212. In other words, a top surface shape of the metal oxide layer 214 is aligned or substantially aligned with a top surface shape of the conductive layer 212. The metal oxide layer 114 and the metal oxide layer 214 can be formed with use of a resist mask for processing the conductive layer 112 and the conductive layer 212, for example.

Note that the top surface shapes of the metal oxide layer 114 and the conductive layer 112 are not necessarily aligned with each other. The top surface shapes of the metal oxide layer 214 and the conductive layer 212 are not necessarily aligned with each other. For example, an end portion of the metal oxide layer 114 may be positioned more outwardly than an end portion of the conductive layer 112, and an end portion of the metal oxide layer 214 may be positioned more outwardly than an end portion of the conductive layer 212. Alternatively, the end portion of the metal oxide layer 114 may be positioned more inwardly than the end portion of the conductive layer 112, and the end portion of the metal oxide layer 214 may be positioned more inwardly than the end portion of the conductive layer 212.

The metal oxide layer 114 and the metal oxide layer 214 each have a function of supplying oxygen into the insulating layer 110. In the case where a conductive film containing a metal or an alloy that is easily oxidized is used for the conductive layer 112 and the conductive layer 212, the metal oxide layer 114 and the metal oxide layer 214 can also function as a barrier layer that prevents the conductive layer 112 and the conductive layer 212 from being oxidized by oxygen in the insulating layer 110.

The metal oxide layer 114 positioned between the insulating layer 110 and the conductive layer 112 functions as a barrier film that prevents diffusion of oxygen contained in the insulating layer 110 to the conductive layer 112 side. Similarly, the metal oxide layer 214 positioned between the insulating layer 110 and the conductive layer 212 functions as a barrier film that prevents diffusion of oxygen contained in the insulating layer 110 into the conductive layer 212 side. Each of the metal oxide layer 114 and the metal oxide layer 214 also functions as a barrier film that prevents diffusion of impurities containing hydrogen elements contained in the conductive layer 112 or the conductive layer 212 to the insulating layer 110 side. Examples of impurities containing hydrogen elements include hydrogen and water. Each of the metal oxide layer 114 and the metal oxide layer 214 is preferably formed using, for example, a material that is less likely to transmit oxygen and hydrogen than at least the insulating layer 110.

Even when a metal material that is likely to absorb oxygen is used for the conductive layer 112 and the conductive layer 212, providing the metal oxide layer 114 and the metal oxide layer 214 can prevent oxygen diffusion from the insulating layer 110 to the conductive layer 112 or the conductive layer 212. Furthermore, even in the case where the conductive layer 112 and the conductive layer 212 contain hydrogen, diffusion of hydrogen from the conductive layer 112 and the conductive layer 212 into the semiconductor layer 108 or the semiconductor layer 208 through the insulating layer 110 can be prevented. Consequently, the carrier concentrations of the channel formation region of the semiconductor layer 108 and the semiconductor layer 208 can be extremely low. Note that examples of the metal material that is likely to absorb oxygen include aluminum and copper.

For the metal oxide layer 114 and the metal oxide layer 214, an insulating material or a conductive material can be used. When the metal oxide layer 114 and the metal oxide layer 214 have insulating properties, each of the metal oxide layer 114 and the metal oxide layer 214 serves as part of the gate insulating layer. Meanwhile, when the metal oxide layer 114 and the metal oxide layer 214 have conductivity, each of the metal oxide layer 114 and the metal oxide layer 214 serves as part of the gate electrode.

Each of the metal oxide layer 114 and the metal oxide layer 214 is preferably formed using an insulating material with a higher permittivity than silicon oxide. It is particularly preferable to use an aluminum oxide film, a hafnium oxide film, a hafnium aluminate film, or the like because driving voltage can be lowered.

For the metal oxide layer 114 and the metal oxide layer 214, a conductive oxide such as indium oxide, indium tin oxide (ITO), or indium tin oxide containing silicon (ITSO) can also be used, for example. A conductive oxide containing indium is particularly preferable because of its high conductivity.

The metal oxide layer 114 and the metal oxide layer 214 can be formed using the same material. The metal oxide layer 114 and the metal oxide layer 214 can be formed by processing the same metal oxide film. The metal oxide layer 114 and the metal oxide layer 214 may be formed using different materials. The metal oxide layer 114 and the metal oxide layer 214 may be formed through different steps.

An oxide material containing one or more kinds of elements contained in the semiconductor layer 108 or the semiconductor layer 208 is preferably used for the metal oxide layer 114 and the metal oxide layer 214. It is particularly preferable to use an oxide semiconductor material that can be used for the semiconductor layer 108 or the semiconductor layer 208. In this case, a metal oxide film formed using the same sputtering target as that for the semiconductor layer 108 or the semiconductor layer 208 is used for the metal oxide layer 114 and the metal oxide layer 214, whereby a formation apparatus can be shared and the productivity can be increased.

The metal oxide layer 114 and the metal oxide layer 214 are preferably formed using a sputtering apparatus. For example, in the case where an oxide film is formed using a sputtering apparatus, forming the oxide film in an atmosphere containing an oxygen gas can suitably supply oxygen into the insulating layer 110. Note that at this time, oxygen may be added not only to the insulating layer 110 but also to the insulating layer 117, the semiconductor layer 108, and the semiconductor layer 208.

As illustrated in FIG. 18B, in the transistor 100K, the conductive layer 106 may be electrically connected to the conductive layer 112 through the opening portion 142 provided in the metal oxide layer 114, the insulating layer 110, the insulating layer 117, and the insulating layer 103. In that case, the same potential can be applied to the conductive layer 106 and the conductive layer 112. Similarly, in the transistor 200K, the conductive layer 206 may be electrically connected to the conductive layer 212 through the opening portion 242 provided in the metal oxide layer 214, the insulating layer 110, the insulating layer 117, and the insulating layer 103.

The metal oxide layer 114 and the metal oxide layer 214 may be removed before the conductive layer 112 and the conductive layer 212 are formed, so that each of the conductive layer 112 and the conductive layer 212 is in contact with the insulating layer 110. The metal oxide layer 114 and the metal oxide layer 214 are not necessarily provided when not needed.

### <Structure Example 12>

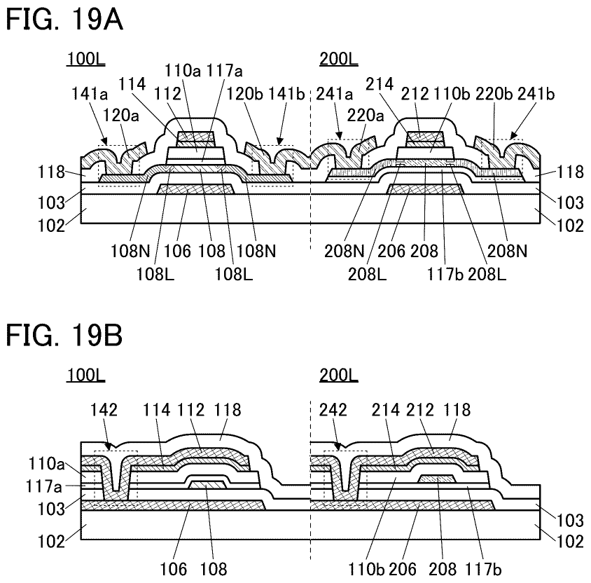

A structure example different from that of the transistor 100J and the transistor 200J is illustrated in FIG. 19A and FIG. 19B. FIG. 19A is a cross-sectional view of a transistor 100L and a transistor 200L in the channel length direction, and FIG. 19B is a cross-sectional view of the transistors in the channel width direction.

The transistor 100L is different from the transistor 100J mainly in that the metal oxide layer 114 is provided between the insulating layer 110a and the conductive layer 112. The transistor 200L is different from the transistor 200J mainly in that the metal oxide layer 214 is provided between the insulating layer 110b and the conductive layer 212.

### <Structure Example 13>

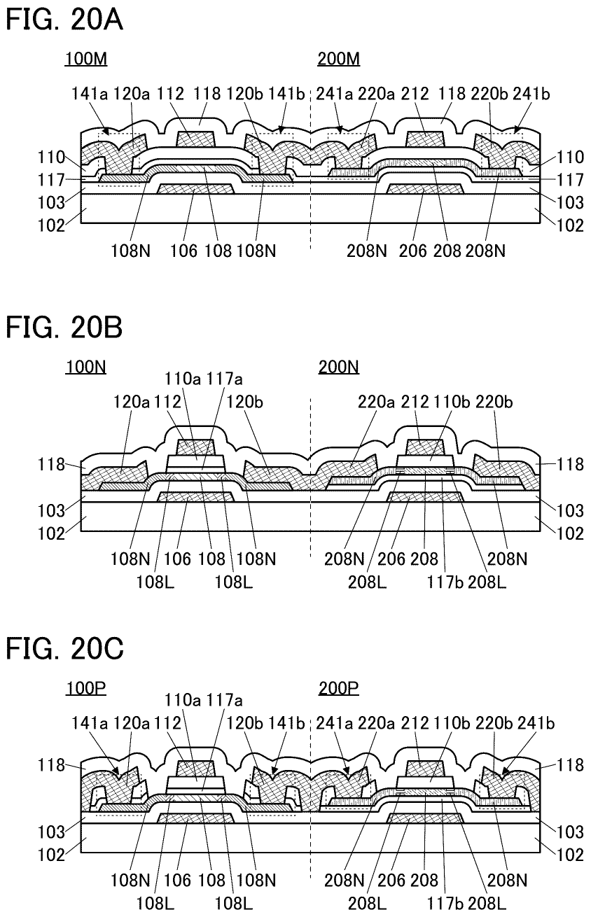

A structure example different from that of the transistor 100A and the transistor 200A is illustrated in FIG. 20A. FIG. 20A is a cross-sectional view of a transistor 100M and a transistor 200M in the channel length direction. FIG. 4B can be referred to for a cross-sectional direction of the transistors in the channel width direction.

The transistor 100M is different from the transistor 100A mainly in that the conductive layer 120a and the conductive layer 120b are provided over the insulating layer 110. The transistor 200M is different from the transistor 200A mainly in that the conductive layer 220a and the conductive layer 220b are provided over the insulating layer 110.

The conductive layer 120a and the conductive layer 120b are electrically connected to the low-resistance regions 108N in the semiconductor layer 108 through the opening portion 141a and the opening portion 141b provided in the insulating layer 110 and the insulating layer 117. The conductive layer 220a and the conductive layer 220b are electrically connected to the low-resistance regions 208N in the semiconductor layer 208 through the opening portion 241a and the opening portion 241b provided in the insulating layer 110.

The conductive layer 120a, the conductive layer 120b, the conductive layer 220a, and the conductive layer 220b can be formed using the same material as the conductive layer 112 and the conductive layer 212. The conductive layer 120a, the conductive layer 120b, the conductive layer 220a, and the conductive layer 220b can be formed in the same step as that for the conductive layer 112 and the conductive layer 212. For example, after the formation of the opening portion 141a, the opening portion 141b, the opening portion 241a, and the opening portion 241b in the insulating layer 110, a conductive film covering the insulating layer 110, the opening portion 141a, the opening portion 141b, the opening portion 241a, and the opening portion 241b is formed and processed, whereby the conductive layer 112, the conductive layer 212, the conductive layer 120a, the conductive layer 120b, the conductive layer 220a, and the conductive layer 220b can be formed.

The insulating layer 118 may be provided to cover the conductive layer 120a, the conductive layer 120b, the conductive layer 220a, the conductive layer 220b, the conductive layer 112, and the conductive layer 212.

After the insulating layer 110 is formed, resist masks are formed in regions to be channel formation regions of the transistor 100M and the transistor 200M, and an impurity element is added with use of the resist masks as a mask, whereby the low-resistance region 108N and the low-resistance region 208N can be formed. After the resist masks are removed, the opening portion 141a, the opening portion 141b, the opening portion 241a, and the opening portion 241b are provided in the insulating layer 110, and subsequently the conductive layer 112, the conductive layer 212, the conductive layer 120a, the conductive layer 120b, the conductive layer 220a, and the conductive layer 220b can be formed.

A structure example different from that of the transistor 100M and the transistor 200M is illustrated in FIG. 20B. FIG. 20B is a cross-sectional view of a transistor 100N and a transistor 200N in the channel length direction. For a cross-sectional view of the transistors in the channel width direction, FIG. 17B can be referred to.

The transistor 100N is different from the transistor 100M mainly in that the insulating layer 110 and the insulating layer 117 are not provided between the semiconductor layer 108 and each of the conductive layer 120a and the conductive layer 120b. In other words, each of the conductive layer 120a and the conductive layer 120b includes a region in contact with a top surface and a side surface of the semiconductor layer 108. The transistor 200N is different from the transistor 200M mainly in that the insulating layer 110 is not provided between the semiconductor layer 208 and each of the conductive layer 220a and the conductive layer 220b. In other words, each of the conductive layer 220a and the conductive layer 220b includes a region in contact with a top surface and a side surface of the semiconductor layer 208.

As illustrated in FIG. 20B, in the transistor 100N, an end portion of the conductive layer 112 may be positioned more inwardly than an end portion of the insulating layer 110a and an end portion of the insulating layer 117a. In other words, the insulating layer 110a and the insulating layer 117a each include a portion extending beyond the end portion of the conductive layer 112 over at least the semiconductor layer 108. Similarly, in the transistor 200N, an end portion of the conductive layer 212 may be positioned more inwardly than an end portion of the insulating layer 110b. In other words, the insulating layer 110b includes a portion extending beyond the end portion of the conductive layer 212 over at least the semiconductor layer 208.

After the formation of the insulating layer 110a, the insulating layer 117a, and the insulating layer 110b, resist masks are formed in regions to be channel formation regions of the transistor 100N and the transistor 200N, and an impurity element is added with use of the resist masks as a mask, whereby the low-resistance region 108N, the region 108L, the low-resistance region 208N, and the region 208L can be formed. After the resist masks are removed, the conductive layer 112, the conductive layer 212, the conductive layer 120a, the conductive layer 120b, the conductive layer 220a, and the conductive layer 220b can be formed.

A structure example different from that of the transistor 100N and the transistor 200N is illustrated in FIG. 20C. FIG. 20C is a cross-sectional view of a transistor 100P and a transistor 200P in the channel length direction. For a cross-sectional view of the transistors in the channel width direction, FIG. 17B can be referred to.

The transistor 100P is different from the transistor 100N mainly in that the insulating layer 110a and the insulating layer 117a are provided between the semiconductor layer 108 and each of the conductive layer 120a and the conductive layer 120b. In other words, the insulating layer 117a includes a region in contact with a top surface and a side surface of the semiconductor layer 108. The transistor 200N is different from the transistor 200N mainly in that the insulating layer 110b is provided between the semiconductor layer 208 and each of the conductive layer 220a and the conductive layer 220b. In other words, the insulating layer 110b includes a region in contact with a top surface and a side surface of the semiconductor layer 208.

### <Manufacturing Method Example 1>

A manufacturing method example of the transistor of one embodiment of the present invention will be described below. Here, the method is described using the transistor 100A and the transistor 200A exemplified in Structure example 2. Here, a structure example in which a metal oxide is used for the semiconductor layer is described.

Note that thin films forming the semiconductor device (insulating films, semiconductor films, conductive films, and the like) can be formed by any of a sputtering method, a chemical vapor deposition (CVD) method, a vacuum evaporation method, a pulsed laser deposition (PLD) method, and an atomic layer deposition (ALD) method.

The thin films that form the semiconductor device (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

When the thin films that form the semiconductor device are processed, a photolithography method or the like can be used for the processing. Alternatively, a nanoimprinting method, a sandblasting method, a lift-off method, or the like may be used for the processing of the thin films. Island-shaped thin films may be directly formed by a deposition method using a blocking mask such as a metal mask.

There are the following two typical examples of a photolithography method. In one of the methods, a resist mask is formed over a thin film that is to be processed, the thin film is processed by etching or the like, and the resist mask is removed. In the other method, a photosensitive thin film is deposited and then processed into a desired shape by light exposure and development.

As the light used for light exposure in the photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. In addition, light exposure may be performed by liquid immersion exposure technique. As the light used for the light exposure, extreme ultraviolet (EUV) light, X-rays, or the like may be used. Instead of the light used for light exposure, an electron beam can be used. It is preferable to use extreme ultraviolet light, X-rays, or an electron beam because extremely minute processing can be performed. Note that in the case of performing light exposure by scanning of a beam such as an electron beam, a photomask is not needed.

For etching of the thin film, a dry etching method, a wet etching method, a sandblasting method, or the like can be used.

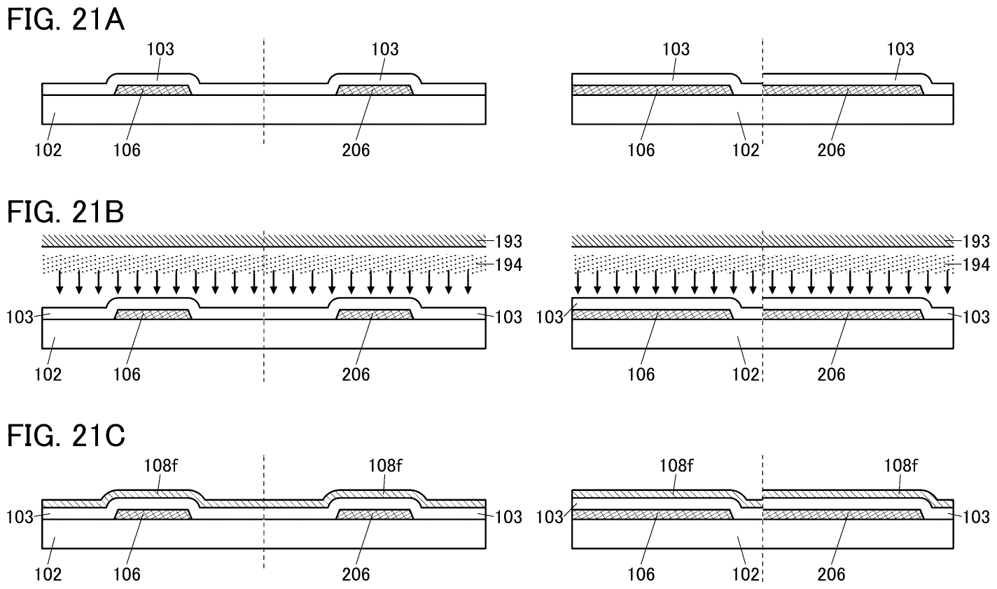

FIG. 21A to FIG. 26B are schematic cross-sectional views, side by side, illustrating stages in a manufacturing process of the transistor 100A and the transistor 200A illustrated in FIG. 4A and FIG. 4B. In each of the views, the left side is a schematic cross-sectional view in the channel length direction, and the right side is a schematic cross-sectional view in the channel width direction.

Hereinafter, the components of the transistor 100A and the transistor 200A that can be formed in the same step (e.g., the conductive layer 106 and the conductive layer 206, and the conductive layer 112 and the conductive layer 212) are assumed to have the same function and effect; in some cases, only one of them is described and the description is referred to for the other components.

### [Formation of Conductive Layer 106 and Conductive Layer 206]

A conductive film is deposited over the substrate 102 and processed by etching, whereby the conductive layer 106 and the conductive layer 206 each functioning as a gate electrode are formed (FIG. 21A).

At this time, as illustrated in FIG. 21A, each of the conductive layer 106 and the conductive layer 206 is preferably processed so as to have an end portion with a tapered shape. This can improve step coverage with the insulating layer 103 to be formed next.

In this specification and the like, a tapered shape indicates a shape in which at least part of the side surface of a structure is inclined to a surface where the components of this structure are formed. For example, the structure preferably includes a region where the angle between the inclined side surface and the formation surface (also referred to as a taper angle) is less than 90°.

When a conductive film containing copper is used as the conductive film to be the conductive layer 106 and the conductive layer 206, wiring resistance can be reduced. For example, a conductive film containing copper is preferably used in the case of a large display device or a display device with a high definition. Even in the case where a conductive film containing copper is used as the conductive layer 106 and the like, diffusion of copper to the side of the semiconductor layer 108 and the like can be suppressed by the insulating layer 103, whereby a highly reliable transistor can be obtained.

### [Formation of Insulating Layer 103]

Next, the insulating layer 103 is formed to cover the substrate 102, the conductive layer 106 and the conductive layer 206 (FIG. 21A). The insulating layer 103 can be formed by a PECVD method, an ALD method, a sputtering method, or the like.

In particular, the insulating layer 103 is preferably formed by a PECVD method.

The insulating layer 103 preferably has a stacked-layer structure including two or more insulating films. In this case, an insulating film containing nitrogen is preferably used as an insulating film positioned on the conductive layer 106 side. In contrast, an insulating film positioned on the side of the semiconductor layer 108 and the semiconductor layer 208 is preferably formed using an insulating film containing oxygen. The insulating films included in the insulating layer 103 are preferably formed successively without exposure to the air with a plasma CVD apparatus.

In the case where the insulating layer 103 is formed with a plasma CVD apparatus, static electricity accumulated on the substrate 102 may be eliminated by performing plasma treatment in a treatment chamber with power lower than that in the formation of the insulating layer 103 after the formation of the insulating layer 103. The plasma treatment can be referred to as a static eliminating process. For the static eliminating process, an atmosphere containing one or more of nitrogen, dinitrogen monoxide, nitrogen dioxide, hydrogen, ammonia, and a rare gas can be used. For example, an argon gas atmosphere can be suitably used for the static eliminating process. A mixed gas containing the plurality of gases may be used for the static eliminating process.

A surface of the insulating layer 103 may be removed after the formation of the insulating layer 103. The static eliminating process sometimes causes defects on the surface of the insulating layer 103. If defects exist in the insulating layer 103 functioning as the second gate insulating layer of the transistor 100A and the transistor 200A, the defects become carrier trap sites and the reliability of the transistor 100A and the transistor 200A might be degraded. Thus, the surface of the insulating layer 103 including defects is removed, so that the reliability of the transistor 100A and the transistor 200A can be increased. For example, cleaning using a cleaning solution containing a hydrofluoric acid can be used to remove the surface of the insulating layer 103. For example, the amount of etching the surface of the insulating layer 103 is preferably greater than or equal to 2 nm and less than or equal to 20 nm, further preferably greater than or equal to 3 nm and less than or equal to 15 nm, further preferably greater than or equal to 5 nm and less than or equal to 10 nm. Typically, the amount of etching the surface of the insulating layer 103 may be about 10 nm.

Heat treatment may be performed after the formation of the insulating layer 103. Heat treatment can reduce the number of defects included in the insulating layer 103. Impurities containing hydrogen elements contained in the insulating layer 103 can be reduced.

The heat treatment temperature is preferably higher than or equal to 150° C. and lower than the strain point of the substrate, further preferably higher than or equal to 250° C. and lower than or equal to 450° C., still further preferably higher than or equal to 300° C. and lower than or equal to 450° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating layer 103 can be inhibited. An oven, a rapid thermal annealing (RTA) apparatus, or the like can be used for the heat treatment. The use of the RTA apparatus can shorten the heat treatment time.

The heat treatment may be performed after the surface of the insulating layer 103 is removed.

Next, treatment for supplying oxygen to the insulating layer 103 may be performed. For example, as the treatment for supplying oxygen, plasma treatment, heat treatment, or the like in an oxygen atmosphere can be performed. Alternatively, as the treatment for supplying oxygen, a plasma ion doping method or an ion implantation method may be used.

[Formation of Metal Oxide Film 108f]

Next, a metal oxide film 108f is deposited over the insulating layer 103 (FIG. 21C).

The metal oxide film 108f is a film to be the semiconductor layer 108 later and preferably formed by a sputtering method using a metal oxide target.

The metal oxide film 108f is preferably a dense film with as few defects as possible. The metal oxide film 108f is preferably a highly purified film in which impurities such as hydrogen or water are reduced as much as possible. It is particularly preferable to use a metal oxide film having crystallinity as the metal oxide film 108f.

In forming the metal oxide film 108f, an oxygen gas is preferably used. FIG. 21B is a schematic cross-sectional view of the inside of a sputtering apparatus at the time of forming the metal oxide film 108f over the insulating layer 103. In FIG. 21B, a target 193 placed inside the sputtering apparatus and plasma 194 formed under the target 193 are schematically illustrated. In the case of using an oxygen gas at the time of forming the metal oxide film 108f, oxygen can be suitably supplied into the insulating layer 103. For example, in the case of using an oxide for the insulating layer 103, oxygen can be suitably supplied into the insulating layer 103. Note that oxygen supplied to the insulating layer 103 is represented by arrows in FIG. 21B.

When hydrogen exists in the semiconductor layer 108 in this situation, a state in which hydrogen enters the oxygen vacancy (Vo) (hereinafter, referred to as VoH) is sometimes generated. In some cases, VoH serves as a carrier generation source that adversely affects the electrical characteristics and reliability of the transistor. In particular, oxygen vacancies (Vo) and VoH in the channel formation region are preferably reduced as much as possible.

By the supply of oxygen to the insulating layer 103, oxygen is supplied to the semiconductor layer 108 and the semiconductor layer 208 in a later step, so that oxygen vacancies (Vo) and VoH in the semiconductor layer 108 and the semiconductor layer 208 can be reduced.

In depositing the metal oxide film, an inert gas (e.g., a helium gas, an argon gas, or a xenon gas) may be mixed in addition to the oxygen gas. Note that when the proportion of an oxygen gas in the whole deposition gas (hereinafter also referred to as an oxygen flow rate ratio) at the time of depositing the metal oxide film is higher, the crystallinity of the metal oxide film can be higher and a transistor with higher reliability can be obtained. On the other hand, when the oxygen flow rate ratio is lower, the crystallinity of the metal oxide film is lower and a transistor with a high on-state current can be obtained.

In depositing the metal oxide film, as the substrate temperature becomes higher, a denser metal oxide film having higher crystallinity can be formed. On the other hand, as the substrate temperature becomes lower, a metal oxide film having lower crystallinity and higher electric conductivity can be formed.

The metal oxide film is formed under the deposition conditions where a substrate temperature is higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than 140° C., high productivity is achieved, which is preferable. Furthermore, when the metal oxide film is deposited with the substrate temperature set at room temperature or without heating the substrate, the crystallinity can be made low.

It is preferable to perform at least one of treatment for desorbing water, hydrogen, an organic substance, and the like adsorbed onto the surface of the insulating layer 103 and treatment for supplying oxygen into the insulating layer 103 before the deposition of the metal oxide film 108f. For example, heat treatment can be performed at a temperature higher than or equal to 70° C. and lower than or equal to 200° C. in a reduced-pressure atmosphere. Alternatively, plasma treatment may be performed in an oxygen-containing atmosphere. Alternatively, oxygen may be supplied to the insulating layer 103 by plasma treatment in an atmosphere containing an oxidizing gas such as dinitrogen monoxide (N₂O). Performing plasma treatment containing a dinitrogen monoxide gas can supply oxygen while suitably removing an organic substance on the surface of the insulating layer 103. It is preferable that the metal oxide film 108f be deposited successively after such treatment, without exposure of the surface of the insulating layer 103 to the air.

Note that in the case where the semiconductor layer 108 has a stacked-layer structure in which a plurality of semiconductor layers are stacked, an upper metal oxide film is preferably deposited successively after deposition of a lower metal oxide film without exposure of the surface of the lower metal oxide layer to the air.

### [Formation of Semiconductor Layer 108]

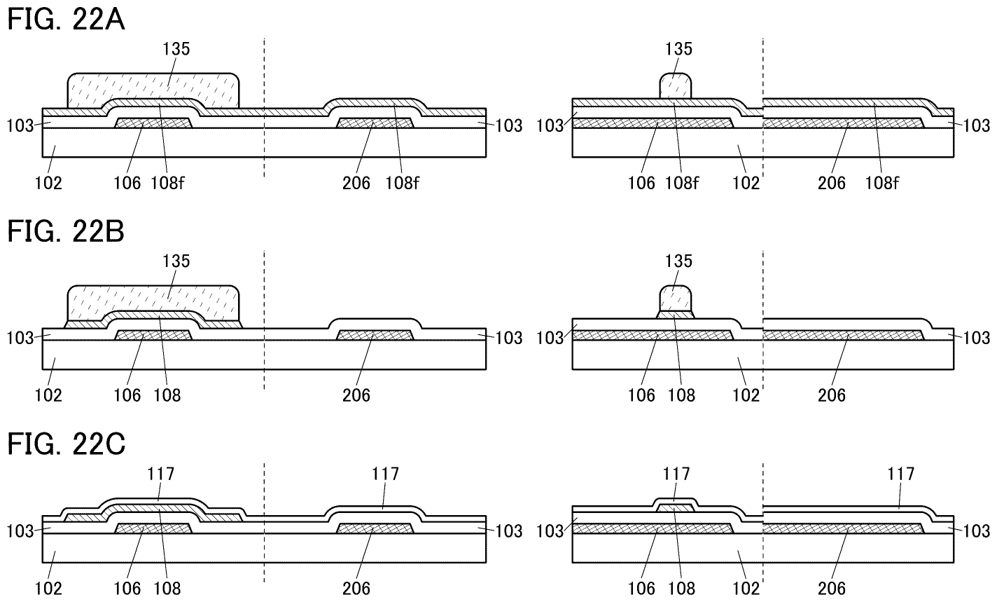

Then, a resist mask 135 is formed over the metal oxide film 108f (FIG. 22A).

Next, the metal oxide film 108f in a region not covered with the resist mask 135 is removed by etching, so that the semiconductor layer 108 is formed and the top surface of the insulating layer 103 is partly exposed (FIG. 22B). For etching of the metal oxide film 108f, either one or both of a wet etching method and a dry etching method is used. A wet etching method is preferably used for etching the metal oxide film 108f, in which case the etching damage on the semiconductor layer 108 can be reduced.

Thus, the island-shaped semiconductor layer 108 is formed.

The insulating layer 103 is preferably formed using a material having a high etching rate selectivity to the metal oxide film 108f. That is, the etching rate of the metal oxide film 108f is preferably higher than that of the insulating layer 103. The amount of etching the insulating layer 103 is made small, whereby the step between the insulating layer 103 and the semiconductor layer 108 becomes small, and the step coverage of a layer (e.g., the insulating layer 117) formed over the insulating layer 103 and the semiconductor layer 108 is improved. As a result, generation of defects such as disconnection or voids in the layer can be suppressed.

When a wet etching method is used for etching the metal oxide film 108f, an etchant containing one or more of oxalic acid, phosphoric acid, acetic acid, nitric acid, hydrofluoric acid, and tetramethyl ammonium hydroxide (TMAH) can be used, for example. In addition, an etchant containing phosphoric acid, acetic acid, and nitric acid can be favorably used.

At the time of forming the semiconductor layer 108, the thickness of the insulating layer 103 in a region not overlapping with the semiconductor layer 108 is sometimes smaller than the thickness of the insulating layer 103 in a region overlapping with the semiconductor layer 108. Alternatively, the insulating layer 103 in the region not overlapping with the semiconductor layer 108 may be removed. By the removal of the insulating layer 103 in the region not overlapping with the semiconductor layer 108, the transistor 100E illustrated in FIG. 9A and the like can be formed.

After that, the resist mask 135 is removed. The removal of the resist mask 135 can be performed by one or both of a wet etching method and a dry etching method.

### [Formation of Insulating Layer 117]

Next, the insulating layer 117 is formed to cover the insulating layer 103 and the semiconductor layer 108 (FIG. 22C). The insulating layer 117 can be formed using a method similar to that of the insulating layer 103. For formation of the insulating layer 117, a PECVD method can be favorably used, for example.

It is preferable to perform plasma treatment on surfaces of the insulating layer 103 and the semiconductor layer 108 before deposition of the gate insulating layer 117. By the plasma treatment, an impurity adsorbed onto the surfaces of the insulating layer 103 and the semiconductor layer 108, such as water, can be reduced. Therefore, impurities at the interface between the semiconductor layer 108 and the insulating layer 103 can be reduced, achieving a highly reliable transistor. The plasma treatment is particularly suitable in the case where the surface of the semiconductor layer 108 is exposed to the air after the formation of the semiconductor layer 108 and before the deposition of the gate insulating layer 117. For example, plasma treatment can be performed in an atmosphere containing oxygen, ozone, nitrogen, dinitrogen monoxide, argon, or the like. The plasma treatment and the deposition of the insulating layer 117 are preferably performed successively without exposure to the air.

[Formation of Metal Oxide Film 208f]

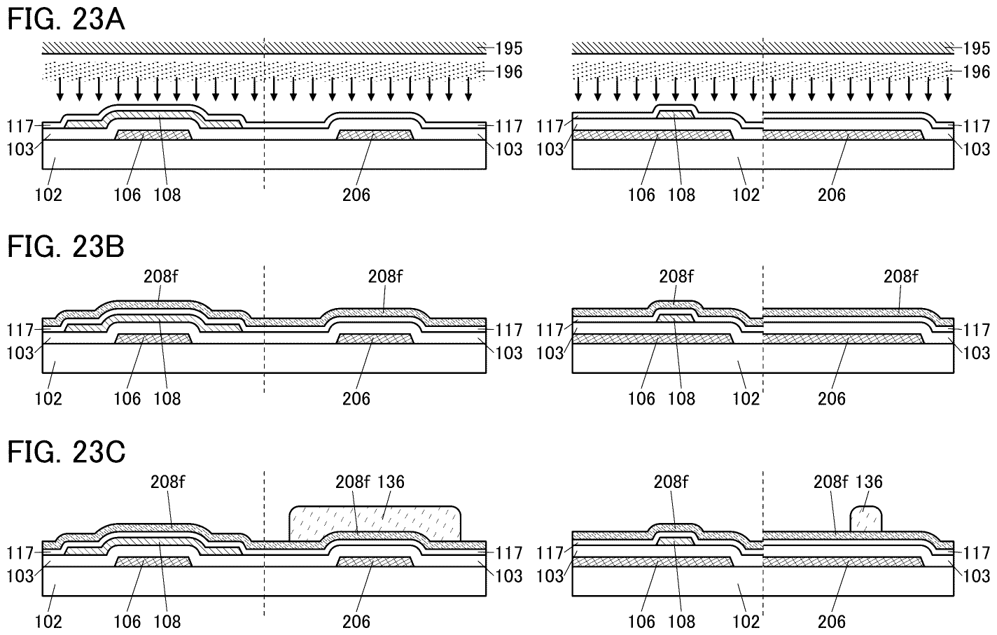

Next, a metal oxide film 208f is formed over the insulating layer 117 (FIG. 23B).

The metal oxide film 208f is a film to be the semiconductor layer 208 later and preferably formed by a sputtering method using a metal oxide target. The metal oxide film 208f can be deposited using a sputtering target different from that used for the above metal oxide film 108f. For details of the deposition of the metal oxide film 208f, the above description of the metal oxide film 108f can be referred to.

In forming the metal oxide film 208f, an oxygen gas is preferably used. FIG. 23A is a schematic cross-sectional view of the inside of a sputtering apparatus at the time of forming the metal oxide film 208f over the insulating layer 117. In FIG. 23A, a target 195 placed inside the sputtering apparatus and plasma 196 formed under the target 195 are schematically illustrated. In the case of using an oxygen gas at the time of forming the metal oxide film 208f, oxygen can be suitably supplied into the insulating layer 117. Note that oxygen supplied to the insulating layer 117 is represented by arrows in FIG. 23A. Note that oxygen may be supplied to the insulating layer 103.

By the supply of oxygen to the insulating layer 117, oxygen is supplied to the semiconductor layer 108 and the semiconductor layer 208 in a later step, so that oxygen vacancies (Vo) and VoH in the semiconductor layer 108 and the semiconductor layer 208 can be reduced.

### [Formation of Semiconductor Layer 208]

Then, a resist mask 136 is formed over the metal oxide film 108f (FIG. 23C).

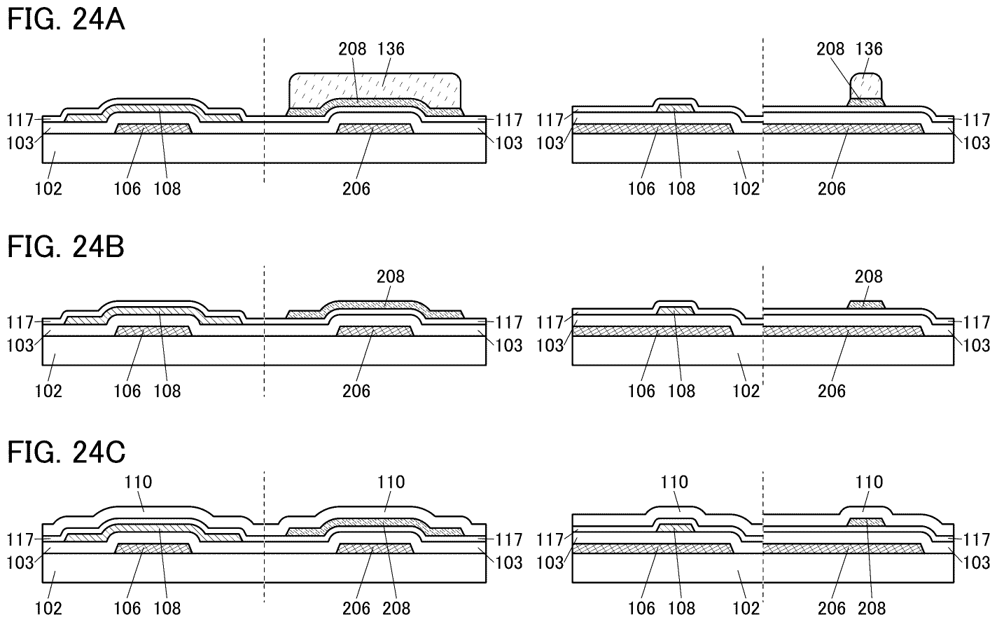

Next, the metal oxide film 208f in a region not covered with the resist mask 136 is removed by etching, so that the semiconductor layer 208 is formed and the top surface of the insulating layer 117 is partly exposed (FIG. 24A). For etching of the metal oxide film 208f, either one or both of a wet etching method and a dry etching method can be used. A wet etching method is preferably used for etching the metal oxide film 208f, in which case the etching damage to the semiconductor layer 208 can be reduced.

Furthermore, the insulating layer 117 is preferably formed using a material having a high etching rate selectivity to the metal oxide film 208f That is, the etching rate of the metal oxide film 208f is preferably higher than that of the insulating layer 117. The amount of etching the insulating layer 117 is made small, whereby the step between the insulating layer 117 and the semiconductor layer 208 becomes small, and the step coverage of a layer (e.g., the insulating layer 110) formed over the insulating layer 117 and the semiconductor layer 208 is improved. As a result, generation of defects such as disconnection or voids in the layer can be suppressed. The metal oxide film 208f can be etched by the method that can be used for etching of the metal oxide film 108f.

At the time of forming the semiconductor layer 208, the thickness of the insulating layer 117 in a region not overlapping with the semiconductor layer 208 is sometimes smaller than the thickness of the insulating layer 117 in a region overlapping with the semiconductor layer 208.

After that, the resist mask 136 is removed (FIG. 24B).

Through the above steps, the semiconductor layer 108 and the semiconductor layer 208 with different compositions can be formed.

Although the semiconductor layer 208 is formed here after the formation of the semiconductor layer 108, the formation order is not limited thereto. That is, the semiconductor layer 108 may be formed after the formation of the semiconductor layer 208.

Although this embodiment describes a structure where two types of semiconductor layers, the semiconductor layer 108 and the semiconductor layer 208, are separately formed, one embodiment of the present invention is not limited thereto. By repetition of the above-described formation of insulating layers and semiconductor layers, three or more types of semiconductor layers can be separately formed. In other words, manufacture of semiconductor devices in each of which three or more types of transistors are incorporated, without a significant increase in steps, is possible.

### [Heat Treatment]

After the semiconductor layer 108 and the semiconductor layer 208 are formed, heat treatment is preferably performed. By the heat treatment, hydrogen or water contained in the semiconductor layer 108 and the semiconductor layer 208 or adsorbed on their surfaces can be removed. Furthermore, the film quality of the semiconductor layer 108 and the semiconductor layer 208 is improved (e.g., the number of defects is reduced or crystallinity is increased) by the heat treatment in some cases.

Furthermore, oxygen can be supplied from the insulating layer 103 to the semiconductor layer 108 and the semiconductor layer 208 by heat treatment.

The temperature of the heat treatment can be typically higher than or equal to 150° C. and lower than the strain point of the substrate, higher than or equal to 200° C. and lower than or equal to 500° C., higher than or equal to 250° C. and lower than or equal to 450° C., or higher than or equal to 300° C. and lower than or equal to 450° C.

The heat treatment can be performed in an atmosphere containing a noble gas or nitrogen. Alternatively, heating may be performed in the atmosphere, and then heating may be performed in an oxygen-containing atmosphere. Alternatively, heating may be performed in a dry air atmosphere. It is preferable that the atmosphere of the above heat treatment contain hydrogen, water, or the like as little as possible. An electric furnace, an RTA apparatus, or the like can be used for the heat treatment. The use of the RTA apparatus can shorten the heat treatment time.

Note that the heat treatment is not necessarily performed. The heat treatment is not performed in this step, and instead heat treatment performed in a later step may also serve as the heat treatment in this step. In some cases, treatment at a high temperature (e.g., deposition step) or the like in a later step can serve as the heat treatment in this step.

### [Formation of Insulating Layer 110]

Next, the insulating layer 110 is formed to cover the insulating layer 117 and the semiconductor layer 208 (FIG. 24C).

The insulating layer 110 can be formed using a method similar to that of the insulating layer 103. For formation of the insulating layer 110, a PECVD method can be favorably used, for example.

It is preferable to perform plasma treatment on surfaces of the insulating layer 117 and the semiconductor layer 208 before deposition of the insulating layer 110. By the plasma treatment, an impurity adsorbed onto the surfaces of the insulating layer 117 and the semiconductor layer 208, such as water, can be reduced. Therefore, impurities at the interface between the semiconductor layer 208 and the insulating layer 110 can be reduced, achieving a highly reliable transistor. The plasma treatment is particularly suitable in the case where the surface of the semiconductor layer 208 is exposed to the air after the formation of the semiconductor layer 208 and before the deposition of the insulating layer 110. For example, plasma treatment can be performed in an atmosphere containing oxygen, ozone, nitrogen, dinitrogen monoxide, argon, or the like. The plasma treatment and the deposition of the insulating layer 110 are preferably performed successively without exposure to the air.

After the insulating layer 110 is deposited, heat treatment is preferably performed. By the heat treatment, hydrogen or water contained in the insulating layer 110 or adsorbed on its surface can be removed. At the same time, the number of defects in the insulating layer 110 can be reduced.

For the conditions of the heat treatment, the above description can be referred to.

Note that the heat treatment is not necessarily performed. The heat treatment is not performed in this step, and instead heat treatment performed in a later step may also serve as the heat treatment in this step. In some cases, treatment at a high temperature (e.g., deposition step) or the like in a later step can serve as the heat treatment in this step.

### [Formation of Opening Portion 142 and Opening Portion 242]

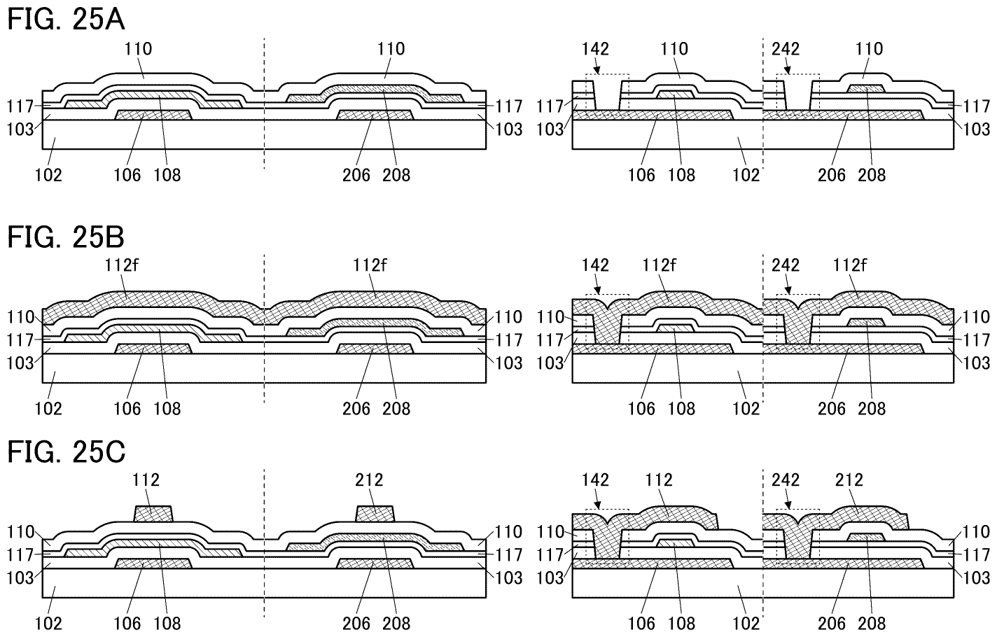

Next, the insulating layer 110, the insulating layer 117, and the insulating layer 103 are partly etched, whereby the opening portion 142 reaching the conductive layer 106 and the opening portion 242 reaching the conductive layer 206 are formed (FIG. 25A). Accordingly, the conductive layer 112 to be formed later can be electrically connected to the conductive layer 106 through the opening portion 142. The conductive layer 212 to be formed later can be electrically connected to the conductive layer 206 through the opening portion 142.

### [Formation of Conductive Layer 112 and Conductive Layer 212]

Next, a conductive film 112f to be the conductive layer 112 and the conductive layer 212 is deposited over the insulating layer 110 (FIG. 25B).

For the conductive film 112f, a low-resistance metal or a low-resistance alloy material is preferably used. It is preferable that the conductive film 112f be formed using a material from which hydrogen is less likely to be released and in which hydrogen is less likely to be diffused. Furthermore, a material that is less likely to be oxidized is preferably used for the conductive film 112f.

For example, the conductive film 112f is preferably deposited by a sputtering method using a sputtering target containing a metal or an alloy.

For example, the conductive film 112f is preferably a stacked-layer film including a low-resistance conductive film and a conductive film which is less likely to be oxidized and in which hydrogen is less likely to be diffused.

Next, the conductive film 112f is partly etched to form the conductive layer 112 and the conductive layer 212 (FIG. 25C).

For the etching of the conductive film 112f, a wet etching method is preferably used, in particular.

As described above, the insulating layer 110 and the insulating layer 117 are not etched and cover the top surface and the side surface of the semiconductor layer 108, the top surface and the side surface of the semiconductor layer 208, and the insulating layer 103, which prevents the semiconductor layer 108, the semiconductor layer 208, and the insulating layer 103 from being partly etched and thinned in etching the conductive film 112f or the like.

### [Treatment for Supplying Impurity Element]

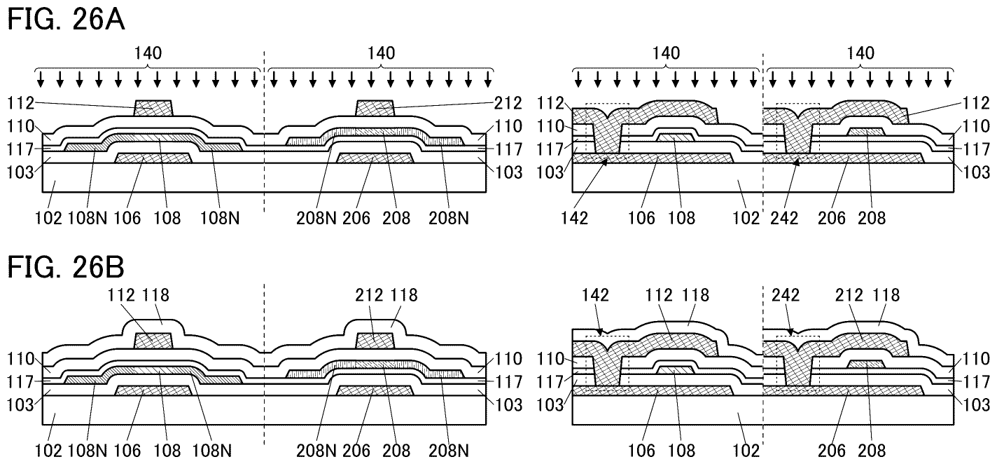

Next, treatment for supplying (also referred to as “adding” or “injecting”) an impurity element 140 to the semiconductor layer 108 and the semiconductor layer 208 is performed with use of the conductive layer 112 and the conductive layer 212 as masks (FIG. 26A). The semiconductor layer 108 is supplied with impurity element 140 through the insulating layer 110 and the insulating layer 117. The semiconductor layer 208 is supplied with the impurity element 140 through the insulating layer 140.

Through the supply of the impurity element 140, the low-resistance regions 108N can be formed in regions of the semiconductor layer 108 that are not covered with the conductive layer 112. Similarly, the low-resistance regions 208N can be formed in the semiconductor layer 208. At this time, the conditions of the treatment for supplying the impurity element 140 are preferably determined in consideration of the material, thickness, or the like of the conductive layer 112 and the conductive layer 212 serving as the masks and the like so that the impurity element 140 is supplied as little as possible to the region of the semiconductor layer 108 that overlaps with the conductive layer 112 and the region of the semiconductor layer 208 that overlaps with the conductive layer 212. In this manner, a channel formation region with a sufficiently reduced impurity concentration can be formed in each of the region of the semiconductor layer 108 that overlaps with the conductive layer 112 and the region of the semiconductor layer 208 that overlaps with the conductive layer 212.

By adjusting the thickness of the insulating layer 117, the amount of impurity elements 140 added to the low-resistance region 108N and that added to the low-resistance region 208N can be different from each other. For example, an increase in the thickness of the insulating layer 117 can make the amount of impurity elements 140 added to the low-resistance region 108N smaller than that added to the low-resistance region 208N. By contrast, a reduction in the thickness of the insulating layer 117 can make the amount of impurity elements 140 added to the low-resistance region 108N equal to that added to the low-resistance region 208N.

A plasma ion doping method or an ion implantation method can be suitably used for the supply of the impurity element 140. In these methods, the concentration profile in the depth direction can be controlled with high accuracy by the acceleration voltage and the dosage of ions, or the like. The use of a plasma ion doping method can increase productivity. In addition, the use of an ion implantation method with mass separation can increase the purity of an impurity element to be supplied.

In the treatment for supplying the impurity element 140, treatment conditions are preferably controlled such that the concentration is the highest at an interface between the semiconductor layer 108 and the insulating layer 117, an interface between the semiconductor layer 208 and the insulating layer 110, a portion in each of the semiconductor layers near its interface, or a portion in each of the insulating layers near its interface. Accordingly, the impurity element 140 at an optimal concentration can be supplied to the semiconductor layer 108, the semiconductor layer 208, the insulating layer 110, and the insulating layer 117 in one treatment.

Examples of the impurity element 140 include one or more of hydrogen, boron, carbon, nitrogen, fluorine, phosphorus, sulfur, arsenic, aluminum, magnesium, silicon, and a noble gas. Note that typical examples of a noble gas include helium, neon, argon, krypton, and xenon. It is particularly preferable to use one or more of boron, phosphorus, aluminum, magnesium, and silicon as the impurity element 140.

As a source gas of the impurity element 140, a gas containing any of the above impurity elements can be used. In the case where boron is supplied, typically, a B₂H₆ gas, a BF₃ gas, or the like can be used. In the case where phosphorus is supplied, typically, a PH₃ gas can be used. A mixed gas in which any of these source gases is diluted with a noble gas may be used.

Besides, any of CH₄, N₂, NH₃, A₁H₃, AlCl₃, SiH₄, Si₂H₆, F₂, HF, H₂, (C₅H₅)₂Mg, a noble gas, and the like can be used as the source gas. An ion source is not limited to a gas, and a solid or a liquid that is vaporized by heating may be used.

Addition of the impurity element 140 can be controlled by setting the conditions such as the acceleration voltage and the dosage in consideration of the compositions, densities, thicknesses, and the like of the insulating layer 110, the semiconductor layer 108, and the semiconductor layer 208.

In the case where boron or phosphorus is added by an ion implantation method or a plasma ion doping method, the dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

Note that a method for supplying the impurity element 140 is not limited thereto; treatment using thermal diffusion by heating, plasma treatment, or the like may be used, for example. In a plasma treatment method, plasma is generated in a gas atmosphere containing an impurity element to be added and plasma treatment is performed, so that the impurity element can be added. A dry etching apparatus, an ashing apparatus, a plasma CVD apparatus, a high-density plasma CVD apparatus, or the like can be used as an apparatus for generating the plasma.

In one embodiment of the present invention, the impurity element 140 can be supplied to the semiconductor layer 108 through the insulating layer 110 and the insulating layer 117 and also can be supplied to the semiconductor layer 208 through the insulating layer 110. Thus, even in the case where the semiconductor layer 108 or the semiconductor layer 208 has crystallinity, damage given to the semiconductor layer 108 and the semiconductor layer 208 at the time of supplying the impurity element 140 is reduced, and degradation of crystallinity can be inhibited. Therefore, this is suitable for the case where an increase in electrical resistance is caused by a reduction in crystallinity.

### [Formation of Insulating Layer 118]

Next, the insulating layer 118 is formed to cover the insulating layer 110, the conductive layer 112, and the conductive layer 212 (FIG. 26B).

In the case where the insulating layer 118 is formed by a plasma CVD method, too high a substrate temperature in film deposition might cause diffusion of the impurity contained in the low-resistance regions 108N and the like to a surrounding portion including the channel formation region of the semiconductor layer 108 or might increase the electric resistance of the low-resistance regions 108N. Thus, the substrate temperature at the time of depositing the insulating layer 118 is determined in consideration of these.

The substrate temperature at the time of depositing the insulating layer 118 is preferably higher than or equal to 150° C. and lower than or equal to 400° C., further preferably higher than or equal to 180° C. and lower than or equal to 360° C., still further preferably higher than or equal to 200° C. and lower than or equal to 250° C., for example. Deposition of the insulating layer 118 at low temperatures enables the transistor to have favorable electrical characteristics even when it has a short channel length.

Heat treatment may be performed after the formation of the insulating layer 118. The heat treatment can allow the low-resistance region 108N and the low-resistance region 208N to have low resistance more stably, in some cases. For example, by the heat treatment, the impurity element 140 diffuses moderately and homogenized locally, so that the low-resistance region 108N and the low-resistance region 208N each having an ideal concentration gradient of the impurity element can be formed. Note that when the temperature of the heat treatment is too high (e.g., higher than or equal to 500° C.), the impurity element 140 is also diffused into the channel formation region, so that the electrical characteristics and reliability of the transistor might be degraded.

For the conditions of the heat treatment, the above description can be referred to.

Note that the heat treatment is not necessarily performed. The heat treatment is not performed in this step, and instead heat treatment performed in a later step may also serve as the heat treatment in this step. In the case where treatment at a high temperature is performed (e.g., deposition step) in a later step, such treatment can serve as the heat treatment in this step in some cases.

[Formation of Opening Portion 141a, Opening Portion 141b, Opening Portion 241a, and Opening Portion 241b]

Next, the insulating layer 118, the insulating layer 110, and the insulating layer 117 are partly etched to form the opening portion 141a and the opening portion 141b reaching the low-resistance region 108N and the opening portion 241a and the opening portion 241b reaching the low-resistance region 208N.

[Formation of Conductive Layer 120a, Conductive Layer 120b, Conductive Layer 220a, and Conductive Layer 220b]

Next, a conductive film is deposited over the insulating layer 118 to cover the opening portion 141a, the opening portion 141b, the opening portion 241a, and the opening portion 241b, and the conductive film is processed into a desired shape, so that the conductive layer 120a, the conductive layer 120b, the conductive layer 220a, and the conductive layer 220b are formed (FIG. 4A and FIG. 4B).

Through the above process, the transistor 100A and the transistor 200A can be manufactured. In the case where the transistor 100A is used in a pixel of a display device, for example, this process may be followed by a step of forming one or more of a protective insulating layer, a planarization layer, a pixel electrode, and a wiring.

The above is the description of Manufacturing method example 1.

### <Manufacturing Method Example 2>

A manufacturing method of the transistor 100C and the transistor 200C illustrated in FIG. 7A and FIG. 7B will be described. Note that description of the same portions as Manufacturing method example 1 described above is omitted and different portions will be described.

First, as in Manufacturing method example 1, the steps up to the formation of the insulating layer 118 are performed (FIG. 26B).

### [Formation of Insulating Layer 130]

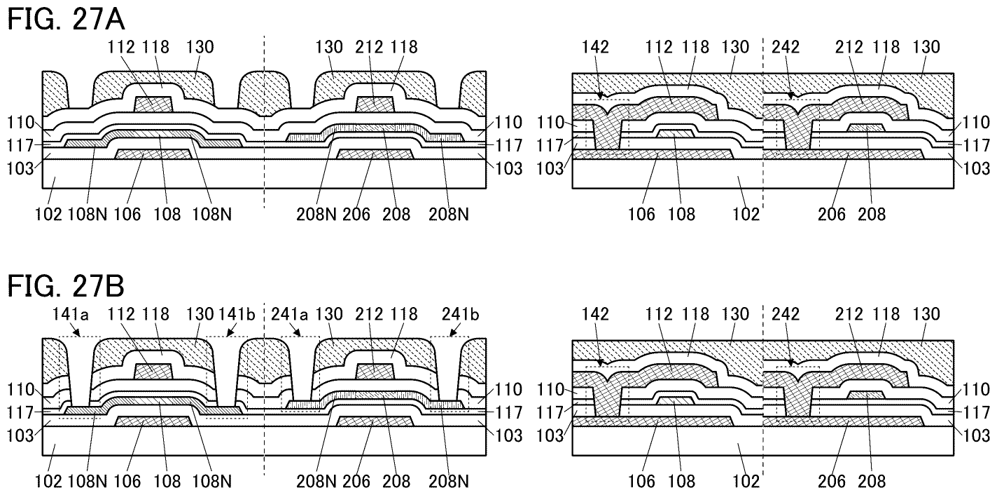

Next, the insulating layer 130 is formed over the insulating layer 118 (FIG. 27A). The insulating layer 130 has an opening in a region that does not overlap with the semiconductor layer 108 or the semiconductor layer 208.

For example, when a photosensitive organic material is used for the insulating layer 130, the insulating layer 130 can be formed in the following manner: a composition containing an organic material is applied by a spin coating method, and then the composition is subjected to selective light exposure and development. As another formation method, one or more of a sputtering method, an evaporation method, a droplet discharging method (an inkjet method), a screen printing method, and an offset printing method may be used.

Here, after the insulating layer 130 is formed, heat treatment is preferably performed. In the case where an organic material is used for the insulating layer 130, the heat treatment can cure the organic material.

The temperature of the heat treatment is preferably lower than the heat resistant temperature of the organic material. For example, the temperature of the heat treatment is preferably higher than or equal to 150° C. and lower than or equal to 350° C., further preferably higher than or equal to 180° C. and lower than or equal to 300° C., still further preferably higher than or equal to 200° C. and lower than or equal to 270° C., yet further preferably higher than or equal to 200° C. and lower than or equal to 250° C., yet still further preferably higher than or equal to 220° C. and lower than or equal to 250° C.

The heat treatment can be performed in an atmosphere containing a noble gas or nitrogen. Alternatively, heating may be performed in a dry air atmosphere. It is preferable that the atmosphere of the above heat treatment contain hydrogen, water, or the like as little as possible. An electric furnace, an RTA apparatus, or the like can be used for the heat treatment, for example.

[Formation of Opening Portion 141a, Opening Portion 141b, Opening Portion 241a, and Opening Portion 241b]

Next, the insulating layer 118, the insulating layer 110, and the insulating layer 117 are partly etched, so that the opening portion 141a and the opening portion 141b reaching the low-resistance regions 108N and the opening portion 241a and the opening portion 241b reaching the low-resistance regions 208N are formed (FIG. 27B).

[Formation of Conductive Layer 120a, Conductive Layer 120b, Conductive Layer 220a, and Conductive Layer 220b]

Next, a conductive film is deposited over the insulating layer 130 to cover the opening portion 141a, the opening portion 141b, the opening portion 241a, and the opening portion 241b, and the conductive film is processed into a desired shape, so that the conductive layer 120a, the conductive layer 120b, the conductive layer 220a, and the conductive layer 220b are formed (FIG. 7A and FIG. 7B).

Through the above process, the transistor 100C and the transistor 200C can be manufactured.

In the case of manufacturing the transistor 100D and the transistor 200D illustrated in FIG. 8A and the like, an insulating film to be the insulating layer 132 is deposited after the insulating layer 130 is formed, the opening portion 143a, the opening portion 143b, the opening portion 243a, and the opening portion 243b are formed in the insulating film, and the conductive layer 120a, the conductive layer 120b, the conductive layer 220a, and the conductive layer 220b are formed. Heat treatment is preferably performed after the insulating layer 130 is formed and before the insulating film to be the insulating layer 132 is formed.

The above is the description of Manufacturing method example 2.

### <Manufacturing Method Example 3>

A manufacturing method of the transistor 100J and the transistor 200J illustrated in FIG. 17A and FIG. 17B will be described. Note that description of the same portions as Manufacturing method example 1 described above is omitted and different portions will be described.

First, as in Manufacturing method example 1, the steps up to the formation of the conductive film 112f are performed (FIG. 25B).

### [Formation of Insulating Layer 110a, Insulating Layer 110b, Insulating Layer 117a, Insulating Layer 117b, Conductive Layer 112, and Conductive Layer 212]

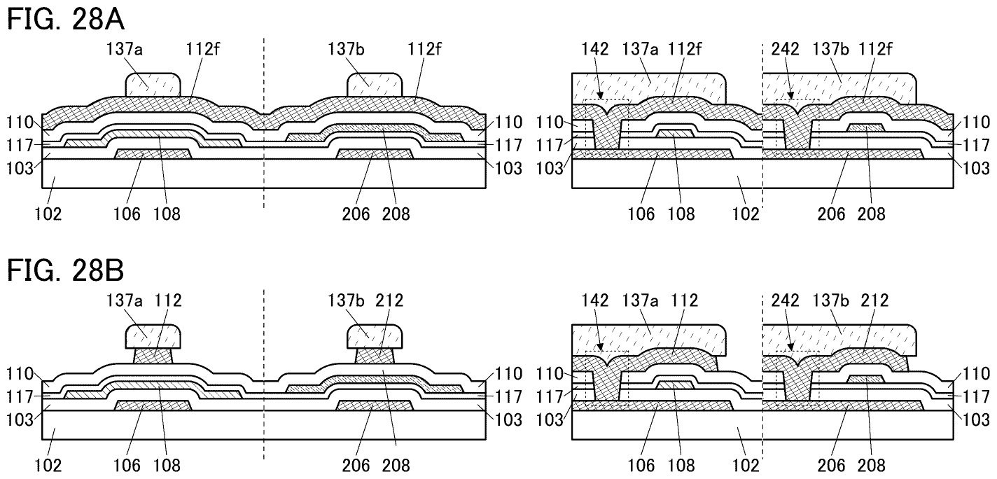

Next, a resist mask 137a and a resist mask 137b are formed over the conductive film 112f (FIG. 28A). Then, the conductive film 112f in a region not covered with the resist mask 137a and a region not covered with the resist mask 137b is removed, so that the conductive layer 112 and the conductive layer 212 are formed (FIG. 28B).

In formation of the conductive layer 112 and the conductive layer 212, the conductive film 112 is processed so that the end portion of the conductive layer 112 is positioned more inwardly than the outline of the resist mask 137a and the end portion of the conductive layer 212 is positioned more inwardly than the outline of the resist mask 137b. A wet etching method can be suitably used to form the conductive layer 112 and the conductive layer 212. In a wet etching method, for example, an etchant containing hydrogen peroxide can be used. For example, an etchant containing one or more of phosphoric acid, acetic acid, nitric acid, hydrochloric acid, and sulfuric acid can be used. In particular, in the case where a material containing copper is used for the conductive layer 112 and the conductive layer 212, an etchant containing phosphoric acid, acetic acid, and nitric acid can be suitably used. The widths of the region 108L and the region 208L can be controlled by adjustment of the etching time.

The conductive layer 112 and the conductive layer 212 may be formed in the following manner: the conductive film 112f is etched by an anisotropic etching method, and then a side surface of the conductive film 112f is etched by an isotropic etching method to make the end surface recede (also referred to as side etching). Accordingly, it is possible to form the conductive layer 112 positioned more inwardly than the insulating layer 110a and the conductive layer 212 positioned more inwardly than the insulating layer 110b in a plan view.

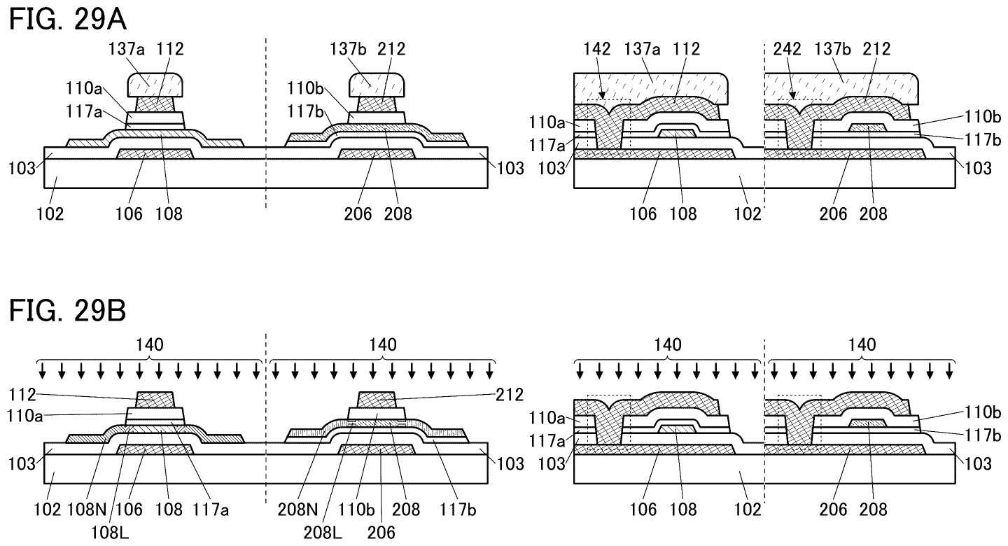

Next, the insulating layer 110 and the insulating layer 117 in a region not covered with the resist mask 137a and a region not covered with the resist mask 137b are removed, whereby the insulating layer 110a, the insulating layer 117a, and the insulating layer 110b are formed (FIG. 29A). At this time, the insulating layer 117 in a region not covered with the semiconductor layer 208 may be also removed to form the insulating layer 117b whose top surface shape is aligned or substantially aligned with the top surface shape of the semiconductor layer 208.

For the formation of the insulating layer 110a, the insulating layer 110b, the insulating layer 117a, and the insulating layer 117b, either one or both of a wet etching method and a dry etching method can be used. Note that after the removal of the resist mask 137a and the resist mask 137b, the insulating layer 110a, the insulating layer 110b, the insulating layer 117a, and the insulating layer 117b may be formed; however, keeping the resist mask 137a and the resist mask 137b enables a reduction in thicknesses of the conductive layer 112 and the conductive layer 212 to be prevented.

After that, the resist mask 137a and the resist mask 137b are removed.

### [Treatment for Supplying Impurity Element]

Next, treatment for supplying (adding or injecting) the impurity element 140 to the semiconductor layer 108 and the semiconductor layer 208 is performed with use of the conductive layer 112 and the conductive layer 212 as masks (FIG. 29B).

By the supply of the impurity element 140, the low-resistance region 108N can be formed in a region of the semiconductor layer 108 that is not covered with any of the conductive layer 112, the insulating layer 117a, or the insulating layer 110a. The region 108L can be formed in a region of the semiconductor layer 108 that does not overlap with the conductive layer 112 and is covered with the insulating layer 117a and the insulating layer 110a. The region 108L is supplied with the impurity element 140 through the insulating layer 110a and the insulating layer 117a. Similarly, the low-resistance region 208N and the region 208L can be formed in the semiconductor layer 208. Note that the region 208L is supplied with the impurity element 140 through the insulating layer 110b.

Note that by adjusting the thickness of the insulating layer 117, the amount of impurity elements 140 added to the regions 108L and that added to the region 208L can be different from each other. For example, an increase in the thickness of the insulating layer 117 can make the amount of impurity elements 140 added to the region 108L smaller than that added to the region 208L. By contrast, a reduction in the thickness of the insulating layer 117 can make the amount of impurity elements 140 added to the region 108L equal to that added to the region 208L.

Next, the insulating layer 118 is formed. Steps subsequent to the formation of the insulating layer 118 can be performed in a way similar to those of Manufacturing method example 1.

Through the above process, the transistor 100J and the transistor 200J can be manufactured.

The above is the description of Manufacturing method example 3.

### <Manufacturing Method Example 4>

A method for manufacturing the transistor 100K and the transistor 200K illustrated in FIG. 18A and FIG. 18B will be described. Note that description of the same portions as Manufacturing method example 1 described above is omitted and different portions will be described.

First, as in Manufacturing method example 1, the steps up to the formation of the insulating layer 110 are performed (FIG. 24C).

[Formation of Metal Oxide Film 114f]

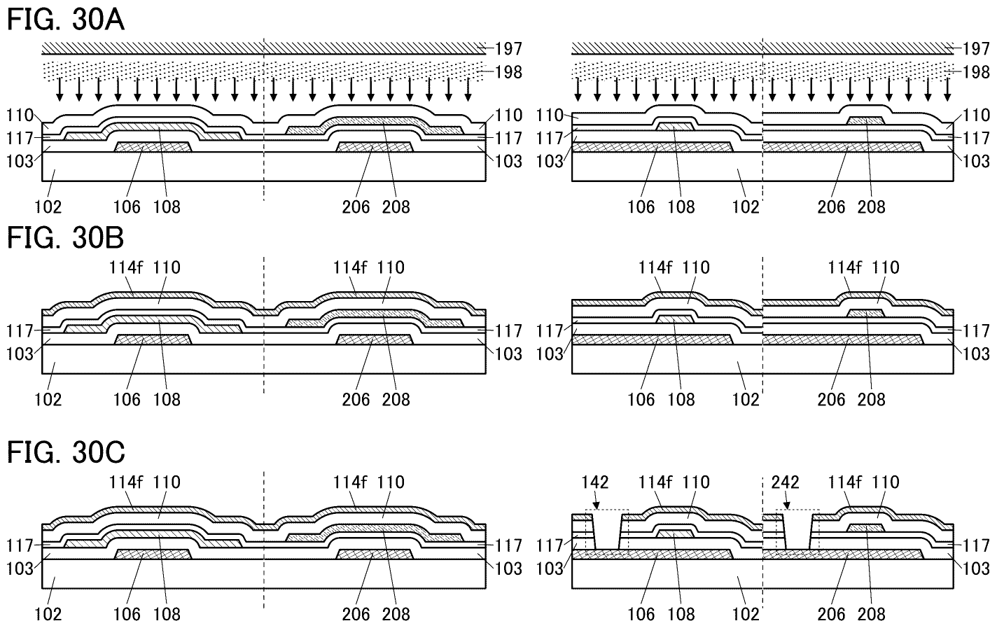

Next, a metal oxide film 114f is formed over the insulating layer 110 (FIG. 30B).

The metal oxide film 114f is preferably deposited in an oxygen-containing atmosphere, for example. It is particularly preferable that the metal oxide film 114f be formed by a sputtering method in an oxygen-containing atmosphere. In that case, oxygen can be supplied to the insulating layer 110 at the time of depositing the metal oxide film 114f Note that oxygen may be supplied to the insulating layer 117, the semiconductor layer 108, and the semiconductor layer 208 at the time of depositing the metal oxide film 114f.

In forming the metal oxide film 114f, an oxygen gas is preferably used. FIG. 30A is a schematic cross-sectional view of the inside of a sputtering apparatus at the time of forming the metal oxide film 114f over the insulating layer 110. In FIG. 30A, a target 197 placed inside the sputtering apparatus and plasma 198 formed under the target 197 are schematically illustrated. In the case of using an oxygen gas at the time of forming the metal oxide film 114f, oxygen can be suitably supplied into the insulating layer 110. Note that oxygen supplied to the insulating layer 110 is represented by arrows in FIG. 30A.

By the supply of oxygen to the insulating layer 110, oxygen is supplied to the semiconductor layer 108 and the semiconductor layer 208 in a later step, so that oxygen vacancies (Vo) and VoH in the semiconductor layer 108 and the semiconductor layer 208 can be reduced.

The above description of the semiconductor layer 108 and the semiconductor layer 208 can be referred to for the case where the metal oxide film 114f is formed by a sputtering method using an oxide target containing a metal oxide as in the case of the semiconductor layer 108 and the semiconductor layer 208.

For example, as deposition conditions of the metal oxide film 114f, a metal oxide film may be formed by a reactive sputtering method with a metal target using oxygen as a deposition gas. When aluminum is used for the metal target, for example, an aluminum oxide film can be deposited.

At the time of depositing the metal oxide film 114f, the amount of oxygen supplied into the insulating layer 110 can be increased with a higher proportion of the oxygen flow rate to the total flow rate of the deposition gas introduced into a deposition chamber of a deposition apparatus (a higher oxygen flow rate ratio) or with higher oxygen partial pressure in the deposition chamber. The oxygen flow rate ratio or oxygen partial pressure is, for example, set to higher than or equal to 20% and lower than or equal to 100%, preferably higher than or equal to 30% and lower than or equal to 100%, further preferably higher than or equal to 40% and lower than or equal to 100%, further preferably higher than or equal to 50% and lower than or equal to 100%, further preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure in the deposition chamber be as close to 100% as possible.

When the metal oxide film 114f is formed by a sputtering method in an oxygen-containing atmosphere in the above manner, oxygen can be supplied to the insulating layer 110 and release of oxygen from the insulating layer 110 can be prevented during the deposition of the metal oxide film 114f. As a result, an extremely large amount of oxygen can be enclosed in the insulating layer 110.

After the deposition of the metal oxide film 114f, heat treatment is preferably performed. By the heat treatment, oxygen contained in the insulating layer 110 can be supplied to the semiconductor layer 108 and the semiconductor layer 208. When the heat treatment is performed while the metal oxide film 114f covers the insulating layer 110, oxygen can be prevented from being released from the insulating layer 110 to the outside, and a large amount of oxygen can be supplied to the semiconductor layer 108 and the semiconductor layer 208. Thus, the amounts of oxygen vacancies in the semiconductor layer 108 and the semiconductor layer 208 can be reduced, leading to a highly reliable transistor.

The above description can be referred to for the heat treatment; thus, the detailed description thereof is omitted.

Note that the heat treatment is not necessarily performed. The heat treatment is not performed in this step, and instead heat treatment performed in a later step may also serve as the heat treatment in this step. In some cases, treatment at a high temperature (e.g., deposition step) or the like in a later step can serve as the heat treatment in this step.

After the deposition of the metal oxide film 114f or the heat treatment, the metal oxide film 114f may be removed.

### [Formation of Opening Portion 142 and Opening Portion 242]

Next, the metal oxide film 114f, the insulating layer 110, the insulating layer 117, and the insulating layer 103 are partly etched to form the opening portion 142 and the opening portion 242 reaching the conductive layer 106 or the conductive layer 206 (FIG. 30C). Accordingly, the conductive layer 112 to be formed later can be electrically connected to the conductive layer 106 through the opening portion 142. The conductive layer 212 to be formed later can be electrically connected to the conductive layer 206 through the opening portion 142.

### [Formation of Conductive Layer 112, Conductive Layer 212, Metal Oxide Layer 114, and Metal Oxide Layer 214]

Next, the conductive film 112f to be the conductive layer 112 and the conductive layer 212 is deposited over the metal oxide film 114f

A low-resistance metal or alloy material is preferably used for the conductive film 112f It is preferable that a material from which hydrogen is less likely to be released and in which hydrogen is less likely to be diffused is used for the conductive film 112f. Furthermore, a material that is less likely to be oxidized is preferably used for the conductive film 112f.

For example, the conductive film 112f is preferably deposited by a sputtering method using a sputtering target containing a metal or an alloy.

For example, the conductive film 112f is preferably a stacked-layer film including a low-resistance conductive film and a conductive film that is less likely to be oxidized and in which hydrogen is less likely to be diffused.

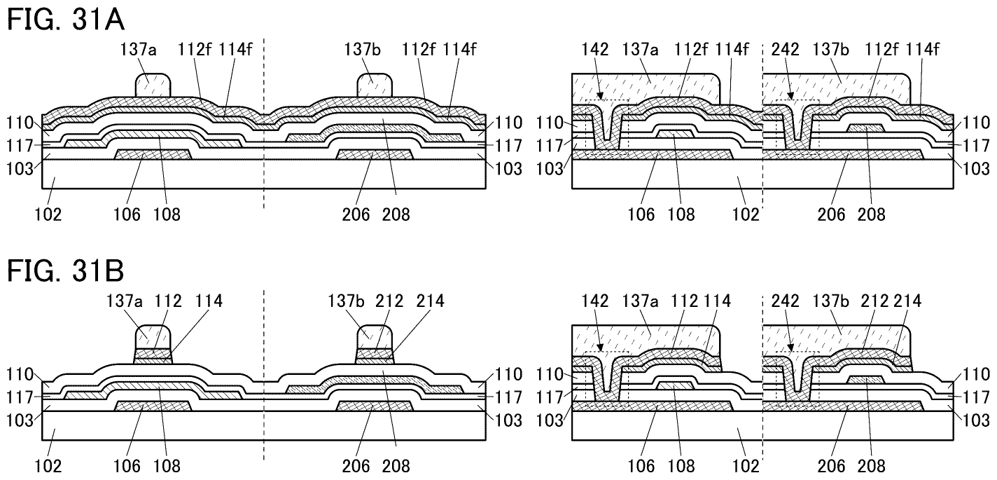

Next, the resist mask 137a and the resist mask 137b are formed over the conductive film 112f (FIG. 31A).

Next, the conductive film 112f and the metal oxide film 114f in a region not covered with the resist mask 137a and a region not covered with the resist mask 137b are removed, whereby the conductive layer 112, the conductive layer 212, the metal oxide layer 114, and the metal oxide layer 214 are formed (FIG. 31B). A wet etching method can be suitably used for etching the conductive film 112f and the metal oxide film 114f.

In such a manner, it is possible to form the conductive layer 112 and the metal oxide layer 114 which have top surface shapes aligned or substantially aligned with each other, and the conductive layer 212 and the metal oxide layer 214 which have top surface shapes aligned or substantially aligned with each other.

As described above, the insulating layer 110 is not etched and covers the top surface and the side surface of the semiconductor layer 208 and the insulating layer 117, which prevents the semiconductor layer 208 and the insulating layer 117 from being partly etched and thinned in etching the conductive film 112f or the like.

After that, the resist mask 137a and the resist mask 137b are removed.

Next, treatment for supplying an impurity element to the semiconductor layer 108 and the semiconductor layer 208 is performed. Steps subsequent to the supply of an impurity element can be performed in a way similar to those of Manufacturing method example 1.

The above is the description of Manufacturing method example 4.

At least part of this embodiment can be implemented in combination with the other embodiments described in this specification as appropriate.

### Embodiment 2

In this embodiment, a structure example of a display device that can include the semiconductor device described in Embodiment 1 will be described.

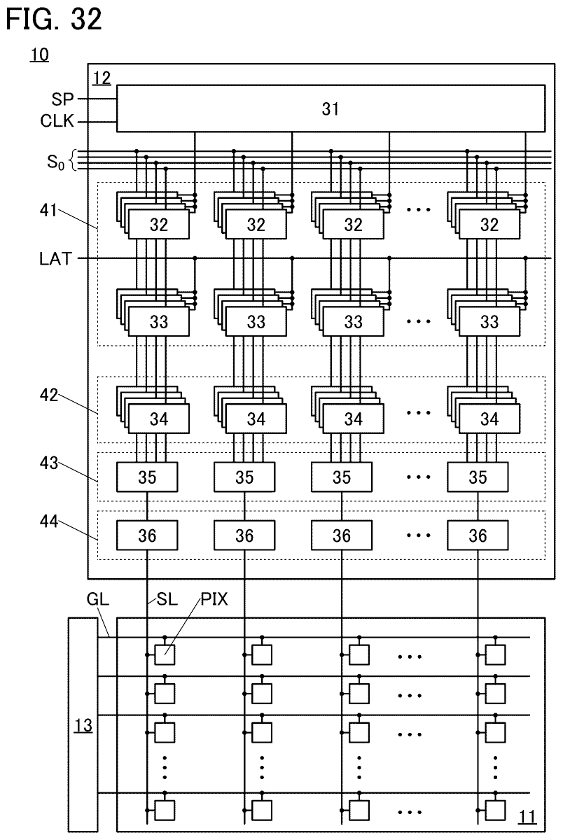

FIG. 32 illustrates a block diagram of a display device 10. The display device 10 includes a display portion 11, a first driver circuit 12 and a second driver circuit 13.

In the display portion 11, a plurality of pixels PIX are arranged in a matrix. Each of the pixels include at least a display element and a transistor. An organic EL element, a liquid crystal element, or the like can be typically used as the display element.

The first driver circuit 12 includes a circuit functioning as a source driver. The first driver circuit 12 has a function of generating a gray level signal based on a video signal input from the outside and supplying the signal to a pixel included in the display portion 11.

The second driver circuit 13 includes a circuit functioning as a gate driver. The second driver circuit 13 has a function of generating a selection signal based on a signal input from the outside and supplying the signal to a pixel included in the display portion 11.

The transistor 100 and the like exemplified in Embodiment 1 can be applied to the pixel PIX in the display portion 11 and the second driver circuit 13. The transistor 200 and the like exemplified in Embodiment 1 can be applied to the first driver circuit 12. Note that as needed, the transistor 200 and the like can be used in the pixel PIX and the second driver circuit 13 and the transistor 100 can be used in the first driver circuit 12.

The display portion 11 includes a plurality of source lines SL connected to the first driver circuit 12 and a plurality of gate lines GL connected to the second driver circuit 13.

### <Structure Example of First Driver Circuit>

A more specific cross-sectional structure example of the first driver circuit 12 included in the display device 10 is described below.

The first driver circuit 12 includes a shift register circuit 31, a latch circuit portion 41, a level shifter circuit portion 42, a D/A converter portion 43, an analog buffer circuit portion 44, and the like.

The latch circuit portion 41 includes a plurality of latch circuits 32 and a plurality of latch circuits 33. The level shifter circuit portion 42 includes a plurality of level shifter circuits 34. The D/A converter portion 43 includes a plurality of DAC circuits 35. The analog buffer circuit portion 44 includes a plurality of analog buffer circuits 36.

A clock signal CLK and a start pulse signal SP are input to the shift register circuit 31. The shift register circuit 31 generates a timing signal whose pulse sequentially shifts in accordance with the clock signal CLK and the start pulse signal SP, and outputs the timing signal to each of the latch circuits 32 in the latch circuit portion 41.

A video signal S₀ and a latch signal LAT are input to the latch circuit portion 41.

When timing signals are input to the latch circuits 32, the video signals S₀ are sampled in response to pulse signals included in the timing signals and sequentially written to the latch circuits 32. A period until writing of the video signals S₀ to all of the latch circuits 32 is completed can be referred to as a line period.

When one line period is completed, the video signals held in the latch circuits 32 are written to the latch circuits 33 all at once and held in accordance with a pulse of the latch signal LAT input to each of the latch circuits 33. To the latch circuits 32 that have finished sending the video signals to the latch circuits 33, the next video signals are sequentially written again in accordance with timing signals from the shift register circuit 31. In this second line period, the video signals that have been written to and held in the latch circuits 33 are output to the level shifter circuits 34 in the level shifter circuit portion 42.

When the video signals are input to the level shifter circuits 34 in the level shifter circuit portion 42, the voltage amplitudes of the signals are amplified by the level shifter circuits 34, and then sent to the DAC circuits 35 in the D/A converter portion 43. A group of video signals input to each of the DAC circuits 35 are converted into an analog signal, which is output to the analog buffer circuit portion 44. The video signal input to the analog buffer circuit portion 44 is output to each of the source line SL through each of the analog buffer circuits 36.

The second driver circuit 13 selects the gate lines GL sequentially. The video signal input from the first driver circuit 12 to the display portion 11 through the source line SL is input to each of the pixels PIX connected to the gate line GL selected by the second driver circuit 13.

Note that another circuit that can output a signal whose pulse sequentially shifts may be used instead of the shift register circuit 31.

### <Variation Example of First Driver Circuit>

The first driver circuit 12 illustrated in FIG. 32 has a structure in which a digital signal is converted into an analog signal to be output to the display portion 11; the use of an analog signal as an input signal further simplifies the structure of the first driver circuit 12.

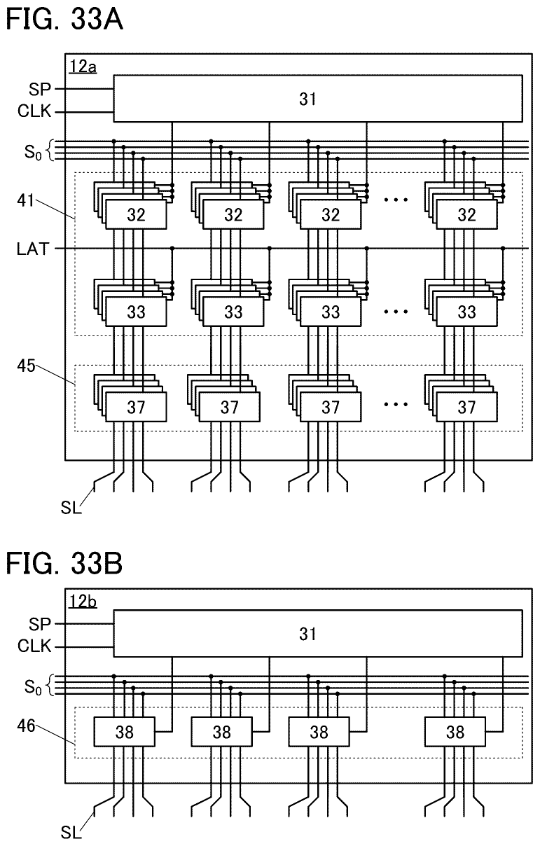

A first driver circuit 12a illustrated in FIG. 33A includes the shift register circuit 31, the latch circuit portion 41, and a source follower circuit portion 45. The source follower circuit portion 45 includes a plurality of source follower circuits 37.

In the latch circuits 32, analog video signals S₀ are sampled as analog data in response to timing signals from the shift register circuit 31. The latch circuits 32 output video signals held in the latch circuits 33 all at once in accordance with the latch signal LAT.

The video signals held in the latch circuits 33 are output to one of the source lines SL through the source follower circuit 37. Note that the aforementioned analog buffer circuit may be used instead of the source follower circuit 37.

The first driver circuit 12b illustrated in FIG. 33B includes the shift register circuit 31 and a demultiplexer circuit 46.

The demultiplexer circuit 46 includes a plurality of sampling circuits 38. Each sampling circuit 38 receives a plurality of analog video signals S₀ from a plurality of wirings and outputs video signals to a plurality of source lines SL at a time in response to a timing signal input from the shift register circuit 31. The shift register circuit 31 outputs timing signals so as to sequentially select a plurality of sampling circuits 38.

For example, in the case where 2160 source lines SL are connected to the display portion 11 and video signals S₀ are supplied from 54 wirings, 40 sampling circuits 38 are provided in the demultiplexer circuit 46, so that one line period can be divided into 40 periods and video signals can be output to 54 source lines SL at a time in each period.

The above is the description of the first driver circuit.

### <Structure Example of Display Portion>

The display portion 11 can have a structure in which a plurality of pixels PIX each including at least one display element and one transistor are arranged in a matrix.

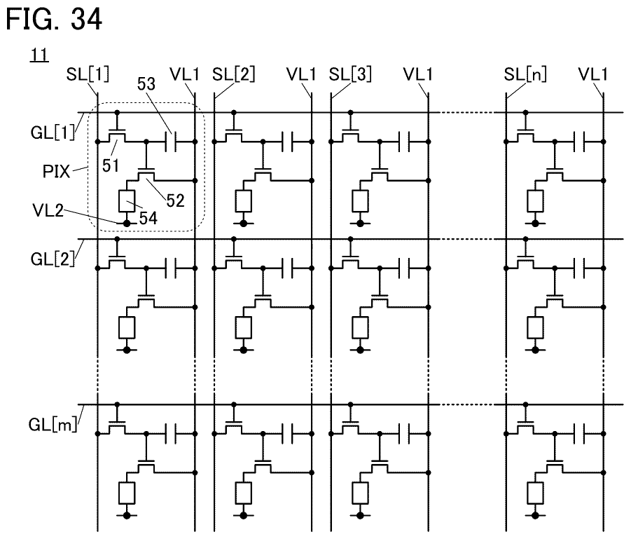

FIG. 34 illustrates an example of a circuit diagram of the display portion 11 where a light-emitting device is used as the display element. As illustrated in FIG. 34, the display portion 11 have a structure where m (m is an integer greater than or equal to 2) gate lines GL (gate line GL[1] to gate line GL[m]) and n (n is an integer greater than or equal to 2) source lines SL (source line SL[1] to source line SL[n]) are electrically connected.

The pixels PIX in the display portion 11 each include a transistor 51, a transistor 52, a capacitor 53, and a light-emitting device 54. The pixels PIX are each connected to the source line SL, the gate line GL, and a wiring VL1 and a wiring VL2 that are supplied with a power source potential.

As the transistor 51 and the transistor 52, the transistor 100 and the like exemplified in Embodiment 1 can be used. Note that the transistor 200 or the like exemplified in Embodiment 1 can be used as one of the transistor 51 and the transistor 52 as needed.

A gate of the transistor 51 is connected to the gate line GL, one of a source and a drain of the transistor 51 is connected to the source line SL, and the other thereof is connected to one electrode of the capacitor 53 and a gate of the transistor 52. One of a source and a drain of the transistor 52 is connected to one electrode of the light-emitting device 54 and the other thereof is connected to the wiring VL1. The other electrode of the capacitor 53 is connected to the wiring VL1. The other electrode of the light-emitting element 54 is connected to the wiring VL2.

The pixel PIX is selected by a signal supplied from the gate line GL. A potential is written from the source line SL through the transistor 51 to a node to which the gate of the transistor 52 is connected, and the potential controls current flowing through the light-emitting device 54, thereby controlling the emission luminance of the light-emitting device 54.

As the light-emitting device 54, an EL device such as an OLED (Organic Light Emitting Diode) and a QLED (Quantum-dot Light Emitting Diode) is preferably used. Examples of a light-emitting substance contained in the EL device include a substance exhibiting fluorescence (a fluorescent material), a substance exhibiting phosphorescence (a phosphorescent material), an inorganic compound (e.g., a quantum dot material), and a substance exhibiting thermally activated delayed fluorescence (a thermally activated delayed fluorescence (TADF) material). Note that as a TADF material, a material that is in a thermal equilibrium state between a singlet excited state and a triplet excited state may be used. Since such a TADF material enables a short emission lifetime (excitation lifetime), an efficiency decrease of a light-emitting device in a high-luminance region can be inhibited. Note that the light-emitting device 54 is not limited thereto and may be an inorganic EL element containing an inorganic material, a light-emitting diode, or the like. In addition, an LED (Light Emitting Diode) such as a micro-LED can also be used as the light-emitting device.

Note that the pixel PIX in the display portion 11 may include transistors whose semiconductor layers are different in their compositions. For example, the semiconductor layer of the transistor 51 may have a composition different from that of the semiconductor layer of the transistor 52. In addition, transistors included in the pixel PIX can be formed to have different thicknesses of gate insulating layers.

Since a positive potential is supplied to a gate, as the transistor 52 functioning as a driver transistor controlling the amount of current flowing in the light-emitting device 54, it is preferable to use a transistor with a smaller amount of change in threshold voltage in a PBTS test, as compared to the transistor 51 functioning as a selection transistor for controlling a selection state in the pixel PIX. Meanwhile, as the transistor 51, it is preferable to use a transistor with a small amount of change in threshold voltage in a NBTIS test. A metal oxide not containing gallium or low content of gallium is preferably used for the semiconductor layer of the transistor 52. The semiconductor layer of the transistor 51 is preferably formed using a metal oxide containing lower content of gallium than that of the transistor 52. A display device with such a structure can have high reliability.

The above is the description of the structure example of the display portion.

Note that the transistors included in the first driver circuit 12 may be formed to have semiconductor layers with different compositions. The transistors included in the second driver circuit 13 may be formed to have semiconductor layers with different compositions. The transistors are formed to have structures achieving required electrical characteristics and reliability, which enables a display device to have both good electrical characteristics and high reliability.

At least part of this embodiment can be implemented in combination with the other embodiments described in this specification as appropriate.

### Embodiment 3

More specific structure examples of the display device will be described below.

Here, in the case where the pixel of the display device includes three kinds of subpixels exhibiting light of different colors, for example, as the three subpixels, subpixels of three colors of red (R), green (G), and blue (B), subpixels of three colors of yellow (Y), cyan (C), and magenta (M), and the like can be given. In the case where four subpixels are included, the four subpixels can be of four colors of red (R), green (G), blue (B), and white (W) or of four colors of R, G, B, and Y, for example. Each of the subpixels includes a light-emitting device.

Pixel layouts in the display device will be described below. There is no particular limitation on the arrangement of subpixels in the pixel, and a variety of methods can be employed. Examples of the arrangement of subpixels include stripe arrangement, S stripe arrangement, matrix arrangement, delta arrangement, Bayer arrangement, and PenTile arrangement.

Examples of a top surface shape of the subpixel include polygons such as a triangle, a tetragon (including a rectangle and a square), a pentagon, and a hexagon; polygons with rounded corners; an ellipse; and a circle. Here, a top surface shape of the subpixel corresponds to a top surface shape of a light-emitting region of the light-emitting device.

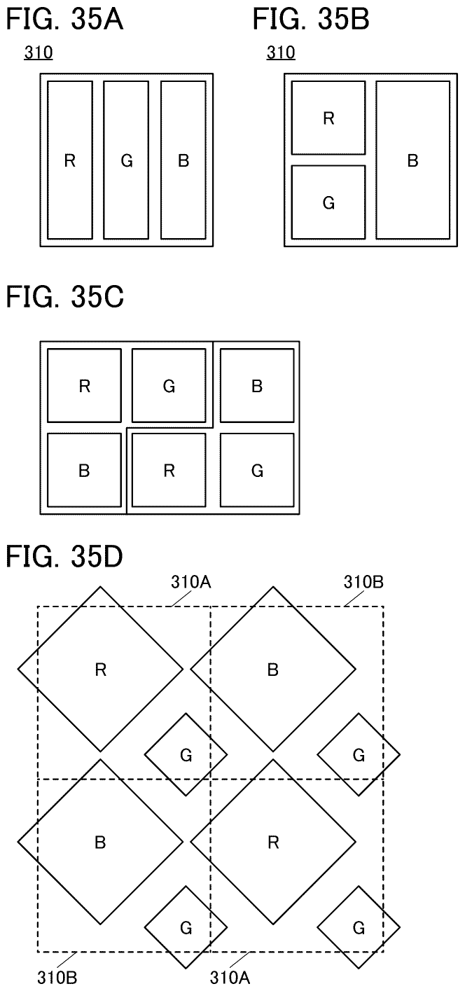

A pixel 310 illustrated in FIG. 35A includes a subpixel (R) exhibiting a red color, a subpixel (G) exhibiting a green color, and a subpixel (B) exhibiting a blue color. The pixel 310 illustrated in FIG. 35A employs the stripe arrangement. Note that the arrangement order of the subpixels is not limited to the structure illustrated in FIG. 35A. Although the subpixels in FIG. 35A have the same area as each other, the area may be different between the subpixels. Here, the area of the subpixel corresponds to the area of a light-emitting region of the light-emitting device. In FIG. 35A, regions of the light-emitting elements in the subpixels are denoted by R, G, and B to easily differentiate the subpixels.

The pixel 310 illustrated in FIG. 35B employs the S-stripe arrangement. The pixel 310 illustrated in FIG. 35B is composed of two rows and two columns, and includes two subpixels (the subpixel (R) and the subpixel (G)) in the left column (first column) and one subpixel (the subpixel (B)) in the right column (second column). In other words, the pixel 310 includes two subpixels (the subpixel (R) and the subpixel (B)) in the upper row (first row) and two subpixels (the subpixel (G) and the subpixel (B)) in the lower row (second row); the subpixel (B) is provided to extend in the two rows.

FIG. 35B shows an example where the area of the subpixel (B) is larger than those of the subpixel (R) and the subpixel (G). This structure can be suitably used in the case where the lifetime of the light-emitting device emitting blue light is shorter than the lifetimes of the light-emitting device emitting red light and the light-emitting device emitting blue light. In the subpixel (B) having a large light-emitting area, the current density of the light-emitting device emitting blue light is low, enabling longer lifetimes of the light-emitting device. That is, the display device can have high reliability.

Note that although the area of the subpixel (B) is larger than the areas of the subpixel (R) and the subpixel (G) in FIG. 35B, one embodiment of the present invention is not limited to this structure. The area of the subpixel can be determined in accordance with the lifetime of the light-emitting device included in the subpixel. The area of the light-emitting device with a short lifetime is preferably made larger than the areas of the other subpixels.

FIG. 35C illustrates two pixels. The pixels illustrated in FIG. 35C includes subpixels of different colors that are arranged in a zigzag manner. Specifically, in every column, the subpixels of different colors are arranged in an odd-numbered row and an even-numbered row.

FIG. 35D illustrates pixels employing the PenTile arrangement. In FIG. 35D, two pixels, a pixel 310A and a pixel 310B, include three kinds of subpixels of a subpixel (R) exhibiting a red color, a subpixel (G) exhibiting a green color, and a subpixel (B) exhibiting a blue color. The two pixels of the pixel 310A and the pixel 310B are composed of one subpixel (R), two subpixels (G), and one subpixel (B). Such a structure can increase the areas of the subpixels while maintaining a pseudo-high resolution, thereby lowering the required processing accuracy. That is, by comparison of display devices with the same processing accuracy, the above structure enables a display device to have a higher resolution. In addition, the number of transistors per area can be reduced, whereby the productivity can be increased. Accordingly, a display device having a pseudo-high resolution can be fabricated with high productivity.

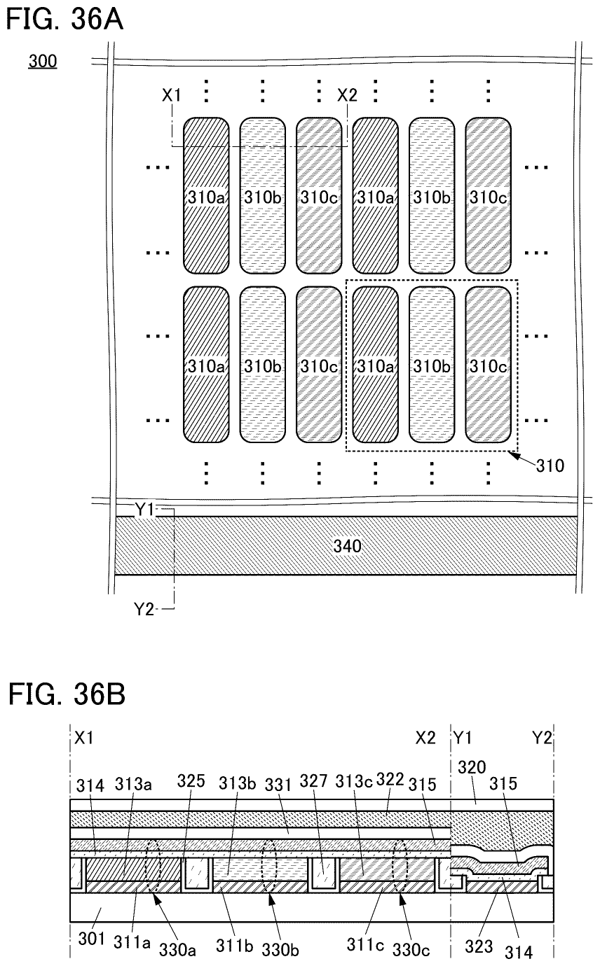

FIG. 36A and FIG. 36B illustrate a display device of one embodiment of the present invention.

FIG. 36A is a top view of a display device 300. The display device 300 includes a display portion where a plurality of pixels 310 are arranged in a matrix, and a connection portion 340 outside the display portion. One pixel 310 consists of three subpixels, a subpixel 310a, a subpixel 310b, and a subpixel 310c. Note that the structure of the pixel is not limited to that illustrated in FIG. 36A.

Although FIG. 36A illustrates an example in which the connection portion 340 is positioned on the lower side of the display portion in a top view, one embodiment of the present invention is not particularly limited. The connection portion 340 is provided in at least one of the upper side, the right side, the left side, and the lower side of the display portion in the top view, or may be provided so as to surround the four sides of the display portion. The number of connection portions 340 can be one or more.

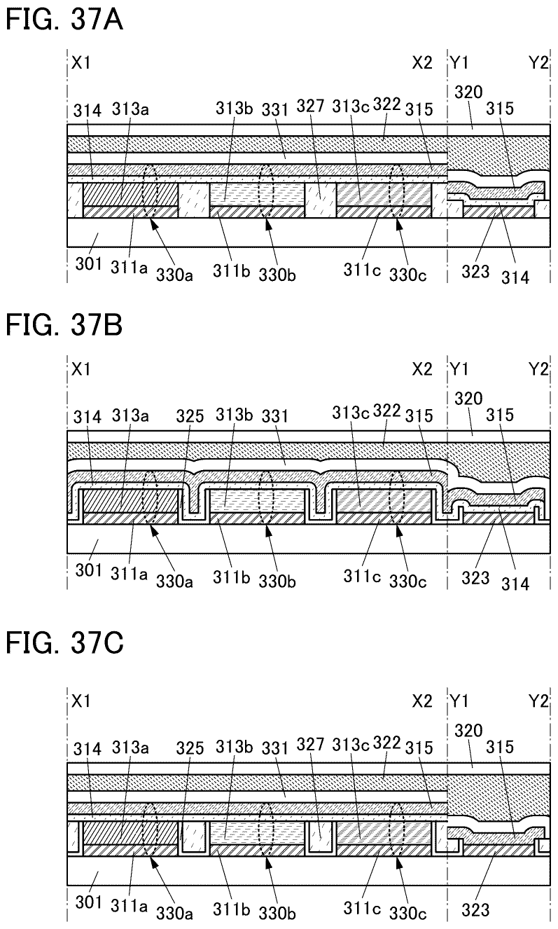

FIG. 36B is a cross-sectional view taken along the dashed-dotted lines X1-X2 and Y1-Y2 in FIG. 36A. Moreover, FIGS. 37A to 37C, FIGS. 38A and 38B, and FIGS. 39A to 39C show variation examples of the cross-sectional view taken along dashed-dotted lines X1-X2 and Y1-Y2 in FIG. 36A.

As illustrated in FIG. 36B, in the display device 300, light-emitting devices 330a, 330b, and 330c are provided over a layer 301 including transistors and a protective layer 331 is provided to cover these light-emitting devices. A substrate 320 is bonded to the protective layer 331 with a resin layer 322. In a region between two adjacent light-emitting devices, an insulating layer 325 and an insulating layer 327 over the insulating layer 325 are provided.

The display device of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The layer 301 including transistors can employ a stacked-layer structure in which a plurality of transistors are provided over a substrate and an insulating layer is provided to cover these transistors, for example. The layer 301 including transistors may have a recessed portion between two adjacent light-emitting devices. For example, an insulating layer positioned on the outermost surface of the layer 301 including transistors may have a recessed portion. As the transistors, the transistor described in Embodiment 1 can be used.

The light-emitting device includes an EL layer between a pair of electrodes. In this specification and the like, one of the pair of electrodes may be referred to as a pixel electrode and the other may be referred to as a common electrode.

One of the pair of electrodes of the light-emitting device functions as an anode, and the other electrode functions as a cathode. The case where the pixel electrode functions as an anode and the common electrode functions as a cathode is described below as an example.

The light-emitting device 330a includes a conductive layer 311a over the layer 301 including transistors, an island-shaped first layer 313a over the conductive layer 311a, a fourth layer 314 over the island-shaped first layer 313a, and a common electrode 315 over the fourth layer 314. The conductive layer 311a functions as a pixel electrode. In the light-emitting device 330a, the first layer 313a and the fourth layer 314 can be collectively referred to as an EL layer.

The first layer 313a includes a hole-injection layer, a hole-transport layer, a light-emitting layer, and an electron-transport layer, for example. Alternatively, the first layer 313a includes a first light-emitting unit, a charge generation layer, and a second light-emitting unit.

The fourth layer 314 includes an electron-injection layer, for example. Alternatively, the fourth layer 314 may include a stack of an electron-transport layer and an electron-injection layer.

The light-emitting device 330b includes a conductive layer 311b over the layer 301 including transistors, an island-shaped second layer 313b over the conductive layer 311b, the fourth layer 314 over the island-shaped second layer 313b, and the common electrode 315 over the fourth layer 314. The conductive layer 311b functions as a pixel electrode. In the light-emitting device 330b, the second layer 313b and the fourth layer 314 can be collectively referred to as an EL layer.

The light-emitting device 330c includes a conductive layer 311c over the layer 301 including transistors, an island-shaped third layer 313c over the conductive layer 311c, the fourth layer 314 over the island-shaped third layer 313c, and the common electrode 315 over the fourth layer 314. The conductive layer 311c functions as a pixel electrode. In the light-emitting device 330c, the third layer 313c and the fourth layer 314 can be collectively referred to as an EL layer.

The fourth layer 314 is a layer shared by the light-emitting devices. The fourth layer 314 includes, for example, the electron-injection layer, as described above. Alternatively, the fourth layer 314 may include a stack of an electron-transport layer and an electron-injection layer.

The common electrode 315 is electrically connected to a conductive layer 323 provided in the connection portion 340. Thus, the same potential is supplied to the common electrode 315 included in the light-emitting devices of the respective colors. Note that FIG. 36B illustrates an example in which the fourth layer 314 is provided over the conductive layer 323 and the conductive layer 323 and the common electrode 315 are electrically connected to each other through the fourth layer 314. The fourth layer 314 is not necessarily provided in the connection portion 340. For example, FIG. 37C illustrates an example in which the fourth layer 314 is not provided over the conductive layer 323 and the conductive layer 323 and the common electrode 315 are directly connected to each other.

For example, by using a mask for specifying a deposition area (also referred to as an area mask or a rough metal mask), the fourth layer 314 can be formed in a region different from a region where the common electrode 315 is formed.

Side surfaces of the conductive layer 311a to the conductive layer 311c, the first layer 313a, the second layer 313b, and the third layer 313c are covered with the insulating layer 325 and the insulating layer 327. This inhibits the fourth layer 314 (or the common electrode 315) from being in contact with the side surface of any of the conductive layer 311a to the conductive layer 311c, the first layer 313a, the second layer 313b, and the third layer 313c, thereby inhibiting a short circuit in the light-emitting devices. Thus, the reliability of the light-emitting device can be increased.

The insulating layer 325 preferably covers at least the side surfaces of the conductive layer 311a to the conductive layer 311c. Moreover, the insulating layer 325 preferably covers the side surfaces of the first layer 313a, the second layer 313b, and the third layer 313c. The insulating layer 325 can be in contact with the side surfaces of the conductive layer 311a to the conductive layer 311c, the first layer 313a, the second layer 313b, and the third layer 313c.

The insulating layer 327 is provided over the insulating layer 325 to fill a recessed portion formed in the insulating layer 325. The insulating layer 327 can overlap with the side surfaces of the conductive layer 311a to the conductive layer 311c, the first layer 313a, the second layer 313b, and the third layer 313c with the insulating layer 325 therebetween.

Moreover, providing the insulating layer 325 and the insulating layer 327 can fill the space between the adjacent island-shaped layers; hence, the formation surface of a layer (e.g., the common electrode) provided over the island-shaped layer has less unevenness and can be flatter. Thus, the coverage with the common electrode can be increased, which can prevent the disconnection of the common electrode.

The insulating layer 325 and the insulating layer 327 can be provided in contact with the island-shaped layer. Thus, peeling of the island-shaped layer can be prevented. Close contact between the insulating layer and the island-shaped layer brings about the effect of fixing or bonding the adjacent island-shaped layer to each other by the insulating layer.

An organic resin film is suitable as the insulating layer 327. In the case where the side surface of the EL layer and the photosensitive organic resin film are in direct contact with each other, the EL layer might be damaged by an organic solvent or the like that might be contained in the photosensitive organic resin film. When an aluminum oxide film formed by an atomic layer deposition (ALD) method is used as the insulating layer 325, a structure can be employed in which the photosensitive organic resin film used as the insulating layer 327 and the side surface of the EL layer are not in direct contact with each other. Thus, the EL layer can be inhibited from being dissolved by the organic solvent, for example.

Note that one of the insulating layer 325 and the insulating layer 327 is not necessarily provided. For example, the insulating layer 325 is formed to have a single-layer structure using an inorganic material, which can be used as a protective insulating layer for the EL layer. This increases the reliability of the display device. As another example, by forming an insulating layer having a single-layer structure using an organic material as the insulating layer 327, a space between adjacent EL layers can be filled with the insulating layer 327 so that higher planarity is achieved. This increases the coverage of the EL layer and the insulating layer 327 with the common electrode (upper electrode) formed thereover.

The fourth layer 314 and the common electrode 315 are provided over the first layer 313a, the second layer 313b, the third layer 313c, the insulating layer 325, and the insulating layer 327. Before the insulating layer 325 and the insulating layer 327 are provided, there is a step due to a region where the pixel electrode and the EL layer are provided and a region where neither the pixel electrode nor the EL layer is provided (a region between the light-emitting devices). In the display device of one embodiment of the present invention, the presence of the insulating layer 325 and the insulating layer 327 enables planarization at the step, and the coverage with the fourth layer 314 and the common electrode 315 can be improved. Consequently, it is possible to inhibit a connection defect due to disconnection. Alternatively, it is possible to inhibit an increase in electric resistance due to local thinning of the common electrode 315 by the level difference.

In order to improve the planarity of the formation surfaces of the fourth layer 314 and the common electrode 315, the level of the top surface of the insulating layer 325 and the level of the top surface of the insulating layer 327 are each preferably the same or substantially the same as the level of the top surface of at least one of the first layer 313a, the second layer 313b, and the third layer 313c. The top surface of the insulating layer 327 preferably has a flat shape and may have a protruding portion, a convex surface, a concave surface, or a recessed portion.

The insulating layer 325 includes regions in contact with the side surfaces of the first layer 313a, the second layer 313b, and the third layer 313c and functions as a protective insulating layer for the first layer 313a, the second layer 313b, and the third layer 313c. Providing the insulating layer 325 can inhibit impurities (e.g., oxygen and moisture) from entering the first layer 313a, the second layer 313b, and the third layer 313c through their side surfaces, resulting in a highly reliable display device.

When the width (thickness) of the insulating layer 325 in the regions in contact with the side surfaces of the first layer 313a, the second layer 313b, and the third layer 313c is large in the cross-sectional view, the intervals between the first layer 313a, the second layer 313b, and the third layer 313c increase, so that the aperture ratio may be reduced. When the width (thickness) of the insulating layer 325 is small, the effect of inhibiting impurities from entering the first layer 313a, the second layer 313b, and the third layer 313c through their side surfaces may be weakened. The width (thickness) of the insulating layer 325 in the regions in contact with the side surfaces of the first layer 313a, the second layer 313b, and the third layer 313c is preferably greater than or equal to 3 nm and less than or equal to 200 nm, further preferably greater than or equal to 3 nm and less than or equal to 150 nm, further preferably greater than or equal to 5 nm and less than or equal to 150 nm, still further preferably greater than or equal to 5 nm and less than or equal to 100 nm, still further preferably greater than or equal to 10 nm and less than or equal to 100 nm, yet further preferably greater than or equal to 10 nm and less than or equal to 50 nm. When the width (thickness) of the insulating layer 325 is within the above range, the display device can have both a high aperture ratio and high reliability.

The insulating layer 325 can be an insulating layer containing an inorganic material. As the insulating layer 325, an inorganic insulating film such as an oxide insulating film, a nitride insulating film, an oxynitride insulating film, or a nitride oxide insulating film can be used, for example. The insulating layer 325 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferable because it has high selectivity with respect to the EL layer in etching and has a function of protecting the EL layer in forming the insulating layer 327 described later. Specifically, when an inorganic insulating film such as an aluminum oxide film, a hafnium oxide film, or a silicon oxide film formed by an ALD method is used for the insulating layer 325, the insulating layer 325 formed can have a small number of pin holes and excel in a function of protecting the EL layer. The insulating layer 325 may have a stacked-layer structure of a film formed by an ALD method and a film formed by a sputtering method. As the insulating layer 325, a stacked-layer structure of an aluminum oxide film formed by an ALD method and a silicon nitride film formed by a sputtering method may be used.

The insulating layer 325 can be formed by a sputtering method, a chemical vapor deposition (CVD) method, a pulsed laser deposition (PLD) method, or an ALD method. The insulating layer 325 is preferably formed by an ALD method achieving good coverage.

The insulating layer 327 provided over the insulating layer 325 has a function of filling a recessed portion of the insulating layer 325, which is formed between the adjacent light-emitting devices. In other words, the insulating layer 327 has an effect of improving the planarity of the formation surface of the common electrode 315. An insulating layer containing an organic material can be suitably used as the insulating layer 327. For the insulating layer 327, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the insulating layer 327, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. Moreover, a photosensitive resin can be used for the insulating layer 327. A photoresist may be used for the photosensitive resin. As the photosensitive resin, a positive photosensitive material or a negative photosensitive material can be used.

The difference between the level of the top surface of the insulating layer 327 and the level of the top surface of any of the first layer 313a, the second layer 313b, and the third layer 313c is preferably less than or equal to 0.5 times, further preferably less than or equal to 0.3 times the thickness of the insulating layer 327, for example. As another example, the insulating layer 327 may be provided so that the level of the top surface of any of the first layer 313a, the second layer 313b, and the third layer 313c is higher than the level of the top surface of the insulating layer 327. As another example, the insulating layer 327 may be provided so that the level of the top surface of the insulating layer 327 is higher than the level of the top surface of the light-emitting layer included in the first layer 313a, the second layer 313b, or the third layer 313c.

FIG. 37A illustrates an example in which the insulating layer 325 is not provided. For example, in the case where the insulating layer 325 is not provided, the insulating layer 327 can be in contact with the side surfaces of the conductive layer 311a to the conductive layer 311c, the first layer 313a, the second layer 313b, and the third layer 313c. The insulating layer 327 can be provided to fill spaces between the EL layers of the light-emitting devices.

In that case, the insulating layer 327 is preferably formed using an organic material that causes less damage to the first layer 313a, the second layer 313b, and the third layer 313c. For example, for the insulating layer 327, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin is preferably used.

FIG. 37B illustrates an example in which the insulating layer 327 is not provided.

The protective layer 331 is preferably provided over the light-emitting devices 330a, 330b, and 330c. Providing the protective layer 331 can improve the reliability of the light-emitting devices.

There is no limitation on the conductivity of the protective layer 331. For the protective layer 331, at least one of an insulating film, a semiconductor film, and a conductive film can be used.

The protective layer 331 including an inorganic film can inhibit deterioration of the light-emitting devices by preventing oxidation of the common electrode 315 and inhibiting entry of impurities (e.g., moisture and oxygen) into the light-emitting devices 330a, 330b, and 330c, for example; thus, the reliability of the display device can be improved.

For the protective layer 331, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

The protective layer 331 preferably includes a nitride insulating film or a nitride oxide insulating film, and further preferably includes a nitride insulating film.

As the protective layer 331, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 315. The inorganic film may further contain nitrogen.

When light emitted from the light-emitting device is extracted through the protective layer 331, the protective layer 331 preferably has a high visible-light-transmitting property. For example, ITO, IGZO, and aluminum oxide are preferable because they are inorganic materials having a high visible-light-transmitting property.

The protective layer 331 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 331 may include an organic film. For example, the protective layer 331 may include both an organic film and an inorganic film.

The end portions of the top surfaces of the conductive layer 311a to the conductive layer 311c are not covered with an insulating layer. This allows the distance between adjacent light-emitting devices to be extremely narrowed. As a result, the display device can have high resolution or high definition.

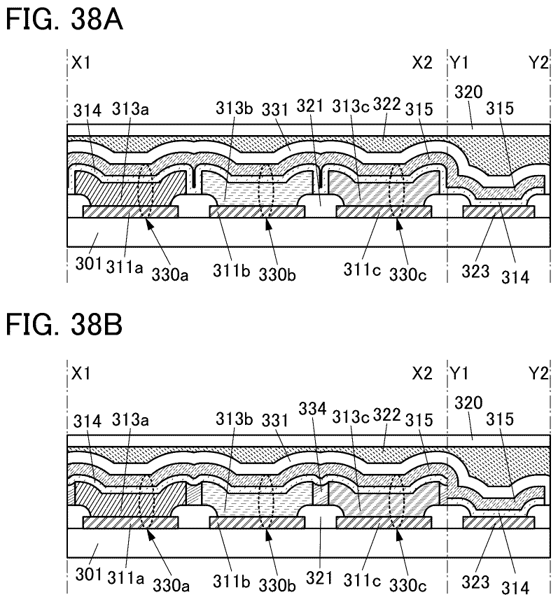

Note that as illustrated in FIG. 38A and FIG. 38B, the end portions of the conductive layer 311a to the conductive layer 311c may be covered with an insulating layer 321.

The insulating layer 321 can have a single-layer structure or a stacked-layer structure including one or both of an inorganic insulating film and an organic insulating film.

Examples of an organic insulating material that can be used for the insulating layer 321 include an acrylic resin, an epoxy resin, a polyimide resin, a polyamide resin, a polyimide-amide resin, a polysiloxane resin, a benzocyclobutene-based resin, and a phenol resin. As an inorganic insulating film that can be used as the insulating layer 321, an inorganic insulating film that can be used as the protective layer 331 can be used.

When an inorganic insulating film is used as the insulating layer 321 that covers the end portion of the pixel electrode, impurities are less likely to enter the light-emitting devices as compared with the case where an organic insulating film is used; therefore, the reliability of the light-emitting devices can be improved. When an organic insulating film is used as the insulating layer 321 that covers the end portion of the pixel electrode, high step coverage can be obtained as compared with the case where an inorganic insulating film is used; therefore, an influence of the shape of the pixel electrodes can be small. Therefore, a short circuit of the light-emitting device can be prevented. Specifically, when an organic insulating film is used as the insulating layer 321, the insulating layer 321 can be processed into a tapered shape or the like. In this specification and the like, a tapered shape indicates a shape in which at least part of the side surface of a structure is inclined to a substrate surface. For example, a region where the angle between the inclined side surface and the substrate surface (also referred to as a taper angle) is less than 90° is preferably included.

Note that the insulating layer 321 is not necessarily provided. The aperture ratio of the subpixel can sometimes be increased without providing the insulating layer 321. Alternatively, the distance between subpixels can be shortened and the resolution or the definition of the display device can sometimes be increased.

Note that FIG. 38A illustrates an example in which the fourth layer 314 is also formed in a region between the first layer 313a and the second layer 313b, for example; however, as illustrated in FIG. 38B, a space 334 may be formed in the region.

The space 334 includes, for example, any one or more selected from air, nitrogen, oxygen, carbon dioxide, and Group 18 elements (typically, helium, neon, argon, xenon, and krypton). Alternatively, a resin or the like may be embedded in the space 334.

FIG. 36A and the like illustrate an example in which the end portion of the conductive layer 311a and the end portion of the first layer 313a are aligned or substantially aligned with each other. In other words, the top surface shape of the conductive layer 311a and the top surface shape of the first layer 313a are the same or substantially the same.

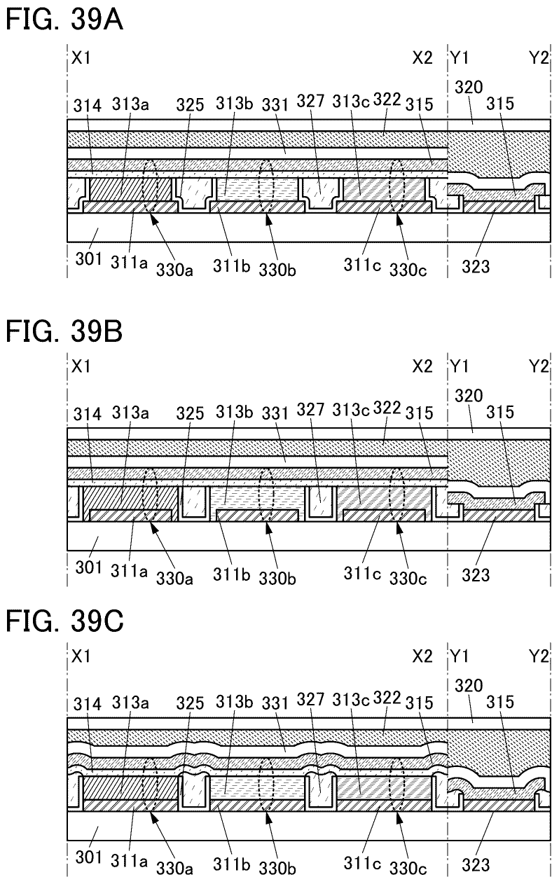

The size relationships between the conductive layer 311a and the first layer 313a, between the conductive layer 311b and the second layer 313b, between the conductive layer 311c and the third layer 313c, and the like are not particularly limited. FIG. 39A illustrates an example in which the end portion of the first layer 313a is positioned more inwardly than the end portion of the conductive layer 311a. In FIG. 39A, the end portion of the first layer 313a is positioned over the conductive layer 311a. FIG. 39B illustrates an example in which the end portion of the first layer 313a is positioned more outwardly than the end portion of the conductive layer 311a. In FIG. 39B, the first layer 313a is provided to cover the end portion of the conductive layer 311a.

In the case where end portions are aligned or substantially aligned with each other and the case where top surface shapes are the same or substantially the same, it can be said that outlines of stacked layers at least partly overlap with each other in a top view. For example, the case of processing the upper layer and the lower layer with use of the same mask pattern or mask patterns that are partly the same is included. However, in some cases, the outlines do not completely overlap with each other and the upper layer is positioned inward from the lower layer or the upper layer is positioned outward from the lower layer; such a case is also described with the expression “end portions are substantially aligned with each other” or “top surface shapes are substantially the same”.

FIG. 39C illustrates a variation example of the insulating layer 327. In the cross-sectional view of FIG. 39C, the top surface of the insulating layer 327 gently rises from its end portions toward the center, i.e., has convexities, and has a depression portion in the center and its vicinity, i.e., has a concavity.

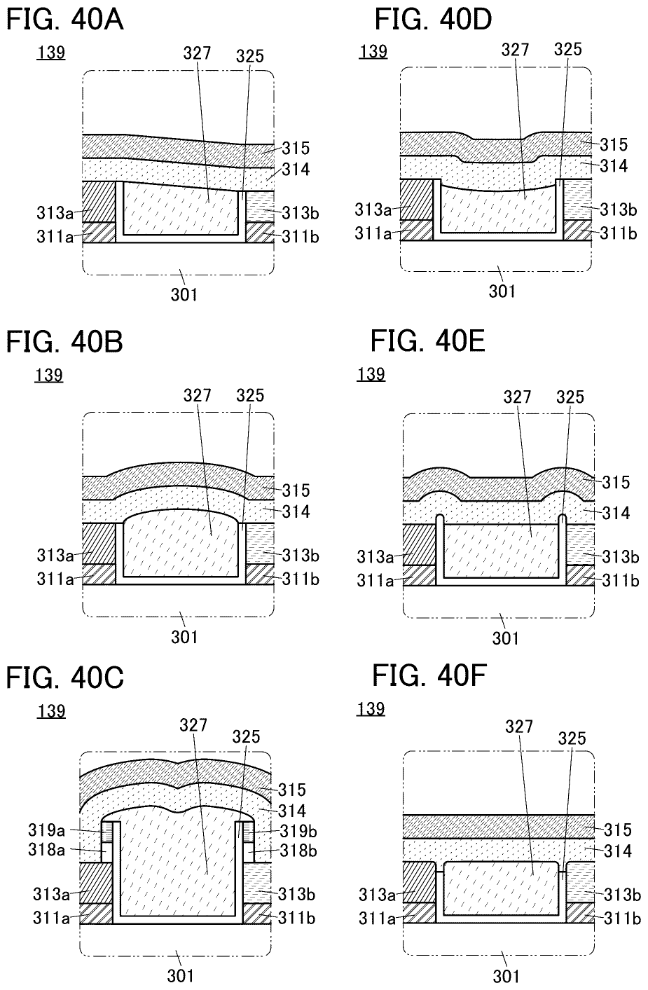

FIG. 40A to FIG. 40F each illustrate a cross-sectional structure of a region 139 including the insulating layer 327 and its surroundings.

FIG. 40A illustrates an example in which the first layer 313a and the second layer 313b have different thicknesses. The top surface level of the insulating layer 325 is aligned or substantially aligned with the top surface level of the first layer 313a on the first layer 313a side, and aligned with or substantially aligned with the top surface level of the second layer 313b on the second layer 313b side. The top surface of the insulating layer 327 has a gentle slope such that the side closer to the first layer 313a is higher and the side closer to the second layer 313b is lower. In this manner, the insulating layer 325 and the insulating layer 327 preferably level with the top surface of the adjacent EL layer. Alternatively, the insulating layer 325 and the insulating layer 327 may level with the top surface of any adjacent EL layer so that their top surfaces can have a flat portion.

In FIG. 40B, the top surface of the insulating layer 327 includes a region whose level is higher than the top surface level of the first layer 313a and the top surface level of the second layer 313b. As shown in FIG. 40B, the top surface of the insulating layer 327 can have a shape in which its center and the vicinity thereof bulge, i.e., a shape including a convex surface, in a cross-sectional view.

In the cross-sectional view of FIG. 40C, the top surface of the insulating layer 327 gently rises from its end portions toward the center, i.e., has convexities, and has a depression portion in the center and its vicinity, i.e., has a concavity. The insulating layer 327 includes a region whose level is higher than the top surface level of the first layer 313a and the top surface level of the second layer 313b. In the region 139, the display device includes at least one of a sacrificial layer 318a and a sacrificial layer 319a, and includes a first region where the insulating layer 327 is higher in level than the top surface of the first layer 313a and the top surface of the second layer 313b and positioned on the outer side of the insulating layer 325. The first region is positioned over at least one of the sacrificial layer 318a and the sacrificial layer 319a. In the region 139, the display device includes at least one of the sacrificial layer 318b and a sacrificial layer 319b, and includes a second region where the insulating layer 327 is higher in level than the top surface of the first layer 313a and the top surface of the second layer 313b and positioned on the outer side of the insulating layer 325. The second region is positioned over at least one of the sacrificial layer 318b and the sacrificial layer 319b.

In FIG. 40D, the top surface of the insulating layer 327 includes a region whose level is less than the top surface level of the first layer 313a and the top surface level of the second layer 313b. That is, in a cross-sectional view, the top surface of the insulating layer 327 has a shape in which its center and the vicinity thereof are depressed, i.e., a shape including a concave surface.

In FIG. 40E, the top surface of the insulating layer 325 includes a region whose level is higher than the top surface level of the first layer 313a and the top surface level of the second layer 313b. That is, the insulating layer 325 protrudes from the formation surface of the fourth layer 314 and forms a protruding portion.

In formation of the insulating layer 325, for example, when the insulating layer 325 is formed so that its height is equal to or substantially equal to the height of the sacrificial layer, a protruding portion of the insulating layer 325 may be formed as illustrated in FIG. 40E.

In FIG. 40F, the top surface of the insulating layer 325 includes a region whose level is less than the top surface level of the first layer 313a and the top surface level of the second layer 313b. That is, the insulating layer 325 forms a recessed portion on the formation surface of the fourth layer 314.

As described above, the insulating layer 325 and the insulating layer 327 can have a variety of shapes.

The sacrificial layer can be formed using an inorganic film such as a metal film, an alloy film, a metal oxide film, a semiconductor film, or an inorganic insulating film, for example.

For the sacrificial layer, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used.

For the sacrificial layer, a metal oxide such as In—Ga—Zn oxide can be used. As the sacrificial layer, an In—Ga—Zn oxide film can be formed by a sputtering method, for example. It is also possible to use indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, indium tin oxide containing silicon, or the like can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium. In particular, M is preferably one or more selected from gallium, aluminum, and yttrium.

As the sacrificial layer, a variety of inorganic insulating films that can be used as the protective layer 331 can be used. In particular, an oxide insulating film is preferable because having higher adhesion to the EL layer than a nitride insulating film. For example, an inorganic insulating material such as aluminum oxide, hafnium oxide, or silicon oxide can be used for the sacrificial layer. As the sacrificial layer, an aluminum oxide film can be formed by an ALD method, for example. The ALD method is preferably used because damage to a base layer (particularly the EL layer or the like) can be reduced. As the sacrificial layer, a silicon nitride film can be formed by a sputtering method, for example.

Alternatively, the sacrificial layer can have a stacked-layer structure of an inorganic insulating film (e.g., aluminum oxide film) formed by an ALD method and an In—Ga—Zn oxide film formed by a sputtering method over the aluminum oxide film, for example. Alternatively, the sacrificial layer can employ a stacked-layer structure of an inorganic insulating film (e.g., an aluminum oxide film) formed by an ALD method and an aluminum film, a tungsten film, or an inorganic insulating film (e.g., a silicon nitride film) formed by a sputtering method.

In this specification and the like, a device formed using a metal mask or an FMM (fine metal mask, high-definition mask) may be referred to as a device having an MM (metal mask) structure. In this specification and the like, a device formed without using a metal mask or an FMM may be referred to as a device having an MML (metal maskless) structure.

In this specification and the like, a structure in which light-emitting layers in light-emitting devices of different colors (here, blue (B), green (G), and red (R)) are separately formed or separately patterned may be referred to as an SBS (Side By Side) structure. The SBS structure allows optimization of materials and structures of light-emitting devices and thus can extend freedom of choice of the materials and the structures, which makes it easy to improve the luminance and the reliability.

In this specification and the like, a light-emitting device capable of emitting white light is sometimes referred to as a white-light-emitting device. Note that a combination of white-light-emitting devices with coloring layers (e.g., color filters) enables a full-color display device.

Structures of light-emitting devices can be classified roughly into a single structure and a tandem structure. A device having a single structure includes one light-emitting unit between a pair of electrodes, and the light-emitting unit preferably includes one or more light-emitting layers. In the case of obtaining white light emission with use of two light-emitting layers, the two light-emitting layers may be selected such that their emission colors are complementary colors. For example, when emission colors of a first light-emitting layer and a second light-emitting layer are complementary colors, the light-emitting device can be configured to emit white light as a whole. When white light emission is obtained using three or more light-emitting layers, the light-emitting device is configured to emit white light as a whole by combining emission colors of the three or more light-emitting layers.

A device having a tandem structure includes two or more light-emitting units between a pair of electrodes, and each light-emitting unit preferably includes one or more light-emitting layers. To obtain white light emission, the structure is made so that light from light-emitting layers of the light-emitting units can be combined to be white light. Note that a structure for obtaining white light emission is similar to a structure in the case of a single structure. In the device having a tandem structure, it is suitable that an intermediate layer such as a charge-generation layer is provided between a plurality of light-emitting units.

When the white-light-emitting device (having a single structure or a tandem structure) and a light-emitting device having an SBS structure are compared to each other, the light-emitting device having an SBS structure can have lower power consumption than the white-light-emitting device. To reduce power consumption, a light-emitting device having the SBS structure is preferably used. Meanwhile, the white-light-emitting device is preferable in terms of lower manufacturing cost or higher manufacturing yield because the manufacturing process of the white-light-emitting device is simpler than that of a light-emitting device having the SBS structure.

In the display device of this embodiment, the distance between the light-emitting devices can be narrowed. Specifically, the distance between the light-emitting devices, the distance between the EL layers, or the distance between the pixel electrodes can be less than 10 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device includes a region where the distance between the side surface of the first layer 313a and the side surface of the second layer 313b or the distance between the side surface of the second layer 313b and the side surface of the third layer 313c is less than or equal to 1 μm, preferably less than or equal to 0.5 μm (500 nm), further preferably less than or equal to 100 nm.

A light-blocking layer may be provided on the surface of the substrate 320 on the resin layer 322 side. A variety of optical members can be arranged on the outer surface of the substrate 320. Examples of the optical members include a polarizing plate, a retardation plate, a light diffusion layer (a diffusion film or the like), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 320.

For the substrate 320, glass, quartz, ceramics, sapphire, a resin, a metal, an alloy, a semiconductor, or the like can be used. For the substrate on the side from which light from the light-emitting device is extracted, a material that transmits the light is used. When the substrate 320 is formed using a flexible material, the flexibility of the display device can be increased. Furthermore, a polarizing plate may be used as the substrate 320.

For the substrate 320, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 320.

In the case where a circularly polarizing plate overlaps with the display device, a highly optically isotropic substrate is preferably used as the substrate included in the display device. A highly optically isotropic substrate has a low birefringence (that can also be referred to as a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display panel might be changed, e.g., creases are generated. Thus, for the substrate, a film with a low water absorption rate is preferably used. For example, the water absorption rate of the film is preferably 1% or lower, further preferably 0.1% or lower, still further preferably 0.01% or lower.

For the resin layer 322, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. An adhesive sheet or the like may be used.

As materials that can be used for a gate, a source, and a drain of a transistor and conductive layers such as a variety of wirings and electrodes included in a display device, metals such as aluminum, titanium, chromium, nickel, copper, yttrium, zirconium, molybdenum, silver, tantalum, or tungsten, an alloy containing any of these metals as its main component, and the like can be given. A single-layer structure or a stacked-layer structure including a film containing any of these materials can be used.

As a light-transmitting conductive material, a conductive oxide such as indium oxide, indium tin oxide, indium zinc oxide, zinc oxide, or zinc oxide containing gallium, or graphene can be used. It is also possible to use a metal material such as gold, silver, platinum, magnesium, nickel, tungsten, chromium, molybdenum, iron, cobalt, copper, palladium, or titanium; or an alloy material containing any of these metal materials. Alternatively, a nitride of the metal material (e.g., titanium nitride) or the like may be used. Note that in the case of using the metal material or the alloy material (or the nitride thereof), the thickness is preferably set small enough to transmit light. Furthermore, a stacked-layer film of the above materials can be used for a conductive layer. For example, a stacked film of indium tin oxide and an alloy of silver and magnesium is preferably used because conductivity can be increased. They can also be used for conductive layers such as wirings and electrodes included in the display device, and conductive layers (e.g., a conductive layer functioning as a pixel electrode or a common electrode) included in a light-emitting device.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

Next, materials that can be used for the light-emitting device is described.

A conductive film that transmits visible light and infrared light is used as the electrode through which light is extracted, which is either the pixel electrode or the common electrode. A conductive film that reflects visible light and infrared light is preferably used as the electrode through which light is not extracted.

The light-emitting device preferably employs a microcavity structure. Therefore, one of the pair of electrodes of the light-emitting device is preferably an electrode having properties of transmitting and reflecting visible light (a transflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified.

Note that the semi-transmissive and semi-reflective electrode can have a stacked-layer structure of an electrode having a reflecting property with respect to visible light and an electrode having a transmitting property with respect to visible light (also referred to as a transparent electrode).

The transparent electrode has a light transmittance higher than or equal to 40%. For example, an electrode having a visible light (light at wavelengths greater than or equal to 400 nm and less than 750 nm) transmittance higher than or equal to 40% is preferably used in the light-emitting device. The visible light reflectivity of the transflective electrode is higher than or equal to 10% and lower than or equal to 95%, preferably higher than or equal to 30% and lower than or equal to 80%. The visible light reflectivity of the reflective electrode is higher than or equal to 40% and lower than or equal to 100%, preferably higher than or equal to 70% and lower than or equal to 100%. These electrodes preferably have a resistivity of 1×10⁻² Ωcm or lower. The near-infrared light (light at wavelengths greater than or equal to 750 nm and less than or equal to 1300 nm) transmittance and reflectivity of these electrodes preferably satisfy the above-described numerical ranges of the visible light transmittance and reflectivity.

The first layer 313a, the second layer 313b, and the third layer 313c each include a light-emitting layer. The first layer 313a, the second layer 313b, and the third layer 313c preferably include the light-emitting layers that emit light of different colors.

The light-emitting layer is a layer containing a light-emitting substance. The light-emitting layer can contain one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

In addition to the light-emitting layer, the first layer 313a, the second layer 313b, and the third layer 313c may further include a layer containing any of a substance with a high hole-injection property, a substance with a high hole-transport property, a hole-blocking material, a substance with a high electron-transport property, a substance with a high electron-injection property, an electron-blocking material, a substance with a bipolar property (a substance with a high electron-transport property and a high hole-transport property), and the like.

Either a low molecular compound or a high molecular compound can be used in the light-emitting device, and an inorganic compound may also be included. Each layer included in the light-emitting device can be formed by an evaporation method (including a vacuum evaporation method), a transfer method, a printing method, an inkjet method, a coating method, or the like.

For example, the first layer 313a, the second layer 313b, and the third layer 313c may each include one or more of a hole-injection layer, a hole-transport layer, a hole-blocking layer, an electron-blocking layer, an electron-transport layer, and an electron-injection layer. In addition, the first layer 313a, the second layer 313b, and the third layer 313c may each include a charge-generation layer (also referred to as an intermediate layer).

The fourth layer 314 can include one or more of a hole-injection layer, a hole-transport layer, a hole-blocking layer, an electron-blocking layer, an electron-transport layer, and an electron-injection layer. For example, in the case where the conductive layer 311a to the conductive layer 311c each function as an anode and the common electrode 315 functions as a cathode, the fourth layer 314 preferably includes an electron-injection layer.

The hole-injection layer is a layer injecting holes from an anode to a hole-transport layer and containing a material with a high hole-injection property. Examples of the material with a high hole-injection property include an aromatic amine compound and a composite material containing a hole-transport material and an acceptor material (electron-accepting material).

Note that thin films included in the display device (insulating films, semiconductor films, conductive films, and the like) can be formed by a sputtering method, a CVD method, a vacuum evaporation method, a PLD method, an ALD method, or the like. Examples of the CVD method include a plasma-enhanced chemical vapor deposition (PECVD: Plasma Enhanced CVD) method and a thermal CVD method. An example of the thermal CVD method is a metal organic chemical vapor deposition (MOCVD: Metal Organic CVD) method.

The thin films included in the display device (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

For manufacture of the light-emitting devices, a vacuum process such as an evaporation method or a solution process such as a spin coating method or an ink-jet method can be especially used. Examples of an evaporation method include physical vapor deposition methods (PVD method) such as a sputtering method, an ion plating method, an ion beam evaporation method, a molecular beam evaporation method, and a vacuum evaporation method, and a chemical vapor deposition method (CVD method). Specifically, the functional layers (e.g., the hole-injection layer, the hole-transport layer, the light-emitting layer, the electron-transport layer, and the electron-injection layer) included in the EL layers can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

Thin films included in the display device can be processed by a photolithography method or the like. Alternatively, the thin films may be processed by a nanoimprinting method, a sandblasting method, a lift-off method, or the like. Island-shaped thin films may be directly formed by a deposition method using a blocking mask such as a metal mask.

As described above, in the method for fabricating the display device of one embodiment of the present invention, an island-shaped EL layer is formed by processing an EL layer formed on the entire surface, not by a pattern of a metal mask; thus, the island-shaped EL layer can have a uniform thickness. In addition, a high-resolution display device or a display device with a high aperture ratio, which has been difficult to achieve, can be fabricated.

The first layer, the second layer, and the third layer included in the light-emitting devices of different colors are formed in separate steps. Accordingly, the EL layers can be formed to have structures (material, thickness, and the like) appropriate for the light-emitting devices of the respective colors. Thus, the light-emitting devices can have favorable characteristics.

This embodiment can be combined with the other embodiments as appropriate.

### Embodiment 4

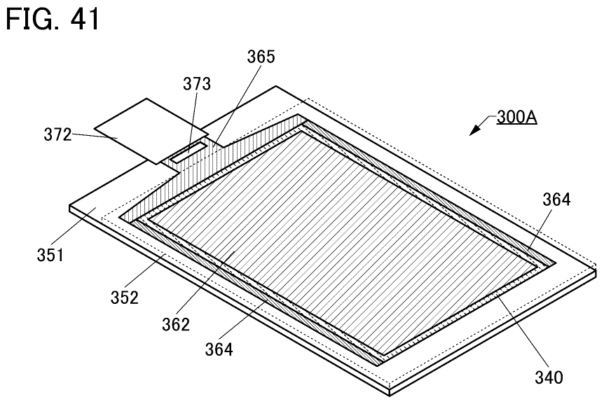

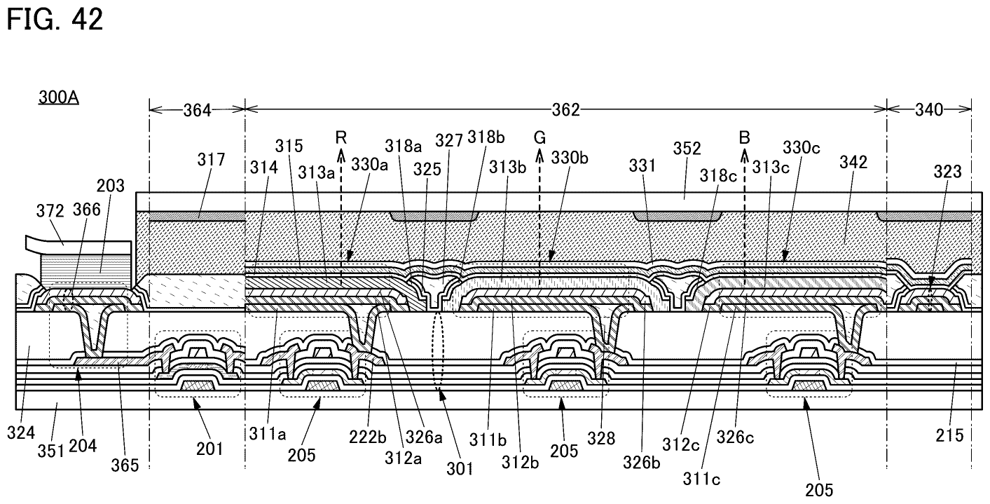

In this embodiment, a display device of one embodiment of the present invention will be described with reference to FIG. 41 and FIG. 42.

The display device of this embodiment can be a high-resolution display device or large-sized display device. Accordingly, the display device of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

FIG. 41 is a perspective view of a display device 300A, and FIG. 42 is a cross-sectional view of the display device 300A.

The display device 300A has a structure in which a substrate 351 and a substrate 352 are bonded to each other. In FIG. 41, the substrate 352 is denoted by a dashed line.

The display device 300A includes a display portion 362, a connection portion 340, a circuit 364, a wiring 365, and the like. FIG. 41 illustrates an example in which an IC 373 and an FPC 372 are mounted on the display device 300A. Thus, the structure illustrated in FIG. 41 can be regarded as a display module including the display device 300A, the IC (integrated circuit), and the FPC.

The connection portion 340 is provided outside the display portion 362. The connection portion 340 can be provided along one side or a plurality of sides of the display portion 362. The number of the connection portions 340 can be one or more. FIG. 41 illustrates an example in which the connection portion 340 is provided to surround the four sides of the display portion. The common electrode of the light-emitting device is electrically connected to a conductive layer in the connection portion 340, and thus a potential can be supplied to the common electrode.

As the circuit 364, a scan line driver circuit can be used, for example.

The wiring 365 has a function of supplying a signal and power to the display portion 362 and the circuit 364. The signal and power are input to the wiring 365 from the outside through the FPC 372 or from the IC 373.

FIG. 41 illustrates an example in which the IC 373 is provided over the substrate 351 by a COG (Chip On Glass) method, a COF (Chip On Film) method, or the like. An IC including a scan line driver circuit, a signal line driver circuit, or the like can be used as the IC 373, for example. Note that the display device 300A and the display module are not necessarily provided with an IC. The IC may be mounted on the FPC by a COF method or the like.

FIG. 42 illustrates an example of cross sections of part of a region including the FPC 372, part of the circuit 364, part of the display portion 362, part of the connection portion 340, and part of a region including an end portion of the display device 300A.

The display device 300A illustrated in FIG. 42 includes a transistor 201, a transistor 205, the light-emitting device 330a which emits red light, the light-emitting device 330b which emits green light, the light-emitting device 330c which emits blue light, and the like between the substrate 351 and the substrate 352.

The light-emitting device 330a includes the conductive layer 311a, the conductive layer 312a over the conductive layer 311a, and a conductive layer 326a over the conductive layer 312a. All of the conductive layer 311a, the conductive layer 312a, and the conductive layer 326a can be referred to as the pixel electrode, or one or two of them can be referred to as the pixel electrode.

The conductive layer 311a is connected to a conductive layer 222b included in the transistor 205 through an opening provided in an insulating layer 324. The end portion of the conductive layer 312a is positioned outward from the end portion of the conductive layer 311a. The end portion of the conductive layer 312a and the end portion of the conductive layer 326a are aligned or substantially aligned with each other. For example, a conductive layer functioning as a reflective electrode can be used as the conductive layer 311a and the conductive layer 312a, and a conductive layer functioning as a transparent electrode can be used as the conductive layer 326a.

The light-emitting device 330b includes the conductive layer 311b, the conductive layer 312b over the conductive layer 311b, and the conductive layer 326b over the conductive layer 312b.

The light-emitting device 330c includes the conductive layer 311c, the conductive layer 312c over the conductive layer 311c, and the conductive layer 326c over the conductive layer 312c.

Detailed description of the conductive layer 311b, the conductive layer 312b, and the conductive layer 326b of the light-emitting device 330b and the conductive layer 311c, the conductive layer 312c, and the conductive layer 326c of the light-emitting device 330c is omitted because these conductive layers are similar to the conductive layer 311a, the conductive layer 312a, and the conductive layer 326a of the light-emitting device 330a.

Depressed portions are formed in the conductive layer 311a, the conductive layer 311b, and the conductive layer 311c to cover the openings provided in the insulating layer 324. A layer 328 is embedded in each of the depressed portions.

The layer 328 has a function of enabling planarization in the depressed portions of the conductive layer 311a, the conductive layer 311b, and the conductive layer 311c. Over the conductive layer 311a, the conductive layer 311b, the conductive layer 311c, and the layer 328, the conductive layer 312a, the conductive layer 312b, and the conductive layer 312c are provided to be electrically connected to the conductive layer 311a, the conductive layer 311b, or the conductive layer 311c. Thus, regions overlapping with the depressed portions of the conductive layer 311a, the conductive layer 311b, and the conductive layer 311c can also be used as the light-emitting regions, increasing the aperture ratio of the pixel.

The layer 328 may be an insulating layer or a conductive layer. Any of a variety of inorganic insulating materials, organic insulating materials, and conductive materials can be used for the layer 328 as appropriate. In particular, the layer 328 is preferably formed using an insulating material.

An insulating layer containing an organic material can be suitably used as the layer 328. For the layer 328, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 328. As the photosensitive resin, a positive photosensitive material or a negative photosensitive material can be used.

When a photosensitive resin is used, the layer 328 can be formed through only light-exposure and development steps, reducing the influence of dry etching, wet etching, or the like on the surfaces of the conductive layer 311a, the conductive layer 311b, and the conductive layer 311c. When the layer 328 is formed using a negative photosensitive resin, the layer 328 can sometimes be formed using the same photomask (light-exposure mask) as the photomask used for forming the opening in the insulating layer 324.

The top surface and the side surface of the conductive layer 312a and the top surface and the side surface of the conductive layer 326a are covered with the first layer 313a. Similarly, the top surface and the side surface of the conductive layer 312b and the top surface and the side surface of the conductive layer 326b are covered with the second layer 313b. Moreover, the top surface and the side surface of the conductive layer 312c and the top surface and the side surface of the conductive layer 326c are covered with the third layer 313c. Accordingly, regions provided with the conductive layer 312a, the conductive layer 312b, or the conductive layer 312c can be entirely used as the light-emitting regions of the light-emitting device 330a, the light-emitting device 330b, or the light-emitting device 330c, increasing the aperture ratio of the pixel.

The side surfaces of the first layer 313a, the second layer 313b, and the third layer 313c are covered with the insulating layer 325 and the insulating layer 327. The sacrificial layer 318a is positioned between the first layer 313a and the insulating layer 325, and the sacrificial layer 318b is positioned between the second layer 313b and the insulating layer 325, and the sacrificial layer 318c is positioned between the third layer 313c and the insulating layer 325. The fourth layer 314 is provided over the first layer 313a, the second layer 313b, the third layer 313c, the insulating layer 325 and the insulating layer 327, and the common electrode 315 is provided over the fourth layer 314. The fourth layer 314 and the common electrode 315 are each one continuous film shared by the plurality of light-emitting devices. The protective layer 331 is provided over the light-emitting device 330a, the light-emitting device 330b, and the light-receiving device 330c.

The protective layer 331 and the substrate 352 are bonded to each other with an adhesive layer 342. A solid sealing structure, a hollow sealing structure, or the like can be employed to seal the light-emitting devices. In FIG. 42, a solid sealing structure is employed in which a space between the substrate 352 and the substrate 351 is filled with the adhesive layer 342. Alternatively, a hollow sealing structure in which the space is filled with an inert gas (e.g., nitrogen or argon) may be employed. Here, the adhesive layer 342 may be provided not to overlap with the light-emitting device. The space may be filled with a resin different from that of the frame-like adhesive layer 342.

The conductive layer 323 is provided over the insulating layer 324 in the connection portion 340. An example is illustrated in which the conductive layer 323 has a stacked-layer structure of a conductive film obtained by processing the same conductive film as the conductive layer 311a, the conductive layer 311b, and the conductive layer 311c; a conductive film obtained by processing the same conductive film as the conductive layer 312a, the conductive layer 312b, and the conductive layer 312c; and a conductive film obtained by processing the same conductive film as the conductive layer 326a, the conductive layer 326b, and the conductive layer 326c. An end portion of the conductive layer 323 is covered with the sacrificial layer, the insulating layer 325, and the insulating layer 327. The fourth layer 314 is provided over the conductive layer 323, and the common electrode 315 is provided over the fourth layer 314. The conductive layer 323 and the common electrode 315 are electrically connected to each other through the fourth layer 314. Note that a structure in which the fourth layer 314 is not formed in the connection portion 340 may be employed. In this case, the conductive layer 323 and the common electrode 315 are directly in contact with each other and electrically connected to each other.

The display device 300A has a top emission structure. Light from the light-emitting device is emitted toward the substrate 352. For the substrate 352, a material having a high transmitting property with respect to visible light is preferably used. The pixel electrode contains a material that reflects visible light, and the counter electrode (common electrode 315) contains a material that transmits visible light.

A stacked-layer structure including the substrate 351 and the components thereover up to the insulating layer 324 corresponds to the layer 301 including the above-described transistor. As the transistor 201 and the transistor 205 in the layer 301, the transistor exemplified in Embodiment 1 can be used. For example, the transistor 200A can be used in the circuit 364, and the transistor 100A can be used in the display portion 362. Furthermore, the semiconductor layer of each of the transistor 100A and the transistor 200A preferably contain indium, and the semiconductor layer of the transistor 200A preferably has a higher atomic ratio of indium to contained metal elements than that in the transistor 100A. With such a structure, a display device having both good electrical characteristics and high reliability can be obtained. A plurality of transistors included in the circuit 364 may have the same structure or two or more kinds of structures. Similarly, a plurality of transistors included in the display portion 362 may have the same structure or two or more kinds of structures.

An insulating layer 215 is provided to cover the transistors. The insulating layer 324 is provided to cover the transistors and has a function of a planarization layer. Note that the number of insulating layers covering the transistors is not limited, and either a single layer or two or more layers may be employed.

A material through which impurities such as water and hydrogen do not easily diffuse is preferably used for at least one of the insulating layers covering the transistors. This allows the insulating layer to function as a barrier layer. Such a structure can effectively inhibit diffusion of impurities into the transistors from the outside and increase the reliability of the display device.

An inorganic insulating film is preferably used as the insulating layer 215. As the inorganic insulating film, for example, a silicon nitride film, a silicon oxynitride film, a silicon oxide film, a silicon nitride oxide film, an aluminum oxide film, or an aluminum nitride film, or the like can be used. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may also be used. A stack including two or more of the above insulating films may also be used.

An organic insulating film is preferably used for the insulating layer 324 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 324 may have a stacked-layer structure including an organic insulating film and an inorganic insulating film. The outermost layer of the insulating layer 324 preferably has a function of an etching protective film. In that case, the formation of a depressed portion in the insulating layer 324 can be inhibited in processing of the conductive layer 311b, the conductive layer 312b, the conductive layer 326b, or the like. Alternatively, a depressed portion may be formed in the insulating layer 324 in processing of the conductive layer 311b, the conductive layer 312b, the conductive layer 326b, or the like.

A connection portion 204 is provided in a region of the substrate 351 that does not overlap with the substrate 352. In the connection portion 204, the wiring 365 is electrically connected to the FPC 372 through a conductive layer 366 and a connection layer 203. An example is illustrated in which the conductive layer 366 has a stacked-layer structure of a conductive film obtained by processing the same conductive film as the conductive layer 311a, the conductive layer 311b, and the conductive layer 311c; a conductive film obtained by processing the same conductive film as the conductive layer 312a, the conductive layer 312b, and the conductive layer 312c; and a conductive film obtained by processing the same conductive film as the conductive layer 326a, the conductive layer 326b, and the conductive layer 326c. On the top surface of the connection portion 204, the conductive layer 366 is exposed. Thus, the connection portion 204 and the FPC 372 can be electrically connected to each other through the connection layer 203.

A light-blocking layer 317 is preferably provided on the surface of the substrate 352 on the substrate 351 side. The light-blocking layer 317 can be provided between adjacent light-emitting devices, in the connection portion 340, in the circuit 364, and the like. A variety of optical members can be arranged on the outer side of the substrate 352. Examples of the optical members include a polarizing plate, a retardation plate, a light diffusion layer (a diffusion film or the like), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 352.

The protective layer 331 provided to cover the light-emitting devices can inhibit an impurity such as water from entering the light-emitting devices, and increase the reliability of the light-emitting devices.

For each of the substrate 351 and the substrate 352, glass, quartz, ceramics, sapphire, a resin, a metal, an alloy, a semiconductor, or the like can be used. For the substrate on the side from which light from the light-emitting device is extracted, a material that transmits the light is used. When a flexible material is used for the substrate 351 and the substrate 352, the flexibility of the display device can be increased. Furthermore, a polarizing plate may be used as the substrate 351 or the substrate 352.

For each of the substrate 351 and the substrate 352, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for one or both of the substrate 351 and the substrate 352.

In the case where a circularly polarizing plate overlaps with the display device, a highly optically isotropic substrate is preferably used as the substrate included in the display device. A highly optically isotropic substrate has a low birefringence (that can also be referred to as a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display panel might be changed, e.g., creases are generated. Thus, for the substrate, a film with a low water absorption rate is preferably used. For example, the water absorption rate of the film is preferably 1% or lower, further preferably 0.1% or lower, still further preferably 0.01% or lower.

As the adhesive layer 342, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. Alternatively, a two-liquid-mixture-type resin may be used. An adhesive sheet or the like may be used.

As the connection layer 203, an anisotropic conductive film (ACF), an anisotropic conductive paste (ACP), or the like can be used.

As materials that can be used for a gate, a source, and a drain of a transistor and conductive layers such as a variety of wirings and electrodes included in a display device, metals such as aluminum, titanium, chromium, nickel, copper, yttrium, zirconium, molybdenum, silver, tantalum, or tungsten, an alloy containing any of these metals as its main component, and the like can be given. A single-layer structure or a stacked-layer structure including a film containing any of these materials can be used.

As a light-transmitting conductive material, a conductive oxide such as indium oxide, indium tin oxide, indium zinc oxide, zinc oxide, or zinc oxide containing gallium, or graphene can be used. It is also possible to use a metal material such as gold, silver, platinum, magnesium, nickel, tungsten, chromium, molybdenum, iron, cobalt, copper, palladium, or titanium; or an alloy material containing any of these metal materials. Alternatively, a nitride of the metal material (e.g., titanium nitride) or the like may be used. Note that in the case of using the metal material or the alloy material (or the nitride thereof), the thickness is preferably set small enough to transmit light. Furthermore, a stacked-layer film of the above materials can be used for a conductive layer. For example, a stacked film of indium tin oxide and an alloy of silver and magnesium is preferably used because conductivity can be increased. They can also be used for conductive layers such as wirings and electrodes included in the display device, and conductive layers (e.g., a conductive layer functioning as a pixel electrode or a common electrode) included in a light-emitting device.

As an insulating material that can be used for each insulating layer, for example, a resin such as an acrylic resin or an epoxy resin, and an inorganic insulating material such as silicon oxide, silicon oxynitride, silicon nitride oxide, silicon nitride, or aluminum oxide can be given.

### Embodiment 5

In this embodiment, light-emitting devices that can be used for the display device according to one embodiment of the present invention will be described.

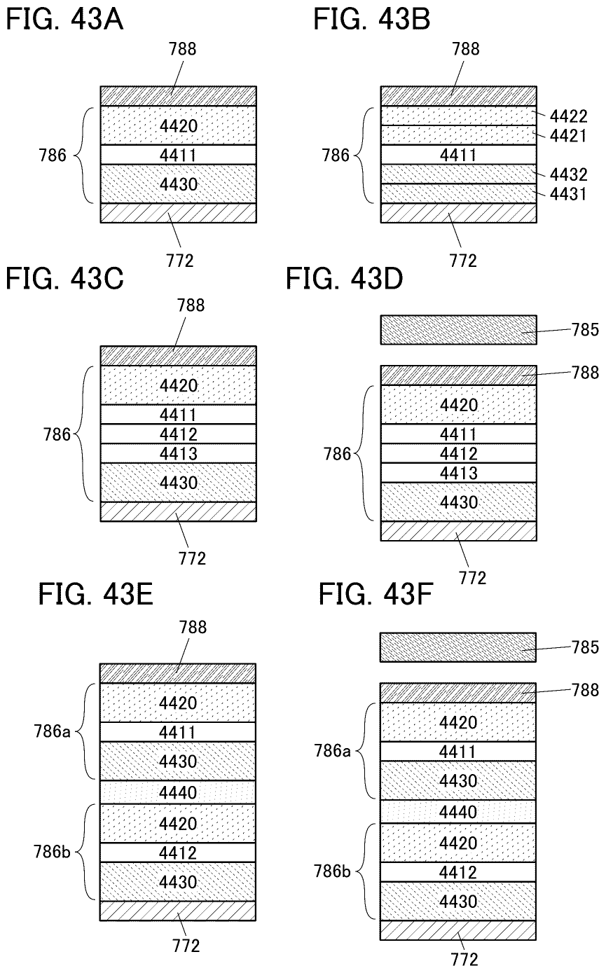

As illustrated in FIG. 43A, the light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (electron-injection layer) and a layer containing a substance with a high electron-transport property (electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between a pair of electrodes, can serve as a single light-emitting unit, and the structure in FIG. 43A is referred to as a single structure in this specification.

FIG. 43B is a variation example of the EL layer 786 included in the light-emitting device illustrated in FIG. 43A. Specifically, the light-emitting device illustrated in FIG. 43B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. For example, when the lower electrode 772 is an anode and the upper electrode 788 is a cathode, the layer 4431 functions as a hole-injection layer, the layer 4432 functions as a hole-transport layer, the layer 4421 functions as an electron-transport layer, and the layer 4422 functions as an electron-injection layer. Alternatively, when the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layered structure, carriers can be efficiently injected to the light-emitting layer 4411, and the efficiency of the recombination of carriers in the light-emitting layer 4411 can be enhanced.

Note that the structure in which a plurality of light-emitting layers (light-emitting layers 4411, 4412, and 4413) are provided between the layer 4420 and the layer 4430 as illustrated in FIG. 43C and FIG. 43D is a variation of the single structure.

A structure in which a plurality of light-emitting units (EL layer 786a and EL layer 786b) are connected in series with a charge-generation layer 4440 therebetween as illustrated in FIG. 43E and FIG. 43F is referred to as a tandem structure in this specification. Note that the tandem structure may be referred to as a stack structure. The tandem structure enables a light-emitting device capable of high-luminance light emission.

In FIG. 43C and FIG. 43D, light-emitting materials that emit the same light or the same material may be used for the light-emitting layer 4411, the light-emitting layer 4412, and the light-emitting layer 4413. For example, a light-emitting material that emit blue light may be used for the light-emitting layer 4411, the light-emitting layer 4412, and the light-emitting layer 4413. A color conversion layer may be provided as a layer 785 illustrated in FIG. 43D.

Alternatively, light-emitting materials emitting different colors may be used for the light-emitting layer 4411, the light-emitting layer 4412, and the light-emitting layer 4413. White light can be obtained when the light-emitting layer 4411, the light-emitting layer 4412, and the light-emitting layer 4413 emit light of complementary colors. A color filter (also referred to as a coloring layer) may be provided as the layer 785 illustrated in FIG. 43D. When white light passes through a color filter, light of a desired color can be obtained.

In FIG. 43E and FIG. 43F, light-emitting materials that emit light of the same color, or moreover, the same light-emitting material may be used for the light-emitting layer 4411 and the light-emitting layer 4412. Alternatively, light-emitting materials that emit light of different colors may be used for the light-emitting layer 4411 and the light-emitting layer 4412. White light can be obtained when the light-emitting layer 4411 and the light-emitting layer 4412 emit light of complementary colors. FIG. 43F illustrates an example in which the coloring layer 785 is further provided. One or both of a color conversion layer and a color filter (coloring layer) can be used as the layer 785.

In FIG. 43C, FIG. 43D, FIG. 43E, and FIG. 43F, the layer 4420 and the layer 4430 may each have a stacked-layer structure of two or more layers as in FIG. 43B.

A structure in which light emission colors (e.g., blue (B), green (G), and red (R)) are separately formed for the light-emitting devices is referred to as an SBS (Side By Side) structure in some cases.

The color of light emitted by the light-emitting device can be red, green, blue, cyan, magenta, yellow, white, or the like depending on the material that constitutes the EL layer 786. Furthermore, the color purity can be further increased when the light-emitting device has a microcavity structure.

The light-emitting device that emits white light preferably contains two or more kinds of light-emitting substances in the light-emitting layer. To obtain white light emission, two or more light-emitting substances are selected such that their emission colors are complementary colors. For example, when the emission color of a first light-emitting layer and the emission color of a second light-emitting layer are complementary colors, it is possible to obtain a light-emitting device which emits white light as a whole. The same applies to a light-emitting device including three or more light-emitting layers.

The light-emitting layer preferably contains two or more light-emitting substances that emit light of R (red), G (green), B (blue), Y (yellow), 0 (orange), and the like. Alternatively, the light-emitting layer preferably contains two or more light-emitting substances that emit light containing two or more of spectral components of R, G, and B.

This embodiment can be combined with the other embodiments as appropriate.

### Embodiment 6

In this embodiment, a metal oxide (also referred to as an oxide semiconductor) that can be used in the OS transistor described in the above embodiment will be described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a chemical vapor deposition (CVD) method such as a metal organic chemical vapor deposition (MOCVD) method, an atomic layer deposition (ALD) method, or the like.

### <Classification of Crystal Structure>

Amorphous (including completely amorphous), CAAC (c-axis-aligned crystalline), nc (nanocrystalline), CAC (cloud-aligned composite), single crystal, and polycrystalline (polycrystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method.

For example, the XRD spectrum of a quartz glass substrate shows a peak with a substantially bilaterally symmetrical shape. On the other hand, the peak of the XRD spectrum of an IGZO film having a crystal structure has a bilaterally asymmetrical shape. The asymmetrical peak of the XRD spectrum clearly shows the existence of crystal in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in the diffraction pattern of the IGZO film deposited at room temperature. Thus, it is suggested that the IGZO film deposited at room temperature is in an intermediate state, which is neither a crystal state nor an amorphous state, and it cannot be concluded that the IGZO film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-O S]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. In addition, the crystal region refers to a region having a periodic atomic arrangement. Note that when an atomic arrangement is regarded as a lattice arrangement, the crystal region also refers to a region with a uniform lattice arrangement. Furthermore, the CAAC-OS has a region where a plurality of crystal regions are connected in an a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Note that indium and the element M can be replaced with each other. Therefore, indium is sometimes contained in the (M,Zn) layer. Furthermore, the element M is sometimes contained in the In layer. Note that Zn is sometimes contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (also referred to as grain boundary) cannot be observed even in the vicinity of the distortion in the CAAC-OS. That is, it is found that formation of a crystal grain boundary is inhibited by the distortion of a lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

The CAAC-OS is an oxide semiconductor with high crystallinity in which no clear crystal grain boundary is observed. Thus, in the CAAC-OS, it can be said that a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Accordingly, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, specifically, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Hence, the orientation in the whole film is not observed. Accordingly, the nc-OS cannot be distinguished from an a-like OS or an amorphous oxide semiconductor by some analysis methods. For example, when an nc-OS film is subjected to structural analysis by out-of-plane XRD measurement with an XRD apparatus using 0120 scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or smaller than the diameter of a nanocrystal (e.g., larger than or equal to 1 nm and smaller than or equal to 30 nm).

[a-Like OS]

The a-like OS is an oxide semiconductor having a structure between those of the nc-OS and the amorphous oxide semiconductor. The a-like OS contains a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Composition of Oxide Semiconductor>>

Next, the above-described CAC-OS will be described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in an In—Ga—Zn oxide are denoted by [In], [Ga], and [Zn], respectively. For example, the first region in the CAC-OS in the In—Ga—Zn oxide has [In] higher than [In] in the composition of the CAC-OS film. Moreover, the second region has [Ga] higher than [Ga] in the composition of the CAC-OS film. For example, the first region has higher [In] and lower [Ga] than the second region. Moreover, the second region has higher [Ga] and lower [In] than the first region.

Specifically, the first region contains indium oxide, indium zinc oxide, or the like as its main component. The second region contains gallium oxide, gallium zinc oxide, or the like as its main component. That is, the first region can be rephrased as a region containing In as its main component. Furthermore, the second region can be rephrased as a region containing Ga as its main component.

Note that a clear boundary between the first region and the second region cannot be observed in some cases.

In a material composition of a CAC-OS in an In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a deposition gas. The ratio of the flow rate of an oxygen gas to the total flow rate of the deposition gas at the time of deposition is preferably as low as possible, and for example, the ratio of the flow rate of an oxygen gas to the total flow rate of the deposition gas at the time of deposition is preferably higher than or equal to 0% and less than 30%, further preferably higher than or equal to 0% and less than or equal to 10%.

For example, according to EDX mapping obtained by energy dispersive X-ray spectroscopy (EDX), the CAC-OS in the In—Ga—Zn oxide has a composition in which the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

On the other hand, the second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, high on-state current, high field-effect mobility, and excellent switching operation can be achieved.

A transistor using the CAC-OS has high reliability. Thus, the CAC-OS is most suitable for a variety of semiconductor devices such as display devices.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a highly reliable transistor can be achieved.

An oxide semiconductor having a low carrier concentration is preferably used for the transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. Note that in the case where the carrier concentration of an oxide semiconductor film is lowered, the impurity concentration in the oxide semiconductor film is lowered to decrease the density of defect states. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charges trapped by the trap states in an oxide semiconductor take a long time to be released and may behave like fixed charges. Thus, a transistor whose channel formation region is formed in an oxide semiconductor having a high density of trap states has unstable electrical characteristics in some cases.

Accordingly, in order to obtain stable electrical characteristics of a transistor, reducing the impurity concentration in an oxide semiconductor is effective. In addition, in order to reduce the impurity concentration in the oxide semiconductor, the impurity concentration in a film that is adjacent to the oxide semiconductor is also preferably reduced. Examples of impurities include hydrogen, nitrogen, alkali metal, alkaline earth metal, iron, nickel, and silicon.

### <Impurity>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are set lower than or equal to 2×10¹⁸ atoms/cm³, preferably lower than or equal to 2×10¹⁷ atoms/cm³.

When the oxide semiconductor contains alkali metal or alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

An oxide semiconductor containing nitrogen easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ a atoms/cm³, further preferably lower than or equal to 1×10¹⁸ atoms/cm³ and still further preferably lower than or equal to 5×10¹⁷ atoms/cm³.

Hydrogen contained in an oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, some hydrogen is bonded to oxygen bonded to a metal atom and generates an electron serving as a carrier. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for a channel formation region in a transistor, the transistor can have stable electrical characteristics.

This embodiment can be combined with the other embodiments as appropriate.

### Embodiment 7

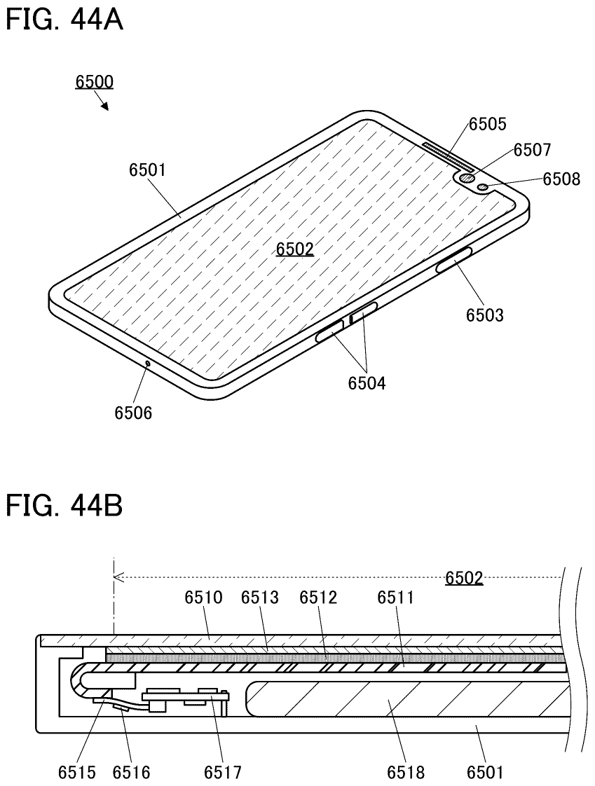

In this embodiment, electronic devices of one embodiment of the present invention will be described with reference to FIG. 44 to FIG. 46.

An electronic device of this embodiment is provided with the display device of one embodiment of the present invention in a display portion. The display device of one embodiment of the present invention can be easily increased in definition and resolution. Thus, the display device of one embodiment of the present invention can be used for a display portion of a variety of electronic devices.

Examples of electronic devices include a digital camera, a digital video camera, a digital photo frame, a mobile phone, a portable game machine, a portable information terminal, and an audio reproducing device in addition to electronic devices with a relatively large screen, such as a television device, a desktop or laptop personal computer, a monitor of a computer or the like, digital signage, and a large game machine such as a pachinko machine.

In particular, the display device of one embodiment of the present invention can have a high resolution, and thus can be suitably used for an electronic device having a relatively small display portion. Examples of such an electronic device include a watch-type or a bracelet-type information terminal device (wearable device), and a wearable device worn on a head, such as a device for VR such as a head-mounted display, a glasses-type device for AR, and a device for MR. The resolution of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution is preferably 4K, 8K, or higher. Furthermore, the pixel density (definition) of the display device of one embodiment of the present invention is preferably higher than or equal to 100 ppi, higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, and yet further preferably higher than or equal to 7000 ppi. With use of such a display device with one or both of high resolution and high definition, the electronic device can have higher realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 illustrated in FIG. 44A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 44B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted while the thickness of the electronic device is controlled. An electronic device with a narrow frame can be obtained when part of the display panel 6511 is folded back so that the portion connected to the FPC 6515 is positioned on the rear side of the display portion.

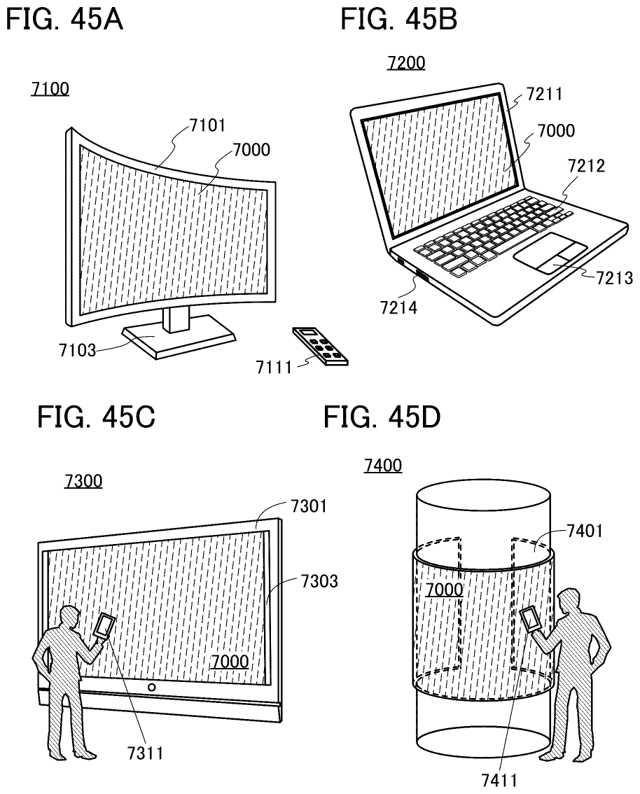

FIG. 45A illustrates an example of a television device. In a television device 7100, a display portion 7000 is incorporated in a housing 7101. Here, a structure in which the housing 7101 is supported by a stand 7103 is illustrated.

The display device of one embodiment of the present invention can be used in the display portion 7000.

Operation of the television device 7100 illustrated in FIG. 45A can be performed with an operation switch provided in the housing 7101 and a separate remote controller 7111.

Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be operated and images displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 45B illustrates an example of a laptop personal computer. The laptop personal computer 7200 includes a housing 7211, a keyboard 7212, a pointing device 7213, an external connection port 7214, and the like. In the housing 7211, the display portion 7000 is incorporated.

The display device of one embodiment of the present invention can be used in the display portion 7000.

FIG. 45C and FIG. 45D illustrate examples of digital signage.

Digital signage 7300 illustrated in FIG. 45C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 45D is digital signage 7400 attached to a cylindrical pillar 7401. The digital signage 7400 includes the display portion 7000 provided along a curved surface of the pillar 7401.

The display device of one embodiment of the present invention can be used for the display portion 7000 in FIG. 45C and FIG. 45D.

A larger area of the display portion 7000 can increase the amount of information that can be provided at a time. The larger display portion 7000 attracts more attention, so that the effectiveness of the advertisement can be increased, for example.

The use of a touch panel in the display portion 7000 is preferable because in addition to display of a still image or a moving image on the display portion 7000, intuitive operation by a user is possible. Moreover, for an application for providing information such as route information or traffic information, usability can be enhanced by intuitive operation.

As illustrated in FIG. 45C and FIG. 45D, it is preferable that the digital signage 7300 or the digital signage 7400 work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

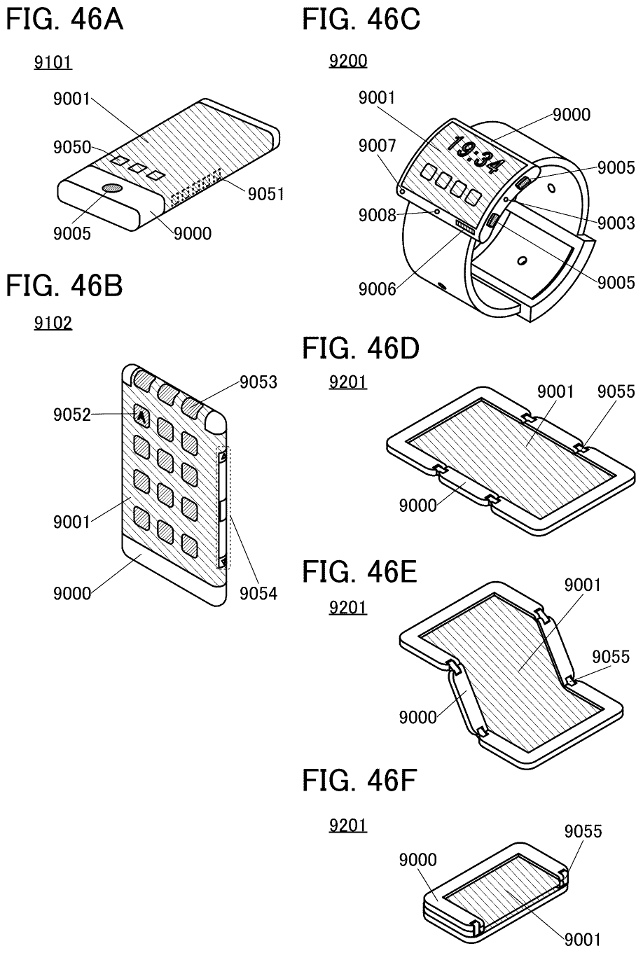

Electronic devices illustrated in FIG. 46A to FIG. 46F each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays), a microphone 9008, and the like.

The electronic devices illustrated in FIG. 46A to FIG. 46F have a variety of functions. For example, the electronic devices can have a function of displaying a variety of information (a still image, a moving image, a text image, and the like) on the display portion, a touch panel function, a function of displaying a calendar, date, time, and the like, a function of controlling processing with use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 46A to FIG. 46F will be described in detail below.

FIG. 46A is a perspective view illustrating a portable information terminal 9101. The portable information terminal 9101 can be used as a smartphone, for example. Note that the portable information terminal 9101 may include the speaker 9003, the connection terminal 9006, the sensor 9007, or the like. The portable information terminal 9101 can display characters and image information on its plurality of surfaces. FIG. 46A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 46B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, the user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer a call, for example.

FIG. 46C is a perspective view illustrating a watch-type portable information terminal 9200. The portable information terminal 9200 can be used as a smartwatch (registered trademark), for example. The display surface of the display portion 9001 is curved, and display can be performed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and can be charged. Note that the charging operation may be performed by wireless power feeding.

FIG. 46D to FIG. 46F are perspective views illustrating a foldable portable information terminal 9201. FIG. 46D is a perspective view of an opened state of the portable information terminal 9201, FIG. 46F is a perspective view of a folded state thereof, and FIG. 46E is a perspective view of a state in the middle of change from one of FIG. 46D and FIG. 46F to the other. The portable information terminal 9201 is highly portable in the folded state and is highly browsable in the opened state because of a seamless large display region. The display portion 9001 of the portable information terminal 9201 is supported by three housings 9000 joined together by hinges 9055. For example, the display portion 9001 can be folded with a radius of curvature greater than or equal to 0.1 mm and less than or equal to 150 mm.

This embodiment can be combined with the other embodiments as appropriate.

### Example 1

The description below is about the fabrication of transistors whose semiconductor layers are different in their compositions over one substrate and the evaluation results of electrical characteristics and reliability of the transistors.

### <Sample Fabrication>

For structures of the transistors fabricated, the transistor 100A and the transistor 200A exemplified in Embodiment 1 can be referred to.

First, a 100-nm-thick tungsten film was formed by a sputtering method over a glass substrate and then processed, whereby a second gate electrode of the transistor 100A and a second gate electrode of the transistor 200A were obtained.

Next, a first insulating layer was deposited by a plasma CVD method. The first insulating layer was formed to have a stacked-layer structure of a 200-nm-thick first silicon nitride film, a 30-nm-thick second silicon nitride film, a 50-nm-thick first silicon oxynitride film, and a 20-nm-thick second silicon oxynitride film.

Next, a 50-nm-thick first metal oxide film was formed over the first gate insulating layer and processed, whereby a first semiconductor layer was obtained. The first metal oxide film was deposited by a sputtering method using a sputtering target with an atomic ratio of metal elements of In:Ga:Zn=1:1:1. The first semiconductor layer was formed in a region overlapping with the second gate electrode of the transistor 100A.

Then, a second insulating layer was deposited by a plasma CVD method over the first insulating layer and the first semiconductor layer. The second insulating layer was formed to a 10-nm-thick third silicon oxynitride film.

Next, a 20-nm-thick second metal oxide film was formed over the second insulating layer and processed, whereby a semiconductor layer was obtained. The second metal oxide film was deposited by a sputtering method using a sputtering target with an atomic ratio of metal elements of In:Ga:Zn=5:1:3. The second semiconductor layer was formed in a region overlapping with the second gate electrode of the transistor 200A.

Next, heat treatment was performed at 350° C. in a dry air (CDA) atmosphere for two hours.

Next, a third insulating layer was deposited by a plasma CVD method over the second insulating layer and the second semiconductor layer. The third insulating layer was formed to have a stacked-layer structure of a 10-nm-thick fourth silicon oxynitride film, a 70-nm-thick fifth silicon oxynitride film, and a 20-nm-thick sixth silicon oxynitride film.

Next, heat treatment was performed at 350° C. in a dry air (CDA) atmosphere for one hour.

Then, a 20-nm-thick third metal oxide film was deposited by a sputtering method over the third insulating layer. The third metal oxide film was deposited by a sputtering method using a sputtering target with an atomic ratio of metal elements of In:Ga:Zn=1:1:1.

Next, heat treatment was performed at 350° C. in a dry air (CDA) atmosphere for one hour.

Next, the first insulating layer, the second insulating layer, the third insulating layer, and the third metal oxide film were etched partly, so that an opening portion reaching the second gate electrode of the transistor 100A and an opening portion reaching the second gate electrode of the transistor 200A were formed.

Then, a conductive film was deposited by a sputtering method to cover the opening portions. The conductive film was formed to have a structure-layer structure of a 50-nm-thick molybdenum film, a 200-nm-thick aluminum film and a 50-nm-thick titanium film. After that, the conductive film and the third metal oxide film were processed, whereby a first gate electrode of the transistor 100A and a first gate electrode of the transistor 200A were obtained.

Then, treatment for adding boron as an impurity element was performed using each of the first gate electrodes as a mask. A plasma ion doping method was used for the addition treatment. A B₂H₆ gas was used as a gas for supplying boron.

Next, a 300-nm-thick silicon nitride oxide film was deposited by a plasma CVD method as a protective layer covering the transistor.

Then, a 1.5-μm-thick acrylic resin film having an opening portion was formed as a planarization film. After that, heat treatment was performed at 240° C. for 1 hour. Then, the silicon nitride oxide film in a region overlapping with the opening portion was removed.

Next, a 50-nm-thick titanium film, a 200-nm-thick aluminum film, and a 50-nm-thick titanium film were formed by sputtering and was processed, whereby a source electrode and a drain electrode of the transistor 100A and a source electrode and a drain electrode of the transistor 200A were obtained. After that, heat treatment was performed at 240° C. for 1 hour.

Through the above steps, the sample including the transistor 100A and the transistor 200A formed over the glass substrate was obtained.

### <Id-Vg Characteristics>

Next, Id-Vg characteristics of the transistors in the sample fabricated above were measured.

For measuring the Id-Vg characteristics of the transistors, a voltage applied to the gate electrode (hereinafter also referred to as gate voltage (Vg)) was applied from −15 V to +15 V in increments of 0.1 V. Moreover, a voltage applied to the source electrode (hereinafter also referred to as a source voltage (Vs)) was 0 V (comm), and a voltage applied to the drain electrode (hereinafter also referred to as a drain voltage (Vd)) was 0.1 V and 10 V. Note that an upper limit of the drain current (Id) measurement was 1×10⁻³ A.

The Id-Vg characteristics measured here were the case where the second gate electrode and the first gate electrode were supplied with the same gate voltage.

Two types of transistors were used in measurement: one with a channel length of 3 and a channel width of 3 μm as designed values and the other with a channel length of 3 μm and a channel width of 50 μm as designed values. The number of transistors measured were 20 in each case.

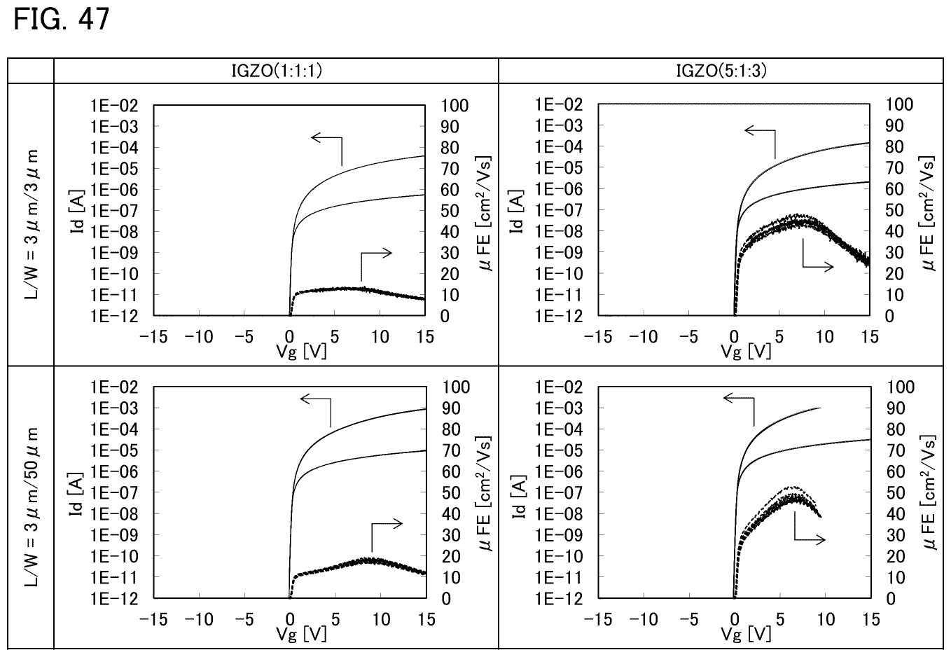

FIG. 47 shows the Id-Vg characteristics of the transistors in each case. In FIG. 47, the horizontal axis represents gate voltages (Vg), the left vertical axis represents drain currents (Id), and the right vertical axis represents field-effect mobility (μFE). Each graph shows two Id-Vg characteristics at drain voltages of 0.1 V and 10 V. Note that the transistor 100A whose semiconductor layer was formed using a sputtering target with the atomic ratio of metal elements of In:Ga:Zn=1:1:1 is denoted by IGZO (1:1:1), and the transistor 200A whose semiconductor layer was formed using a sputtering target with the atomic ratio of metal elements of In:Ga:Zn=5:1:3 is denoted by IGZO (5:1:3).

As shown in FIG. 47, favorable electrical characteristics with small variation was observed in each case. Higher on-state current and field-effect mobility were confirmed in the transistor 200A using IGZO (5:1:3) than those in the transistor 100A using IGZO (1:1:1).

### <Reliability>

Next, the reliability of the transistors fabricated in the above manner was evaluated.

As the reliability evaluation, a GBT stress test was performed. In this example, a PBTS test and an NBTIS tests were performed.

In the PBTS test, a substrate over which the transistors were formed was held at 60° C., a voltage of 0.1 V was applied to the source and the drain of the transistors, and a voltage of 20 V was applied to the gate; this state was held for one hour. The test environment was a dark state. In the NBTIS test, a substrate over which the transistors were formed was held at 60° C., a voltage of 0 V was applied to the source and the drain of the transistors and a voltage of −20 V was applied to the gate in a state where irradiation with white LED light at 5000 lx was performed; this state was held for one hour. The irradiation with white LED light was performed from the glass substrate side. In the PBTS test and the NBTIS test, the used transistors each have a channel length of 3 μm and a channel width of 3 μm.

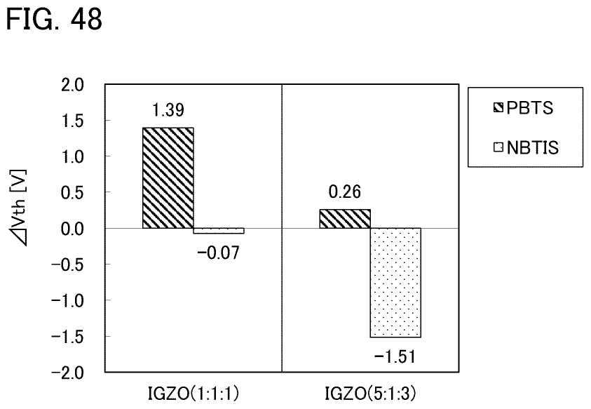

FIG. 48 shows the amounts of change in the threshold voltage between before and after the PBTS test and between before and after the NBTIS test. In FIG. 48, the horizontal axis represents the condition of the semiconductor layer, and the vertical axis represents the amount of change in the threshold voltage (ΔVth).

FIG. 48 shows that the amount of change in threshold voltage in the PBTS test was small in the case of the transistor 200A using IGZO (5:1:3), and that the amount of change in threshold voltage in the NBTIS test was small in the case of the transistor 100A using IGZO (1:1:1). Since the transistor 100A using IGZO (1:1:1) contains higher content of gallium in the semiconductor layer than the transistor 200A using IGZO (5:1:3), a smaller amount of change in the threshold voltage in the NBTIS test is considered. In contrast, since the transistor 200A using IGZO (5:1:3) contains higher content of indium in the semiconductor layer than the transistor 100A using IGZO (1:1:1), a higher on-state current is considered. In addition, since the gallium content in the semiconductor layer is low, a smaller amount of change in the threshold voltage in the PBTS test is considered. Thus, it was confirmed that transistors with different compositions in the semiconductor layers are able to be formed separately over one substrate and they can have favorable electrical characteristics and reliability.

### Example 2

This example describes evaluation results of reliability, with respect to an X-ray, of transistors that can be used in the semiconductor device of one embodiment of the present invention.

In this example, an OS transistor including a metal oxide in a semiconductor layer and a transistor including low-temperature polysilicon (LTPS) in a semiconductor layer (hereinafter, the transistor is also referred to as an LTPS transistor) were fabricated.

As Sample A, an OS transistor of a TGSA (top-gate self-aligned) type, corresponding to the transistor 200K described in Embodiment 1, was fabricated. Sample A is an n-channel transistor.

As Sample B, an OS transistor of a BGTC (bottom-gate top-contact) type was fabricated. Sample B is an n-channel transistor.

As Sample C, an LTPS transistor of a TGSA type was fabricated. For Sample C, two types of transistors, an n-channel (nch) transistor and a p-channel (pch) transistor, were fabricated.

### <Sample a Fabrication>

First, a 100-nm-thick tungsten film was formed by a sputtering method over a glass substrate, and then processed, whereby a second gate electrode (bottom gate electrode) of the transistor was obtained.

Then, a second gate insulating layer was deposited by a plasma CVD method. As the second gate insulating layer, a 290-nm-thick first silicon nitride film, a 60-nm-thick second silicon nitride film, and a 3-nm-thick first silicon oxynitride film were stacked in this order.

Next, a 25-nm-thick first metal oxide film was formed over the second gate insulating layer and processed, whereby a semiconductor layer was obtained. The first metal oxide film was deposited by a sputtering method using a sputtering target with an atomic ratio of metal elements of In:Ga:Zn=1:1:1.

Next, heat treatment was performed at 350° C. in a dry air (CDA) atmosphere for two hours.

Then, a first gate insulating layer was deposited by a plasma CVD method over the second gate insulating layer and the semiconductor layer. Next, as the first gate insulating layer, a 10-nm-thick second silicon oxynitride film, a 70-nm-thick third silicon oxynitride film, and a 20-nm-thick fourth silicon oxynitride film were stacked in this order.

Next, heat treatment was performed at 350° C. in a dry air (CDA) atmosphere for one hour.

Next, a 20-nm-thick second metal oxide film was deposited by a sputtering method over the first gate insulating layer. The second metal oxide film was deposited by a sputtering method using a sputtering target with an atomic ratio of metal elements of In:Ga:Zn=5:1:3.

Next, heat treatment was performed at 350° C. in a dry air (CDA) atmosphere for one hour.

Then, the second gate insulating layer, the first gate insulating layer, and the second metal oxide film were etched partly, so that a first opening portion reaching the second gate electrode was formed.

Then, a conductive film was deposited by a sputtering method to cover the first opening portion. The conductive film was formed by stacking a 50-nm-thick molybdenum film, a 200-nm-thick aluminum film, and a 50-nm-thick titanium film in this order. After that, the conductive film and the second metal oxide film were processed, whereby a first gate electrode (top gate electrode) was obtained. The first gate electrode (top gate electrode) is electrically connected to the second gate electrode (bottom gate electrode) through the first opening portion.

Next, treatment for adding boron as an impurity element was performed using the first gate electrode as a mask. A plasma ion doping method was used for the addition treatment. A B₂H₆ gas was used as a gas for supplying boron.

Next, a 300-nm-thick silicon nitride oxide film nm was deposited by a plasma CVD method as a protective layer covering the transistor.

Then, as a planarization film, a 2-μm-thick polyimide film having a second opening portion was formed. After that, heat treatment was performed at 240° C. for 1 hour. Then, the silicon nitride oxide film in a region overlapping with the second opening portion was removed.

Next, a conductive film was deposited by a sputtering method to cover the second opening portion. The conductive film was formed by stacking a 50-nm-thick titanium film, a 300-nm-thick aluminum film, and a 50-nm-thick titanium film in that order. Then, the conductive film was processed, whereby a source electrode and a drain electrode were obtained. After that, heat treatment was performed at 240° C. for 1 hour.

Through the above steps, Sample A including the transistor over the glass substrate was obtained.

### <Sample B Fabrication>

In Sample B, a 20-nm-thick metal oxide was used for a semiconductor layer of the transistor. To obtain the metal oxide, a metal oxide film was deposited by a sputtering method using a sputtering target with an atomic ratio of metal elements of In:Ga:Zn=4:2:4.1 and then processed. A gate electrode was provided over a glass substrate, a gate insulating layer was provided over the gate electrode, a semiconductor layer was provided over the gate insulating layer, and a source electrode and a drain electrode were provided over the semiconductor layer. As the gate insulating layer, a 250-nm-thick silicon nitride film and a 5-nm-thick first silicon oxynitride film were stacked in this order. Note that Sample B includes a back gate electrode. An insulating layer was provided over the semiconductor layer, the source electrode, and the drain electrode, and the back gate electrode was provided over the insulating layer. The insulating layer was formed by stacking a 20-nm-thick second silicon oxynitride film, a 400-nm-thick third silicon oxynitride film, and a 100-nm-thick silicon nitride oxide film in this order. Note that the gate electrode and the back gate electrode were electrically connected to each other.

### <Sample C Fabrication>

In Sample C, 50-nm-thick LTPS was used for a semiconductor layer of the transistor. Note that Sample C includes a bottom gate electrode. The bottom gate electrode was provided over a glass substrate, a second gate insulating layer was provided over the bottom gate electrode, a semiconductor layer was provided over the second gate insulating layer, a first gate insulating layer was formed over the semiconductor layer, and a top gate electrode was provided over the first gate insulating layer. An insulating layer was provided over the first gate insulating layer and the top gate electrode, an opening portion reaching the semiconductor layer was provided in the first gate insulating layer and the insulating layer, and a source electrode and a drain electrode were provided to cover the openings portion. As the first gate insulating layer, a 110-nm-thick silicon oxynitride film was provided. As the second gate insulating layer, a 140-nm-thick silicon nitride oxide film and a 100-nm-thick silicon oxynitride film were stacked in this order. Note that the bottom gate electrode was electrically connected to the top gate electrode.

### <Reliability of Transistor>

The reliability of Samples fabricated in the above manner, with respect to an X-ray, was evaluated.

First, each Sample was set in an X-ray irradiation apparatus and subjected to static eliminating treatment with an ionizer for 5 minutes.

Next, Id-Vg characteristics of the transistors were measured before X-ray irradiation.

For measuring the Id-Vg characteristics of the transistors, a voltage applied to the gate electrode (hereinafter also referred to as gate voltage (Vg)) was applied from −30 V to +10 V or from −30 V to +5 V in increments of 0.1 V. Moreover, a voltage applied to the source electrode (hereinafter also referred to as a source voltage (Vs)) was 0 V (comm), and a voltage applied to the drain electrode (hereinafter also referred to as a drain voltage (Vd)) was 10 V. Note that an upper limit of the drain current (Id) measurement was 1×10⁻³ A. The Id-Vg characteristics measured here were the case where the first gate electrode and the second gate electrode were supplied with the same gate voltage.

The measured transistors each have a channel length of 3 μm and a channel width of 10 μm as designed values.

Next, each Sample was irradiated with an X-ray. As an X-ray irradiation apparatus, MX-160Labo produced by mediXtec Corporation was used. Tungsten was used as an X-ray source. Note that tube voltages of the X-ray source in the case of Sample A and Sample B were two types, 80 kV and 160 kV, and that in the case of Sample C was 160 kV.

Next, the Id-Vg characteristics of the transistors were measured.

In this example, the irradiation with the X-ray and the Id-Vg measurement were repeated, whereby a change in transistor characteristics with respect to the integral does of X-ray was evaluated.

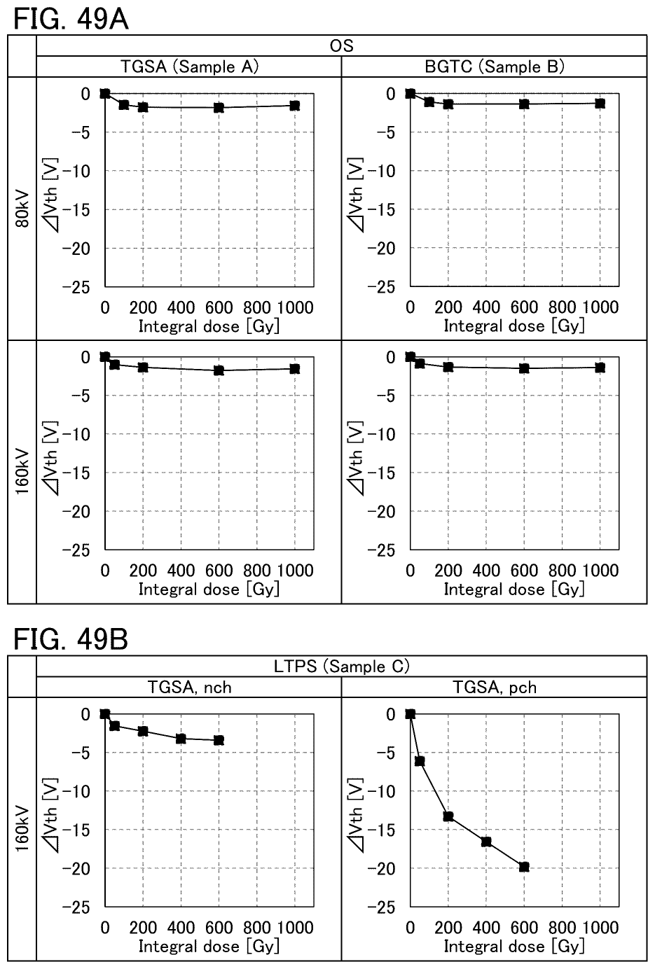

FIG. 49A shows the amounts of change in threshold voltage of Sample A and Sample B. FIG. 49B shows the amount of change in threshold voltage of Sample C. In FIG. 49A and FIG. 49B, each horizontal axis represents integral doses of X-ray, and each vertical axis represents the amount of change in threshold voltage of the transistor (ΔVth). The amount of change in threshold voltage of the transistor (ΔVth) denotes a difference between the threshold voltages before and after the X-ray irradiation (a value obtained by subtracting the threshold voltage before the X-ray irradiation from the threshold voltage after the X-ray irradiation).

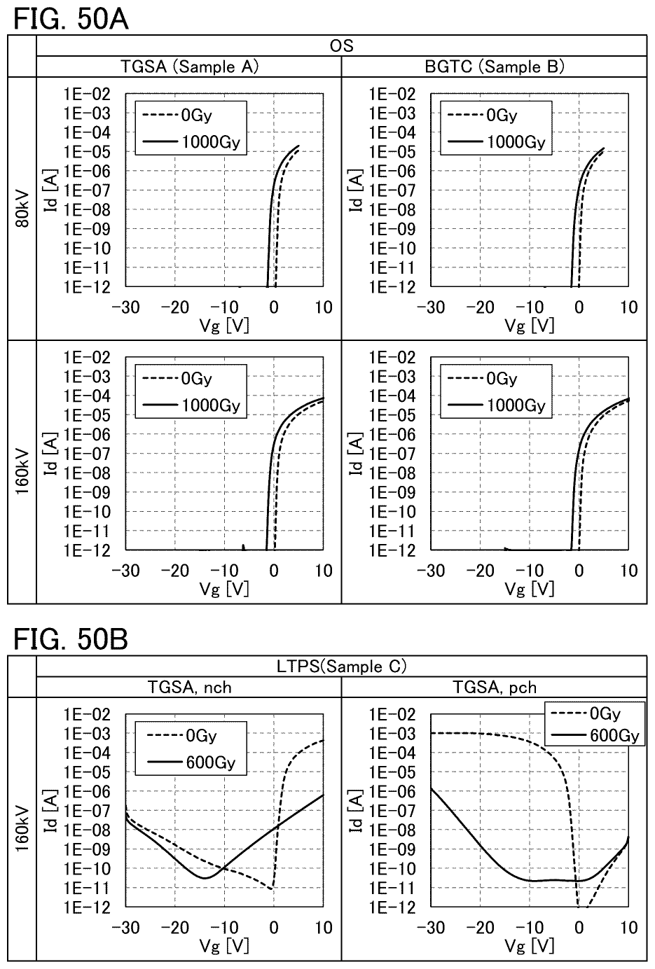

FIG. 50A shows the Id-Vg characteristics of Sample A and Sample B before and after the X-ray irradiation. FIG. 50B shows the Id-Vg characteristics of Sample C before and after the X-ray irradiation. In FIG. 50A and FIG. 50B, each horizontal axis represents gate voltage (Vg), and each vertical axis represents drain currents (Id). Furthermore, the Id-Vg characteristics before the X-ray irradiation, that is, at 0 Gy of the integral dose of the X-ray, are denoted by dotted lines, and the Id-Vg characteristics after the X-ray irradiation was denoted by solid lines. The Id-Vg characteristics of Sample A and Sample B shown here are in the case where the integral dose of the X-ray was 1000 Gy, and the Id-Vg characteristics of Sample C shown here are in the case where the integral dose of the X-ray was 600 Gy.

As shown in FIG. 49A, FIG. 49B, FIG. 50A, and FIG. 50B, it was found that Sample A and Sample B (OS transistors) each including a metal oxide in a semiconductor layer have a smaller amount of change in threshold voltage with respect to X-ray irradiation and higher reliability with respect to X-ray than Sample C (LTPS transistor) including LTPS in a semiconductor layer.

### REFERENCE NUMERALS

GL: gate line, PIX: pixel, SL: source line, TB100: thickness, TB200: thickness, TT100: thickness, TT200: thickness, 10: display device, 11: display portion, 12a: first driver circuit, 12b: first driver circuit, 12: first driver circuit, 13: second driver circuit, 31: shift register circuit, 32: latch circuit, 33: latch circuit, 34: level shifter circuit, 35: DAC circuit, 36: analog buffer circuit, 37: source follower circuit, 38: sampling circuit, 41: latch circuit portion, 42: level shifter circuit portion, 43: D/A converter portion, 44: analog buffer circuit portion, 45: source follower circuit portion, 46: demultiplexer circuit, 51: transistor, 52: transistor, 53: capacitor, 54: light-emitting device, 100A: transistor, 100B: transistor, 100C: transistor, 100D: transistor, 100E: transistor, 100F: transistor, 100G: transistor, 100H: transistor, 100I: transistor, 100J: transistor, 100K: transistor, 100L: transistor, 100M: transistor, 100N: transistor, 100P: transistor, 100: transistor, 102: substrate, 103a: insulating layer, 103b: insulating layer, 103: insulating layer, 106: conductive layer, 108f: metal oxide film, 108L: region, 108N: low-resistance region, 108: semiconductor layer, 110A: insulating layer, 110a: insulating layer, 110B: insulating layer, 110b: insulating layer, 110C: insulating layer, 110: insulating layer, 112f: conductive film, 112: conductive layer, 114f: metal oxide film, 114: metal oxide layer, 117a: insulating layer, 117b: insulating layer, 117: insulating layer, 118: insulating layer, 120a: conductive layer, 120b: conductive layer, 130: insulating layer, 132: insulating layer, 135: resist mask, 136: resist mask, 137a: resist mask, 137b: resist mask, 139: region, 140: impurity element, 141a: opening portion, 141b: opening portion, 142: opening portion, 143a: opening portion, 143b: opening portion, 193: target, 194: plasma, 195: target, 196: plasma, 197: target, 198: plasma, 200A: transistor, 200B: transistor, 200C: transistor, 200D: transistor, 200E: transistor, 200F: transistor, 200G: transistor, 200H: transistor, 200I: transistor, 200J: transistor, 200K: transistor, 200L: transistor, 200M: transistor, 200N: transistor, 200P: transistor, 200: transistor, 201: transistor, 203: connection layer, 204: connection portion, 205: transistor, 206: conductive layer, 208f: metal oxide film, 208L: region, 208N: low-resistance region, 208: semiconductor layer, 212: conductive layer, 214: metal oxide layer, 215: insulating layer, 220a: conductive layer, 220b: conductive layer, 222b: conductive layer, 241a: opening portion, 241b: opening portion, 242: opening portion, 243a: opening portion, 243b: opening portion, 300A: display device, 300: display device, 301: layer, 310a: subpixel, 310A: pixel, 310b: subpixel, 310B: pixel, 310c: subpixel, 310: pixel, 311a: conductive layer, 311b: conductive layer, 311c: conductive layer, 312a: conductive layer, 312b: conductive layer, 312c: conductive layer, 313a: first layer, 313b: second layer, 313c: third layer, 314: fourth layer, 315: common electrode, 317: light-blocking layer, 318a: sacrificial layer, 318b: sacrificial layer, 318c: sacrificial layer, 319a: sacrificial layer, 319b: sacrificial layer, 320: substrate, 321: insulating layer, 322: resin layer, 323: conductive layer, 324: insulating layer, 325: insulating layer, 326a: conductive layer, 326b: conductive layer, 326c: conductive layer, 327: insulating layer, 328: layer, 330a: light-emitting device, 330b: light-emitting device, 330c: light-emitting device, 331: protective layer, 334: space, 340: connection portion, 342: adhesive layer, 351: substrate, 352: substrate, 362: display portion, 364: circuit, 365: wiring, 366: conductive layer, 372: FPC, 373: IC, 772: lower electrode, 785: layer, 786a: EL layer, 786b: EL layer, 786: EL layer, 788: upper electrode, 4411: light-emitting layer, 4412: light-emitting layer, 4413: light-emitting layer, 4420: layer, 4421: layer, 4422: layer, 4430: layer, 4431: layer, 4432: layer, 4440: charge-generation layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9200: portable information terminal, 9201: portable information terminal

1. A semiconductor device comprising:
a first transistor; and
a second transistor,
wherein the first transistor comprises a first semiconductor layer, a first insulating layer over the first semiconductor layer, a second insulating layer over the first insulating layer, and a first gate electrode over the second insulating layer,
wherein the second transistor comprises a second semiconductor layer, the second insulating layer over the second semiconductor layer, and a second gate electrode over the second insulating layer,
wherein each of the first semiconductor layer and the second semiconductor layer comprises indium, and
wherein an atomic ratio of the indium in the second semiconductor layer to metal elements in the second semiconductor layer is different from an atomic ratio of the indium in the first semiconductor layer to metal elements in the first semiconductor layer.

2. The semiconductor device according to claim 1,
wherein the first insulating layer comprises a first region in contact with a top surface of the first semiconductor layer and a second region in contact with a bottom surface of the second semiconductor layer.

3. The semiconductor device according to claim 1,
wherein the atomic ratio of the indium in the second semiconductor layer to the metal elements in the second semiconductor layer is higher than the atomic ratio of the indium in the first semiconductor layer to the metal elements in the first semiconductor layer.

4. The semiconductor device according to claim 1, wherein the atomic ratio of the indium in the second semiconductor layer to the metal elements in the second semiconductor layer is higher than or equal to 30 atomic % and lower than or equal to 100 atomic %.

5. The semiconductor device according to claim 1,
wherein the atomic ratio of the indium in the first semiconductor layer to the metal elements in the first semiconductor layer is higher than the atomic ratio of the indium in the second semiconductor layer to the metal elements in the second semiconductor layer.

6. The semiconductor device according to claim 1, wherein the atomic ratio of the indium in the first semiconductor layer to the metal elements in the first semiconductor layer is higher than or equal to 30 atomic % and lower than or equal to 100 atomic %.

7. The semiconductor device according to claim 1,
wherein each of the first semiconductor layer and the second semiconductor layer comprises an element M,
wherein the element M is one or more kinds selected from gallium, aluminum, yttrium, and tin, and
wherein an atomic ratio of the element M in the second semiconductor layer to metal elements in the second semiconductor layer is different an atomic ratio of the element M in the first semiconductor layer to metal elements in the first semiconductor layer.

8. The semiconductor device according to claim 7, wherein the atomic ratio of the element M in the second semiconductor layer to the metal elements in the second semiconductor layer is higher than or equal to 20 atomic % and lower than or equal to 60 atomic %.

9. (canceled)

10. The semiconductor device according to claim 7, wherein the atomic ratio of the element M in the first semiconductor layer to the metal elements in the first semiconductor layer is higher than or equal to 20 atomic % and lower than or equal to 60 atomic %.

11. The semiconductor device according to claim 1,
wherein the first transistor further comprises a third insulating layer and a third gate electrode,
wherein the third gate electrode comprises a region overlapping with the first gate electrode with the first semiconductor layer therebetween, and
wherein the third gate electrode comprises a region overlapping with the first semiconductor layer with the third insulating layer therebetween.

12. The semiconductor device according to claim 11,
wherein the second transistor further comprises the first insulating layer, the third insulating layer, and a fourth gate electrode,
wherein the fourth gate electrode comprises a region overlapping with the second gate electrode with the second semiconductor layer therebetween, and
wherein the fourth gate electrode comprises a region overlapping with the second semiconductor layer with the first insulating layer and the third insulating layer therebetween.

13. (canceled)
